(19) United States
(12) Patent Application Publication
(10) Pub. No.: US 2021/0222092 A1
(43) Pub. Date: Jul. 22, 2021

(54) CHEMICAL LIQUID AND CHEMICAL LIQUID STORAGE BODY

(71) Applicant: FUJIFILM Corporation, Tokyo (JP)

(72) Inventors: Tetsuya KAMIMURA, Shizuoka (JP); Satomi TAKAHASHI, Shizuoka (JP)

(73) Assignee: FUJIFILM Corporation, Tokyo (JP)

(21) Appl. No.: 17/219,818

(22) Filed: Mar. 31, 2021

Related U.S. Application Data
(63) Continuation of application No. PCT/JP2019/038078, filed on Sep. 27, 2019.

(30) Foreign Application Priority Data
Oct. 3, 2018 (JP) 2018-188530

(51) Int. Cl. C11D 7/36; C11D 7/26; H01L 21/02; G03F 7/32; C11D 7/20; C11D 11/00

(52) U.S. Cl. CPC C11D 7/36; C11D 7/266; C11D 7/261; C11D 11/0047; H01L 21/02057; G03F 7/32; C11D 7/20; C11D 7/264

(57) ABSTRACT

An object of the present invention is to provide a chemical liquid and a chemical liquid storage body having excellent performance of inhibiting metal impurity-containing defects. The chemical liquid according to an embodiment of the present invention contains an organic solvent, organic impurities, and metal impurities, in which the organic impurities contain a phosphoric acid ester and an adipic acid ester, and a mass ratio of a content of the phosphoric acid ester to a content of the adipic acid ester is equal to or higher than 1.

### CROSS-REFERENCE TO RELATED APPLICATIONS

This application is a Continuation of PCT International Application No. PCT/JP2019/038078 filed on Sep. 27, 2019, which claims priority under 35 U.S.C. § 119(a) to Japanese Patent Application No. 2018-188530 filed on Oct. 3, 2018. Each of the above applications is hereby expressly incorporated by reference, in its entirety, into the present application.

### BACKGROUND OF THE INVENTION

### 1. Field of the Invention

The present invention relates to a chemical liquid and a chemical liquid storage body.

### 2. Description of the Related Art

In a case where semiconductor devices are manufactured by a wiring forming process including photolithography, as a prewet solution, a resist solution, a developer, a rinsing solution, a peeling solution, a chemical mechanical polishing (CMP) slurry, a washing solution used after CMP, and the like, a chemical liquid containing water and/or an organic solvent is used.

As shown JP1997-049000A (JP-H09-049000A), for the purpose of inhibiting the decomposition over time and the like, sometimes organic solvents contain an antioxidant. In other words, for example, as for a polyhydric alcohol-based organic solvent, in a case where this solvent is used as a pure organic solvent, radicals are generated in the molecules, which leads to a problem in that the organic solvent turns into a peroxide and then to an organic acid. In order to prevent such a problem, an antioxidant is used.

### SUMMARY OF THE INVENTION

In some cases, various impurities contained in the chemical liquid cause defects in semiconductor devices. Such defects sometimes cause the reduction in manufacturing yield of semiconductor devices and an electrical abnormality such as a short circuit.

Specific examples of such impurities include organic impurities such as a plasticizer eluted from a manufacturing device used for manufacturing an organic solvent and an antioxidant added to stabilize an organic solvent as shown in JP1997-049000A (JP-H09-049000A), metal impurities eluted from a manufacturing device used for manufacturing an organic solvent, and the like.

The inventors of the present invention used a chemical liquid containing an organic solvent in a wiring forming process including photolithography. As a result, it has been revealed that depending on the ratio of specific compounds contained in organic impurities, sometimes metal impurity-containing defects in a wiring board increases.

Therefore, an object of the present invention is to provide a chemical liquid and a chemical liquid storage body having excellent performance of inhibiting metal impurity-containing defects.

In order to achieve the above object, the inventors of the present invention conducted intensive studies. As a result, the inventors have found that in a chemical liquid containing an organic solvent, organic impurities containing a phosphoric acid ester and an adipic acid ester, and metal impurities, in a case where a mass ratio of a content of the phosphoric acid ester to a content of the adipic acid ester is equal to or higher than a specific value, excellent performance of inhibiting metal impurity-containing defects is obtained. Based on this finding, the inventors have accomplished the present invention.

That is, the inventors of the present invention have found that the above object can be achieved by the following constitutions.

[1] A chemical liquid containing an organic solvent, organic impurities, and metal impurities, in which the organic impurities contain a phosphoric acid ester and an adipic acid ester, and a mass ratio of a content of the phosphoric acid ester to a content of the adipic acid ester is equal to or higher than 1.

[2] The chemical liquid described in [1], in which the content of the phosphoric acid ester is 0.1 mass ppt to 100 mass ppm with respect to a total mass of the chemical liquid.

[3] The chemical liquid described in [1] or [2], in which the content of the adipic acid ester is 0.1 mass ppt to 10 mass ppm with respect to a total mass of the chemical liquid.

[4] The chemical liquid described in any one of [1] to [3], in which the mass ratio of the content of the phosphoric acid ester to the content of the adipic acid ester is 1 to 10⁴.

[5] The chemical liquid described in any one of [1] to [4], in which the organic impurities further contain a phthalic acid ester.

[6] The chemical liquid described in [5], in which a content of the phthalic acid ester is 0.1 mass ppt to 10 mass ppm with respect to a total mass of the chemical liquid.

[7] The chemical liquid described in [5] or [6], in which a mass ratio of the content of the phosphoric acid ester to a content of the phthalic acid ester is 10⁻² to 10.

[8] The chemical liquid described in any one of [5] to [7], in which a mass ratio of the content of the adipic acid ester to a content of the phthalic acid ester is 10⁻³ to 10.

[9] The chemical liquid described in any one of [1] to [8], further containing water, in which a content of the water is 0.001% to 0.10% by mass with respect to a total mass of the chemical liquid.

[10] The chemical liquid described in any one of [1] to [9], in which the organic impurities further contain at least one kind of compound selected from the group consisting of alcohol and acetone.

[11] The chemical liquid described in [10], in which the alcohol is at least one kind of compound selected from the group consisting of methanol, ethanol, n-butanol, and cyclohexanol.

[12] The chemical liquid described in [10] or [11], in which a total content of the alcohol and the acetone is 1 mass ppt to 3,000 mass ppm with respect to a total mass of the chemical liquid.

[13] The chemical liquid described in any one of [10] to [12], in which a mass ratio of the content of the phosphoric acid ester to a total content of the alcohol and the acetone is 10⁻³ to 10⁹.

[14] The chemical liquid described in any one of [10] to [13], in which a mass ratio of the content of the adipic acid ester to a total content of the alcohol and the acetone is 10⁻¹ to 10⁵.

[15] The chemical liquid described in any one of [10] to [14], further containing water, in which a mass ratio of a content of water to a total content of the alcohol and the acetone is 1 to 10⁹.

[16] The chemical liquid described in any one of [1] to [15], in which a content of the metal impurities is 0.1 to 2,000 mass ppt with respect to a total mass of the chemical liquid.

[17] The chemical liquid described in any one of [1] to [16], in which the metal impurities contain metal-containing particles and metal ions.

[18] The chemical liquid described in [17], in which the metal-containing particles contain metal nanoparticles having a particle size of 0.5 to 17 nm.

[19] The chemical liquid described in [18], in which the metal nanoparticles contain first iron oxide nanoparticles consisting of iron oxide, and the number of the first iron oxide nanoparticles contained in a unit volume of the chemical liquid is 10 to 1.0×10¹¹ particles/cm³.

[20] The chemical liquid described in [19], in which the metal nanoparticles contain second iron oxide nanoparticles containing iron oxide and an organic compound, and a ratio of the number of the second iron oxide nanoparticles contained in a unit volume of the chemical liquid to the number of the first iron oxide nanoparticles contained in a unit volume of the chemical liquid is 10 to 10⁸.

[21] The chemical liquid described in any one of [1] to [20], in which the organic impurities further contain a stabilizer.

[22] The chemical liquid described in [21], in which the stabilizer is an antioxidant. [23] The chemical liquid described in [21] or [22], further containing water, in which a mass ratio of a content of the water to a content of the stabilizer is 10 to 10⁵.

[24] The chemical liquid described in any one of [21] to [23], in which the organic impurities further contain at least one kind of compound selected from the group consisting of alcohol and acetone, and a mass ratio of a total content of the alcohol and the acetone to a content of the stabilizer is 10⁻⁷ to 10³.

[25] The chemical liquid described in any one of [21] to [24], in which the stabilizer is at least one kind of antioxidant selected from the group consisting of dibutylhydroxytoluene, hydroquinone, didodecyl 3,3′-thiodipropionate, dioctadecyl 3,3′-thiodipropionate, ditetradecyl 3,3′-thiodipropionate, 4,4′-butylidenebis-(6-tert-butyl-3-methylphenol), 2,2′-methylenebis-(4-ethyl-6-tert-butylphenol), butylhydroxyanisole, tris(2-ethylhexyl)phosphite, and triisodecyl phosphite.

[26] The chemical liquid described in any one of [21] to [25], in which a boiling point of the stabilizer is 150° C. to 500° C.

[27] The chemical liquid described in any one of [1] to [26], in which the number of objects to be counted having a size equal to or greater than 0.04 μm that is counted by a light scattering liquid-borne particle counter is equal to or less than 100 particles/mL.

[28] The chemical liquid described in any one of [1] to [27], which is used as a raw material of at least one kind of liquid selected from the group consisting of a developer, a rinsing solution, a prewet solution, and a piping washing solution.

[29] A chemical liquid storage body including a container and the chemical liquid described in any one of [1] to [28] that is stored in the container.

[30] The chemical liquid storage body described in [29], in which at least a part of a liquid contact portion of the container is a fluororesin, electropolished stainless steel, or glass.

[31] The chemical liquid storage body described in [29] or [30], in which a void volume of the container in the chemical liquid storage body is 5% to 30% by volume.

As will be described below, according to an aspect of the present invention, it is possible to provide a chemical liquid and a chemical liquid storage body having excellent performance of inhibiting metal impurity-containing defects.

### DESCRIPTION OF THE PREFERRED EMBODIMENTS

Hereinafter, the present invention will be described.

The following constituents will be described based on typical embodiments of the present invention in some cases, but the present invention is not limited to the embodiments.

In the present specification, the range of numerical values described using “to” means a range including the numerical values listed before and after “to” as the lower limit and the upper limit.

In the present invention, “ppm” means “parts-per-million (10⁻⁶)”, “ppb” means “parts-per-billion (10⁻⁹)”, “ppt” means “parts-per-trillion (10⁻¹²)”, and “ppq” means “parts-per-quadrillion (10⁻¹⁵)”.

In the present invention, regarding the description of a group (atomic group), in a case where whether the group is substituted or unsubstituted is not described, as long as the effects of the present invention are not impaired, the group includes a group which does not have a substituent and a group which has a substituent. For example, “hydrocarbon group” includes not only a hydrocarbon group which does not have a substituent (unsubstituted hydrocarbon group) but also a hydrocarbon group which has a substituent (substituted hydrocarbon group). The same is true of each compound.

Furthermore, in the present invention, “radiation” means, for example, far ultraviolet, extreme ultraviolet (EUV), X-rays, electron beams, and the like. In addition, in the present invention, light means actinic rays or radiation. In the present invention, unless otherwise specified, “exposure” includes not only exposure by far ultraviolet, X-rays, EUV, and the like, but also lithography by particle beams such as electron beams or ion beams.

[Chemical Liquid]

The chemical liquid according to an embodiment of the present invention (hereinafter, also called “the present chemical liquid”) contains an organic solvent, organic impurities, and metal impurities, in which the organic impurities contain a phosphoric acid ester and an adipic acid ester, and a mass ratio of a content of the phosphoric acid ester to a content of the adipic acid ester is equal to or higher than 1.

In a case where a chemical liquid is used for wafer treatment or the like, sometimes metal impurity-containing defects remain on a wafer surface as residues. Examples of the metal impurity-containing defects include defects that contain only metal impurities and defects that are formed by the incorporation of metal components (metal impurities) contained in the chemical liquid into an organic compound (organic impurities) contained in the chemical liquid.

As a result of repeating studies on the problem, the inventors of the present invention have found that in a case where a mass ratio of a content of a phosphoric acid ester to a content of an adipic acid ester as organic impurities is equal to or higher than 1 as shown in Examples that will be described later, the occurrence of metal impurity-containing defects can be inhibited.

More specifically, the inventors have found that, for example, in a case where the mass ratio of the content of the phosphoric acid ester to the content of the adipic acid ester is controlled, residues derived from these compounds can be controlled. The mechanism is assumed to operate for the following reasons. That is, both the adipic acid ester and phosphoric acid ester exhibit a coordinating ability to metals. Although these compounds have substantially the same coordinating ability, the complexes formed by these are in different conditions. The adipic acid ester tends to act on other elements (such as a Si substrate) via a carboxyl-derived skeleton thereof and thus turns into residues. On the other hand, because the phosphoric acid ester has an alkylated phosphoric acid group, the skeleton of the compound is less able to interact with other elements. That is, the phosphoric acid ester hardly remains as a complex after acting on a metal. Therefore, presumably, in a case where the mass ratio of the content of the phosphoric acid ester to the content of the adipic acid ester is equal to or higher than 1, the amount of phosphoric acid ester complexes will be relatively large and thus the amount of residues will be reduced.

[Organic Solvent]

The chemical liquid contains an organic solvent. In the present specification, “organic solvent” means a liquid organic compound contained in the chemical liquid at a content greater than 10,000 mass ppm per component with respect to the total mass of the chemical liquid. That is, in the present specification, a liquid organic compound contained in an amount greater than 10,000 mass ppm with respect to the total mass of the chemical liquid corresponds to an organic solvent.

In the present specification, “liquid” means that the compound stays in liquid form at 25° C. under atmospheric pressure.

The type of the organic solvent is not particularly limited, and known organic solvents are used. Examples of the organic solvent include alkylene glycol monoalkyl ether carboxylate, alkylene glycol monoalkyl ether, a lactic acid alkyl ester, alkyl alkoxypropionate, cyclic lactone (preferably having 4 to 10 carbon atoms), a monoketone compound which may have a ring (preferably having 4 to 10 carbon atoms), alkylene carbonate, alkoxyalkyl acetate, alkyl pyruvate, and the like.

Furthermore, as the organic solvent, those described in JP2016-057614A, JP2014-219664A, JP2016-138219A, and JP2015-135379A may be used.

As the organic solvent, at least one kind of compound is preferable which is selected from the group consisting of propylene glycol monomethyl ether, propylene glycol monoethyl ether (PGME), propylene glycol monopropyl ether, propylene glycol monomethyl ether acetate (PGMEA), ethyl lactate (EL), methyl methoxypropionate, cyclopentanone, cyclohexanone (CHN), γ-butyrolactone, diisoamyl ether, butyl acetate (nBA), isoamyl acetate (iAA), isopropanol (IPA), 4-methyl-2-pentanol (MIBC), dimethylsulfoxide, N-methyl-2-pyrrolidone (NMP), diethylene glycol, ethylene glycol, dipropylene glycol, propylene glycol, ethylene carbonate, propylene carbonate (PC), sulfolane, cycloheptanone, 1-hexanol, decane, and 2-heptanone. Among these, at least one kind of compound selected from the group consisting of nBA, CHN, IPA, EL, PGMEA, PGME, and PC is preferable because these have higher defect inhibition performance.

The content of the organic solvent in the chemical liquid is not particularly limited. Generally, the content of the organic solvent with respect to the total mass of the chemical liquid is preferably equal to or greater than 98.0% by mass, more preferably equal to or greater than 99.0% by mass, even more preferably equal to or greater than 99.9% by mass, and particularly preferably equal to or greater than 99.99% by mass. The upper limit thereof is not particularly limited, but is less than 100% by mass in many cases.

One kind of organic solvent may be used singly, or two or more kinds of organic solvents may be used in combination. In a case where two or more kinds of organic solvents are used in combination, the total amount thereof is within the above range.

The type and content of the organic solvent in the chemical liquid can be measured using a gas chromatography mass spectrometry.

[Organic Impurities]

The chemical liquid contains organic impurities. The organic impurities may be added to the chemical liquid or may be unintentionally mixed with the chemical liquid in the process of manufacturing the chemical liquid. Examples of the case where the organic impurities are unintentionally mixed with the chemical liquid in the process of manufacturing the chemical liquid include, but are not limited to, a case where the organic impurities are contained in raw materials (for example, an organic solvent) used for manufacturing the chemical liquid, a case where the organic impurities are mixed with the chemical liquid in the process of manufacturing the chemical liquid (for example, contamination), and the like.

The content and type of the organic impurities in the chemical liquid can be measured using gas chromatography mass spectrometry (GCMS).

<Phosphoric Acid Ester and Adipic Acid Ester>

The organic impurities in the present invention contain a phosphoric acid ester and an adipic acid ester. These components may be added to the chemical liquid.

In some cases, the phosphoric acid ester is used as a plasticizer for a rubber member such as an O-ring constituting an organic solvent manufacturing device. The phosphoric acid ester may be a component which is eluted from such a member into the organic solvent and incorporated into the chemical liquid together with the organic solvent.

The adipic acid ester may be a component which is incorporated into the chemical liquid together with the organic solvent, as a byproduct generated during the manufacturing of the organic solvent.

Specific examples of the phosphoric acid ester include tricresyl phosphate (TCP), tributyl phosphate (TBP), and the like. Among these, TBP is preferable because this compound further inhibits the metal impurity-containing defects.

Specific examples of the adipic acid ester include bis(2-ethylhexyl)adipate (DOA, another name: dioctyl adipate), monomethyl adipate (MMAD), and the like. Among these, bis(2-ethylhexyl)adipate (DOA) is preferable because this compound further inhibits the metal impurity-containing defects.

The mass ratio of the content of the phosphoric acid ester to the content of the adipic acid ester (content of phosphoric acid ester/content of adipic acid ester) is equal to or higher than 1. In view of further inhibiting the metal impurity-containing defects (particularly, defects containing both the organic impurities and metal impurities and defects containing oxides of metal atoms), the mass ratio is preferably higher than 1, and particularly preferably equal to or higher than 1.2. Furthermore, the mass ratio is preferably equal to or lower than 10⁵, and particularly preferably equal to or lower than 10³.

The present chemical liquid may contain one kind of phosphoric acid ester and one kind of adipic acid ester, or contain two or more kinds of phosphoric acid esters and two or more kinds of adipic acid esters.

In the present specification, in a case where the present chemical liquid contains two or more kinds of phosphoric acid esters, the content of the phosphoric acid esters means the total amount of the phosphoric acid esters contained in the present chemical liquid. Likewise, as for adipic acid esters, the content of the adipic acid esters means the total amount of the adipic acid esters contained in the present chemical liquid.

The content of the phosphoric acid ester is preferably 0.05 mass ppt to 150 mass ppm with respect to the total mass of the present chemical liquid. In view of further inhibiting the metal impurity-containing defects, the content of the phosphoric acid ester is more preferably 0.1 mass ppt to 100 mass ppm, and particularly preferably 1 mass ppt to 100 mass ppm.

In a case where the phosphoric acid ester contains tributyl phosphate (TBP), the content of the tributyl phosphate is preferably 0.005 mass ppt to 60 mass ppm with respect to the total mass of the present chemical liquid. In view of achieving at least excellent stability of the chemical liquid or higher performance of inhibiting metal impurity-containing defects, the content of the tributyl phosphate is more preferably 0.1 mass ppt to 40 mass ppm, and particularly preferably 1 mass ppt to 20 mass ppm.

The content of the adipic acid ester is preferably 0.003 mass ppt to 40 mass ppm with respect to the total mass of the present chemical liquid. In view of further inhibiting the metal impurity-containing defects, the content of the phosphoric acid ester is more preferably 0.1 mass ppt to 10 mass ppm, and particularly preferably 1 mass ppt to 10 mass ppm.

In a case where the phosphoric acid ester contains tributyl phosphate (TBP), in view of higher defect inhibition performance, the mass ratio of the content of the phosphoric acid ester to the content of the tributyl phosphate (content of phosphoric acid ester/content of tributyl phosphate) is preferably 1 to 10², and particularly preferably 1 to 10.

<Phthalic Acid Ester>

The organic impurities in the present invention may further contain a phthalic acid ester. The phthalic acid ester may be added to the chemical liquid. In some cases, the phthalic acid ester is used as a plasticizer for a rubber member such as an O-ring constituting an organic solvent manufacturing device. The phosphoric acid ester may be a component which is eluted from such a member into the organic solvent and incorporated into the chemical liquid together with the organic solvent.

Specific examples of the phthalic acid ester include dioctyl phthalate (DOP), bis(2-ethylhexyl)phthalate (DEHP), bis(2-propylheptyl)phthalate (DPHP), dibutyl phthalate (DBP), benzylbutyl phthalate (BBzP), diisodecyl phthalate (DIDP), diisooctyl phthalate (DIOP), diethyl phthalate (DEP), diisobutyl phthalate (DIBP), dihexyl phthalate, diisononyl phthalate (DINP), and the like.

The content of the phthalic acid ester is preferably 0.01 mass ppt to 50 mass ppm with respect to the total mass of the present chemical liquid. In view of further inhibiting metal impurity-containing defects, the content of the phthalic acid ester is more preferably 0.1 mass ppt to 10 mass ppm, and particularly preferably 1 mass ppt to 10 mass ppm.

In the present specification, in a case where the present chemical liquid contains two or more kinds of phthalic acid esters, the content of the phthalic acid esters means the total amount of the phthalic acid esters contained in the present chemical liquid.

The mass ratio of the content of the phosphoric acid ester to the content of the phthalic acid ester (content of phosphoric acid ester/content of phthalic acid ester) is preferably 10⁻³ to 10², more preferably 10⁻² to 10, and particularly preferably 10⁻¹ to 10. In a case where the mass ratio is equal to or higher than 10⁻², the chemical liquid has excellent stability. In a case where the mass ratio is equal to or lower than 10, the metal impurity-containing defects (particularly, defects containing oxides of metal atoms) are further inhibited.

The mass ratio of the content of the adipic acid ester to the content of the phthalic acid ester (content of adipic acid ester/content of phthalic acid ester) is preferably 10⁻⁴ to 10², more preferably 10⁻³ to 10, and particularly preferably 10⁻² to 10. In a case where the mass ratio is within a range of 10⁻³ to 10, the metal impurity-containing defects (particularly, defects containing both the organic impurities and metal impurities and defects containing oxides of metal atoms) are further inhibited.

In a case where the phosphoric acid ester contains tributyl phosphate (TBP), in view of higher defect inhibition performance, the mass ratio of the content of the tributyl phosphate to the content of the phthalic acid ester (content of tributyl phosphate/content of phthalic acid ester) is preferably 10⁻⁴ to 10², more preferably 10⁻³ to 10, and particularly preferably 10⁻² to 10.

<Alcohol and Acetone>

The organic impurities in the present invention may further contain at least one kind of compound selected from the group consisting of alcohol and acetone.

As described above, the organic solvent contained in the present chemical liquid refers to a liquid organic compound contained in the chemical liquid at a content greater than 10,000 mass ppm with respect to the total mass of the chemical liquid. Therefore, each of alcohol and acetone classified as organic impurities means a single alcohol or acetone component whose content is equal to or less than 10,000 mass ppm with respect to the total mass of the present chemical liquid.

In view of further inhibiting the metal impurity-containing defects, the alcohol as organic impurities is preferably at least one kind of compound selected from the group consisting of methanol, ethanol, n-butanol, and cyclohexanol.

The total content of the alcohol and the acetone as organic impurities with respect to the total mass of the present chemical liquid is preferably 0.1 mass ppt to 3,500 mass ppm, more preferably 1 mass ppt to 3,000 mass ppm, and particularly preferably 100 mass ppt to 2,800 mass ppm. In a case where the total content is equal to or greater than 1 mass ppt, the chemical liquid has excellent stability. In a case where the total content is equal to or less than 3,000 mass ppm, the chemical liquid has excellent stability, and the metal impurity-containing defects (particularly, metal atom-containing defects) are further inhibited.

In the present specification, the total content of the alcohol and the acetone as organic impurities means only the content of the alcohol in a case where the present chemical liquid does not contain the acetone, and means only the content of the acetone in a case where the present chemical liquid does not contain the alcohol.

The mass ratio of the content of the phosphoric acid ester to the total content of the alcohol and the acetone as organic impurities (content of phosphoric acid ester/total content of alcohol and acetone) is preferably 10⁻⁵ to 10¹², more preferably 10⁻³ to 10⁹, and particularly preferably 10⁻³ to 10⁸. In a case where the mass ratio is equal to or higher than 10⁻³, the chemical liquid has excellent stability, and the metal impurity-containing defects (particularly, metal atom-containing defects) are further inhibited. In a case where the mass ratio is equal to or lower than 10⁹, the chemical liquid has excellent stability.

The mass ratio of the content of the adipic acid ester to the total content of the alcohol and the acetone as organic impurities (content of adipic acid ester/total content of alcohol and acetone) is preferably 10⁻⁵ to 10¹², more preferably 10⁻³ to 10⁵, and particularly preferably 10⁻¹ to 10⁴. In a case where the mass ratio is equal to or higher than 10⁻¹, the metal impurity-containing defects (particularly, defects containing both the organic impurities and metal impurities and defects containing oxides of metal atoms) are further inhibited. In a case where the mass ratio is equal to or lower than 10⁵, the metal impurity-containing defects (particularly, defects containing both the organic impurities and metal impurities) are further inhibited.

The mass ratio of the content of the phthalic acid ester to the total content of the alcohol and the acetone as organic impurities (content of phthalic acid ester/total content of alcohol and acetone) is preferably 10⁻⁷ to 10¹³, more preferably 10⁻⁵ to 10¹¹, and particularly preferably 10⁻⁴ to 10⁹. In a case where the mass ratio is equal to or higher than 10⁻⁵, the chemical liquid has excellent stability, and the metal impurity-containing defects (particularly, metal atom-containing defects) are further inhibited. In a case where the mass ratio is equal to or lower than 10¹¹, the chemical liquid has excellent stability.

In a case where the phosphoric acid ester contains tributyl phosphate (TBP), in view of higher defect inhibition performance, the mass ratio of the content of the tributyl phosphate to the total content of the alcohol and the acetone as organic impurities (content of tributyl phosphate/total content of alcohol and acetone) is preferably 10⁻⁷ to 10¹², more preferably 10⁻⁴ to 10², even more preferably 10⁻³ to 10, and particularly preferably 10⁻² to 10.

<Stabilizer>

The organic impurities in the present invention may contain a stabilizer. The stabilizer is a component added for the purpose of inhibiting decomposition of the organic solvent over time. Examples thereof include an antioxidant.

Even though the aforementioned phosphoric acid ester functions as a stabilizer (antioxidant), the phosphoric acid ester is not classified as a stabilizer.

In view of further improving the stability of the chemical liquid, the boiling point of the stabilizer is preferably 150° C. to 500° C., and particularly preferably 200° C. to 480° C. In the present specification, unless otherwise specified, the boiling point means a standard boiling point.

The stabilizer is preferably at least one kind of antioxidant selected from the group consisting of dibutylhydroxytoluene (BHT), hydroquinone, didodecyl 3,3′-thiodipropionate, dioctadecyl 3,3′-thiodipropionate, ditetradecyl 3,3′-thiodipropionate, 4,4′-butylidenebis-(6-tert-butyl-3-methylphenol), 2,2′-methylenebis-(4-ethyl-6-tert-butylphenol), butylhydroxyanisole, tris(2-ethylhexyl)phosphite, and triisodecyl phosphite.

The content of the stabilizer with respect to the total mass of the present chemical liquid is preferably 0 to 10 mass ppm, and particularly preferably 1 mass ppt to 5 mass ppm.

In the present specification, in a case where the present chemical liquid contains two or more kinds of stabilizers, the content of the stabilizers means the total amount of the stabilizers contained in the present chemical liquid.

The mass ratio of the total content of the alcohol and the acetone as organic impurities to the content of the stabilizer (particularly, an antioxidant) (total content of alcohol and acetone/content of stabilizer) is preferably 10⁻⁸ to 10⁴, more preferably 10⁻⁷ to 10³, and particularly preferably 10⁻⁶ to 10³. In a case where the mass ratio is equal to or higher than 10⁻⁷, the metal impurity-containing defects (particularly, defects containing both the organic impurities and metal impurities) are further inhibited. In a case where the mass ratio is equal to or lower than 10³, the chemical liquid has excellent stability, and the metal impurity-containing defects (particularly, metal atom-containing defects) are further inhibited.

In a case where the phosphoric acid ester contains tributyl phosphate (TBP), in view of higher defect inhibition performance, the mass ratio of the content of the tributyl phosphate to the content of the stabilizer (particularly, an antioxidant) (content of tributyl phosphate/content of stabilizer) is preferably 10⁻³ to 10⁸, more preferably 10⁻² to 10⁷, and particularly preferably 1 to 10⁷.

<Organic Impurities Other than the Above>

The organic impurities may further contain organic impurities other than the phosphoric acid ester, the adipic acid ester, the alcohol and acetone, and the stabilizer.

Such organic impurities may be byproducts generated in the process of synthesizing an organic solvent and/or unreacted raw materials (hereinafter, also called “byproduct and the like”), and the like.

Examples of the byproduct and the like include compounds represented by Formulae I to V, and the like.

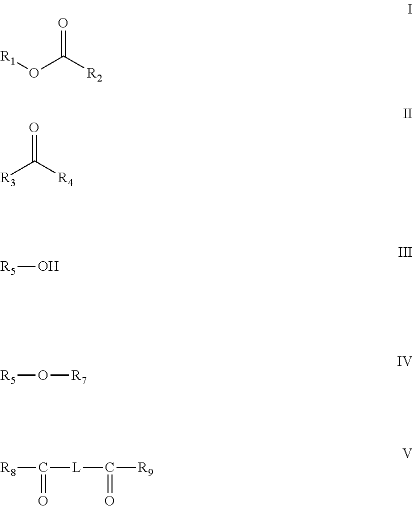

In Formula I, R₁ and R₂ each independently represent an alkyl group or a cycloalkyl group. Alternatively, R₁ and R₂ may be bonded to each other to form a ring.

As the alkyl group or the cycloalkyl group represented by R₁ and R₂, an alkyl group having 1 to 12 carbon atoms or a cycloalkyl group having 6 to 12 carbon atoms is preferable, and an alkyl group having 1 to 8 carbon atoms or a cycloalkyl group having 6 to 8 carbon atoms is more preferable.

The ring formed of R₁ and R₂ bonded to each other is a lactone ring, preferably a 4- to 9-membered lactone ring, and more preferably a 4- to 6-membered lactone ring.

It is preferable that R₁ and R₂ satisfy a relationship in which the number of carbon atoms in the compound represented by Formula I is equal to or greater than 8.

In Formula II, R₃ and R₄ each independently represent a hydrogen atom, an alkyl group, an alkenyl group, a cycloalkyl group, or a cycloalkenyl group. Alternatively, R₃ and R₄ may be bonded to each other to form a ring. Here, R₃ and R₄ do not simultaneously represent a hydrogen atom.

As the alkyl group represented by R₃ and R₄, for example, an alkyl group having 1 to 12 carbon atoms is preferable, and an alkyl group having 1 to 8 carbon atoms is more preferable.

As the alkenyl group represented by R₃ and R₄, for example, an alkenyl group having 2 to 12 carbon atoms is preferable, and an alkenyl group having 2 to 8 carbon atoms is more preferable.

As the cycloalkyl group represented by R₃ and R₄, for example, a cycloalkyl group having 6 to 12 carbon atoms is preferable, and a cycloalkyl group having 6 to 8 carbon atoms is more preferable.

As the cycloalkenyl group represented by R₃ and R₄, for example, a cycloalkenyl group having 3 to 12 carbon atoms is preferable, and a cycloalkenyl group having 6 to 8 carbon atoms is more preferable.

The ring formed of R₃ and R₄ bonded to each other is a cyclic ketone structure, which may be a saturated cyclic ketone or an unsaturated cyclic ketone. The cyclic ketone is preferably a 6- to 10-membered ring, and more preferably a 6- to 8-membered ring.

It is preferable that R₃ and R₄ satisfy a relationship in which the number of carbon atoms in the compound represented by Formula II is equal to or greater than 8.

In Formula III, R₅ represents an alkyl group or a cycloalkyl group.

As the alkyl group represented by R₅, an alkyl group having 6 or more carbon atoms is preferable, an alkyl group having 6 to 12 carbon atoms is more preferable, and an alkyl group having 6 to 10 carbon atoms is particularly preferable.

The alkyl group may have an ether bond in the chain thereof or may have a substituent such as a hydroxyl group.

As the cycloalkyl group represented by R₅, a cycloalkyl group having 6 or more carbon atoms is preferable, a cycloalkyl group having 6 to 12 carbon atoms is more preferable, and a cycloalkyl group having 6 to 10 carbon atoms is particularly preferable.

In Formula IV, R₆ and R₇ each independently represent an alkyl group or a cycloalkyl group. Alternatively, R₆ and R₇ may be bonded to each other to form a ring.

As the alkyl group represented by R₆ and R₇, an alkyl group having 1 to 12 carbon atoms is preferable, and an alkyl group having 1 to 8 carbon atoms is more preferable.

As the cycloalkyl group represented by R₆ and R₇, for example, a cycloalkyl group having 6 to 12 carbon atoms is preferable, and a cycloalkyl group having 6 to 8 carbon atoms is more preferable.

The ring formed of R₆ and R₇ bonded to each other is a cyclic ether structure. The cyclic ether structure is preferably a 4- to 8-membered ring, and more preferably a 5- to 7-membered ring.

It is preferable that R₆ and R₇ satisfy a relationship in which the number of carbon atoms in the compound represented by Formula IV is equal to or greater than 8.

In Formula V, R₈ and R₉ each independently represent an alkyl group or a cycloalkyl group. Alternatively, R₈ and R₉ may be bonded to each other to form a ring. L represents a single bond or an alkylene group.

As the alkyl group represented by R₈ and R₉, an alkyl group having 6 to 12 carbon atoms is preferable, and an alkyl group having 6 to 10 carbon atoms is more preferable.

As the cycloalkyl group represented by R₈ and R₉, for example, a cycloalkyl group having 6 to 12 carbon atoms is preferable, and a cycloalkyl group having 6 to 10 carbon atoms is more preferable.

The ring formed of R₈ and R₉ bonded to each other is a cyclic diketone structure. The cyclic diketone structure is preferably a 6- to 12-membered ring, and more preferably a 6- to 10-membered ring.

As the alkylene group represented by L, for example, an alkylene group having 1 to 12 carbon atoms is preferable, and an alkylene group having 1 to 10 carbon atoms is more preferable.

R₈, R₉, and L satisfy a relationship in which the number of carbon atoms in the compound represented by Formula V is equal to or greater than 8.

The organic impurities are not particularly limited. However, in a case where the organic solvent is an amide compound, an imide compound, or a sulfoxide compound, in an aspect, examples of the organic impurities include an amide compound, an imide compound, and a sulfoxide compound having 6 or more carbon atoms. Examples of the organic impurities also include the following compounds.

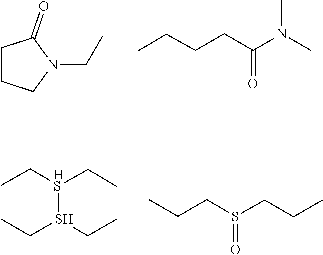

Examples of the organic impurities also include unreacted raw materials, structural isomers and byproducts generated during the manufacturing the organic solvent, and the like.

Examples of organic impurities also include tris(2-ethylhexyl) trimellitate (TEHTM), tris(n-octyl-n-decyl) trimellitate (ATM), dibutyl sebacate (DBS), dibutyl maleate (DBM), diisobutyl maleate (DIBM), an azelaic acid ester, a benzoic acid ester, terephthalate (such as dioctyl terephthalate (DEHT)), diisononyl 1,2-cyclohexanedicarboxylic acid ester (DINCH), epoxidized vegetable oil, sulfonamide (such as N-(2-hydroxypropyl)benzenesulfonamide (HP BSA) and N-(n-butyl)benzenesulfonamide (BB SA-NBBS)), acetylated monoglyceride, triethyl citrate (TEC), triethyl acetylcitrate (ATEC), tributyl citrate (TBC), tributyl acetylcitrate (ATBC), trioctyl citrate (TOC), acetyl trioctyl citrate (ATOC), trihexyl citrate (THC), trihexyl acetylcitrate (ATHC) epoxidized soybean oil, ethylene propylene rubber, polybutene, a 5-ethylidene-2-norbornene adduct polymer, polymer plasticizers exemplified below, and the like.

Presumably, these organic impurities may be mixed into the substance to be purified or the chemical liquid from a filter, piping, a tank, an O-ring, a container, and the like that come into contact with the substance to be purified or the chemical liquid in a purification step. Particularly, compounds other than alkyl olefin are involved in the occurrence of a bridge defect.

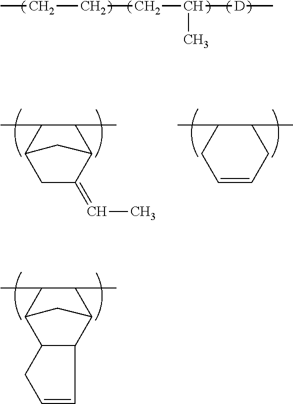

[Metal Impurities]

The present chemical liquid contains metal impurities (metal components). Examples of the metal impurities include metal-containing particles and metal ions. For example, the content of the metal impurities means the total amount of metal-containing particles and metal ions.

Although a suitable aspect of the chemical liquid manufacturing method will be described later, the chemical liquid can be generally manufactured by purifying a substance to be purified containing the solvent and the organic compound described above. The metal impurities may be intentionally added in the chemical liquid manufacturing process, may be contained in the substance to be purified from the first, or may migrate from a chemical liquid manufacturing device or the like (so-called contamination) in the chemical liquid manufacturing process.

The content of the metal impurities with respect to the total mass of the present chemical liquid is preferably 0.1 to 2,000 mass ppt. In view of excellent stability of the chemical liquid, the content of the metal impurities is more preferably 0.1 to 1,500 mass ppt, and particularly preferably 1 to 1,500 mass ppt.

The content of the metal impurities is measured by ICP-MS which will be described later.

<Metal-Containing Particles>

The present chemical liquid may contain metal-containing particles containing metal atoms.

The metal atoms are not particularly limited, and examples thereof include lead (Pb) atoms, sodium (Na) atoms, potassium (K) atoms, calcium (Ca) atoms, iron (Fe) atoms, copper (Cu) atoms, magnesium (Mg) atoms, manganese (Mn) atoms, lithium (Li) atoms, aluminum (Al) atoms, chromium (Cr) atoms, nickel (Ni) atoms, titanium (Ti) atoms, zinc (Zn) atoms, and zirconium (Zr) atoms. Among these, Fe atoms, Al atoms, Cr atoms, Ni atoms, Pb atoms, Ti atoms, and the like are preferable.

Particularly, in a case where the content of the metal-containing particles containing Fe atoms, Al atoms, and Ti atoms in the chemical liquid is strictly controlled, it is easy to obtain higher defect inhibition performance. In a case where the content of the metal-containing particles containing Fe atoms in the chemical liquid is strictly controlled, it is easy to obtain much higher defect inhibition performance.

That is, the metal atoms are preferably at least one kind of atoms selected from the group consisting of Fe atoms, Al atoms, Cr atoms, Ni atoms, Pb atoms, Ti atoms, and the like, and more preferably at least one kind of atoms selected from the group consisting of Fe atoms, Al atoms, and Ti atoms.

The metal-containing particles may contain one kind of the above metal atoms or two or more kinds of the above metal atoms in combination.

Furthermore, the metal-containing particles may contain an organic compound (for example, a component derived from the aforementioned organic impurities) in addition to the metal atoms.

The particle size of the metal-containing particles is not particularly limited. For example, in a chemical liquid for manufacturing semiconductor devices, the content of particles having a particle size of about 0.1 to 100 nm in the chemical liquid is controlled in many cases.

Through studies, the inventors of the present invention have found that particularly in a chemical liquid used for a photoresist process of extreme ultraviolet (EUV) exposure, in a case where the content of metal-containing particles having a particle size of 0.5 to 17 nm (hereinafter, also called “metal nanoparticles”) in the chemical liquid is controlled, it is easy to obtain a chemical liquid having excellent defect inhibition performance. In the photoresist process of EUV exposure, a fine resist interval, a fine resist width, and a fine resist pitch are required in many cases. In these cases, the number of finer particles that was not considered as a critical issue in the conventional process needs to be controlled.

The number-based particle size distribution of the metal-containing particles is not particularly limited. However, in view of obtaining a chemical liquid having further improved effects of the present invention, it is preferable that the metal-containing particles have a maximum particle size in at least one range selected from the group consisting of a range of particle size less than 5 nm and a range of particle size larger than 17 nm.

In other words, it is preferable that the metal-containing particles do not have a maximum particle size in a range of particle size of 5 to 17 nm. In a case where the metal-containing particles do not have a maximum particle size in a range of particle size of 5 to 17 nm, the defect inhibition performance, particularly, the bridge defect inhibition performance of the chemical liquid is further improved. The bridge defect means a defect in the form of a crosslink between wiring patterns.

In addition, in view of obtaining a chemical liquid having further improved effects of the present invention, it is particularly preferable that the metal-containing particles have a maximum particle size in a range of particle size equal to or greater than 0.5 nm and less than 5 nm in the number-based particle size distribution. In a case where the metal-containing particles have a maximum particle size in the above range, the chemical liquid has further improved bridge defect inhibition performance.

The content of the metal-containing particles with respect to the total mass of the present chemical liquid is preferably 0.01 to 1,000 mass ppt, more preferably 0.1 to 500 mass ppt, and particularly preferably 0.1 to 100 mass ppt. In a case where the content of the metal-containing particles is within the above range, a chemical liquid having excellent defect inhibition performance is obtained.

The type and content of the metal-containing particles in the chemical liquid can be measured by single particle inductively coupled plasma mass spectrometry (SP-ICP-MS).

The device used in SP-ICP-MS is the same as the device used in general inductively coupled plasma mass spectrometry (ICP-MS). The only difference between SP-ICP-MS and ICP-MS is how to analyze data. With SP-ICP-MS, data can be analyzed using commercial software.

With ICP-MS, the content of metal impurities (metal components) as a measurement target is measured regardless of the way the metal impurities are present. Accordingly, the total mass of metal-containing particles and metal ions as a measurement target is quantified as the content of the metal impurities.

With SP-ICP-MS, the content of metal-containing particles can be measured. Accordingly, by subtracting the content of the metal-containing particles from the content of the metal impurities in a sample, the content of metal ions in the sample can be calculated.

Examples of the device for SP-ICP-MS include Agilent 8800 triple quadrupole inductively coupled plasma mass spectrometry (ICP-MS, for semiconductor analysis, option #200) manufactured by Agilent Technologies, Inc. By using this device, the content of the metal-containing particles can be measured by the method described in Examples. In addition to the device described above, it is possible to use NexION350S manufactured by PerkinElmer Inc. and Agilent 8900 manufactured by Agilent Technologies, Inc.

(Metal Nanoparticles)

Among the metal-containing particles, particles having a particle size of 0.5 to 17 nm are called metal nanoparticles.

The number of metal nanoparticles contained in a unit volume of the present chemical liquid is preferably 1.0×10⁻¹ to 1.0×10¹³ particles/cm³, more preferably 1.0×10 to 1.0×10¹² particles/cm³, and particularly preferably 1.0×10 to 1.0×10¹¹ particles/cm³. In a case where number of metal nanoparticles contained in the chemical liquid is equal to or greater than 1.0×10 particles/cm³, the chemical liquid has excellent stability. In a case where number of metal nanoparticles contained in the chemical liquid is equal to or less than 1.0×10¹² particles/cm³, excellent residue inhibition performance is obtained.

The content of the metal nanoparticles in the chemical liquid can be measured by the method described in Examples. The number of metal nanoparticles (number) per unit volume of the chemical liquid is rounded off such that the number includes two significant digits.

The metal atoms contained in the metal nanoparticles are not particularly limited and the same as the atoms described above as metal atoms contained in the metal-containing particles. Particularly, in view of obtaining a chemical liquid having further improved effects of the present invention, the metal atoms are preferably at least one kind of metal atoms selected from the group consisting of Fe atoms, Al atoms, and Ti atoms, and particularly preferably Fe atoms.

The metal nanoparticles may contain a plurality of atoms. For example, the metal nanoparticles contain Fe atoms, Al atoms, and Ti atoms typically in a case where the chemical liquid contains all of metal nanoparticles containing Fe atoms, metal nanoparticles containing Al atoms, and metal nanoparticles containing Ti atoms.

As long as the metal nanoparticles contain metal atoms, the form of the metal nanoparticles is not particularly limited. For example, the metal nanoparticles may be in the form of simple metal atoms, compounds containing metal atoms (hereinafter, also called “metal compound”), a complex of these, and the like. Furthermore, the metal nanoparticles may contain a plurality of metal atoms. In a case where the metal nanoparticles contain a plurality of metals, among the plurality of metals, metal atoms at the highest content (atm %) are regarded as a main component. Therefore, in a case where metal nanoparticles containing a plurality of metals are called by the name of iron nanoparticles (Fe nanoparticles), the name means that iron atoms (Fe atoms) are the main component among the plurality of metals.

The complex is not particularly limited, and examples thereof include a so-called core-shell type particle having a simple metal atom and a metal compound covering at least a portion of the simple metal atom, a solid solution particle including a metal atom and another atom, a eutectic particle including a metal atom and another atom, an aggregate particle of a simple metal atom and a metal compound, an aggregate particle of different kinds of metal compounds, a metal compound in which the composition thereof continuously or intermittently changes toward the center of the particle from the surface of the particle, and the like.

The atom other than the metal atom contained in the metal compound is not particularly limited, and examples thereof include a carbon atom, an oxygen atom, a nitrogen atom, a hydrogen atom, a sulfur atom, a phosphorus atom, and the like. Among these, an oxygen atom is preferable. The form of the metal compound containing an oxygen atom is not particularly limited. However, the metal compound is more preferably an oxide of a metal atom.

Furthermore, the metal nanoparticles may contain an organic compound (for example, a component derived from the aforementioned organic impurities) in addition to the metal atoms.

In view of obtaining a chemical liquid having further improved effects of the present invention, it is preferable that the metal nanoparticles consist of at least one kind of particles selected from the group consisting of particles consisting of simple metal atoms, particles consisting of oxides of metal atoms, particles consisting of simple metal atoms and oxides of metal atoms, and particles consisting of oxides of metal atoms and an organic compound.

The present chemical liquid may contain first iron oxide nanoparticles consisting of iron oxide (that is, particles consisting of iron oxide having a particle size of 0.5 to 17 nm). In this case, the number of the first iron oxide nanoparticles contained in a unit volume of the chemical liquid is preferably 1 to 1.0×10¹² particles/cm³, more preferably 10 to 1.0×10¹¹ particles/cm³, and particularly preferably 10² to 10¹⁰ particles/cm³. In a case where the number of the above particles contained in the chemical liquid is equal to or greater than 10 particles/cm³, the metal impurity-containing defects (particularly, metal atom-containing defects) are further inhibited. In a case where the number of the above particles contained in the chemical liquid is equal to or less than 1.0×10¹¹ particles/cm³, the metal impurity-containing defects (particularly, defects containing both the organic impurities and metal impurities) are further inhibited.

The present chemical liquid may contain second iron oxide nanoparticles containing iron oxide and an organic compound (that is, particles containing iron oxide and an organic compound and having a particle size of 0.5 to 17 nm). Examples of the organic compound include the aforementioned organic impurities and components derived from the organic impurities.

In this case, the ratio of the number of the second iron oxide nanoparticles contained in a unit volume of the chemical liquid to the number of the first iron oxide nanoparticles contained in a unit volume of the chemical liquid (number of second iron oxide nanoparticles contained in chemical liquid/number of first iron oxide nanoparticles contained in chemical liquid) is preferably 1 to 10⁹, more preferably from 10 to 10⁸, and particularly preferably 10 to 10⁷. In a case where the ratio is within a range of 10 to 10⁸, the metal impurity-containing defects (particularly, defects containing oxides of metal atoms) are further inhibited.

The present chemical liquid may contain at least one kind of metal nanoparticles selected from the group consisting of iron nanoparticles containing iron atoms (hereinafter, also called “Fe nanoparticles”), aluminum nanoparticles containing aluminum atoms (hereinafter, also called “Al nanoparticles”), and titanium nanoparticles containing titanium atoms (hereinafter, also called “Ti nanoparticles”).

In this case, the total number of Fe nanoparticles, Al nanoparticles, and Ti nanoparticles contained in a unit volume of the chemical liquid is preferably 1 to 1.0×10¹⁵ particles/cm³, and more preferably 1 to 1.0×10¹³ particles/cm³. In a case where the number of the above particles contained in the chemical liquid is within the above range, the residue inhibition performance is further improved.

<Metal Ions>

The present chemical liquid may contain metal ions.

Examples of the metal ions include ions of metal atoms such as Pb (lead), Na (sodium), K (potassium), Ca (calcium), Fe (iron), Cu (copper), Mg (magnesium), Mn (manganese), Li (lithium), Al (aluminum), Cr (chromium), Ni (nickel), Ti (titanium), Zn (zinc), and Zr (zirconium).

The content of the metal ions with respect to the total mass of the present chemical liquid is preferably 0.01 to 2,000 mass ppt, more preferably 0.1 to 1,000 mass ppt, and particularly preferably 0.1 300 mass ppt. In a case where the content of the metal ions is equal to or greater than 0.01 mass ppt, the metal impurity-containing defects (particularly, metal atom-containing defects) are further inhibited. In a case where the content of the metal ions is equal to or less than 2,000 mass ppm, the chemical liquid has excellent stability.

As described above, the content of the metal ions in the chemical liquid is determined by subtracting the content of the metal-containing particles measured by SP-ICP-MS from the content of the metal impurities in the chemical liquid measured by ICP-MS.

<Water>

The present chemical liquid may contain water. The water is not particularly limited, and examples thereof include distilled water, deionized water, pure water, and the like.

Water may be added to the chemical liquid or may be unintentionally mixed into the chemical liquid in the process of manufacturing the chemical liquid. Examples of the case where water is unintentionally mixed with the chemical liquid in the process of manufacturing the chemical liquid include a case where water is contained in a raw material (for example, an organic solvent) used for manufacturing the chemical liquid, a case where water is mixed with the chemical liquid in the process of manufacturing the chemical liquid (for example, contamination), and the like. However, the present invention is not limited to these.

The content of water with respect to the total mass of the present chemical liquid is preferably 0.001% to 0.10% by mass, more preferably 0.005% to 0.1% by mass, and particularly preferably 0.01% to 0.1% by mass. In a case where the content of water is within the above range, the residue inhibition performance is further improved.

The content of water in the present chemical liquid means the content of water measured using a device which adopts the Karl Fischer titration method as the principle of measurement.

The mass ratio of the content of water to the total content of the alcohol and the acetone as organic impurities (content of water/total content of alcohol and acetone) is preferably 0.1 to 10¹⁰, more preferably 1 to 10⁹, and particularly preferably 1 to 10⁸. In a case where the mass ratio is within a range of 1 to 10⁹, at least the stability of the chemical liquid or the performance of inhibiting metal impurity-containing defects is further improved.

The mass ratio of the content of water to the content of the aforementioned stabilizer (content of water/content of stabilizer) is preferably 10 to 10⁵, more preferably 10 to 10⁴, and particularly preferably 10² to 10⁴. In a case where the mass ratio is equal to or higher than 10, the chemical liquid has excellent stability. In a case where the mass ratio is equal to or lower than 10⁵, excellent defect inhibition performance is obtained.

[Other Components]

The present chemical liquid may contain components other than the above. Examples of those other components include a resin and the like.

(Resin)

The present chemical liquid may contain a resin. As the resin, a resin P having a group which is decomposed by the action of an acid and generates a polar group is more preferable. As such a resin, a resin having a repeating unit represented by Formula (AI) that will be described later is more preferable, which is a resin whose solubility in a developer containing an organic solvent as a main component is reduced by the action of an acid. The resin having a repeating unit represented by Formula (AI), which will be described later, has a group that is decomposed by the action of an acid and generates an alkali-soluble group (hereinafter, also called “acid-decomposable group”).

Examples of the polar group include an alkali-soluble group. Examples of the alkali-soluble group include a carboxyl group, a fluorinated alcohol group (preferably a hexafluoroisopropanol group), a phenolic hydroxyl group, and a sulfo group.

In the acid-decomposable group, the polar group is protected with a group dissociated by an acid (acid-dissociable group). Examples of the acid-dissociable group include —C(R₃₆)(R₃₇)(R₃₈), —C(R₃₆)(R₃₇)(OR₃₉), —C(R₀₁)(R₀₂)(OR₃₉), and the like.

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

Hereinafter, the resin P whose solubility in a developer containing an organic solvent as a main component is reduced by the action of an acid will be specifically described.

((Formula (AI): Repeating Unit Having Acid-Decomposable Group))

It is preferable that the resin P contain a repeating unit represented by Formula (AI).

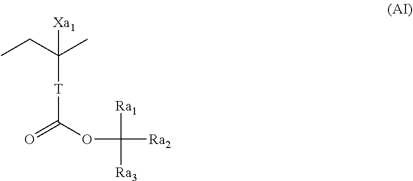

In Formula (AI), Xa₁ represents a hydrogen atom or an alkyl group which may have a substituent.

T represents a single bond or a divalent linking group.

Ra₁ to Ra₃ each independently represent an alkyl group (linear or branched) or a cycloalkyl group (monocyclic or polycyclic).

Two out of Ra₁ to Ra₃ may be bonded to each other to form a cycloalkyl group (monocyclic or polycyclic).

Examples of the alkyl group which is represented by Xa₁ and may have a substituent include a methyl group and a group represented by —CH₂—R₁₁. R₁₁ represents a halogen atom (such as a fluorine atom), a hydroxyl group, or a monovalent organic group.

Xa₁ is preferably a hydrogen atom, a methyl group, a trifluoromethyl group, or a hydroxymethyl group.

Examples of the divalent linking group represented by T include an alkylene group, a —COO-Rt-group, a —O-Rt-group, and the like. In the formulae, Rt represents an alkylene group or a cycloalkylene group.

T is preferably a single bond or a —COO-Rt-group. Rt is preferably an alkylene group having 1 to 5 carbon atoms, and more preferably a —CH₂— group, a —(CH₂)₂— group, or a —(CH₂)₃— group.

The alkyl group represented by Ra₁ to Ra₃ preferably has 1 to 4 carbon atoms.

The cycloalkyl group represented by Ra₁ to Ra₃ is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group.

The cycloalkyl group formed by the bonding of two groups out of Ra₁ to Ra₃ is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group. The cycloalkyl group is more preferably a monocyclic cycloalkyl group having 5 or 6 carbon atoms.

In the cycloalkyl group formed by the bonding of two groups out of Ra₁ to Ra₃, for example, one methylene group constituting the ring may be substituted with a heteroatom such as an oxygen atom or a group having a heteroatom such as a carbonyl group.

As the repeating unit represented by Formula (AI), for example, an aspect is preferable in which Ra₁ is a methyl group or an ethyl group, and Ra₂ and Ra₃ are bonded to each other to form the aforementioned cycloalkyl group.

Each of the above groups may have a substituent. Examples of the substituent include an alkyl group (having 1 to 4 carbon atoms), a halogen atom, a hydroxyl group, an alkoxy group (having 1 to 4 carbon atoms), a carboxyl group, an alkoxycarbonyl group (having 2 to 6 carbon atoms), and the like. The number of carbon atoms in the substituent is preferably equal to or smaller than 8.

The content of the repeating unit represented by Formula (AI) with respect to all the repeating units in the resin P is preferably 20 to 90 mol %, more preferably 25 to 85 mol %, and particularly preferably 30 to 80 mol %.

((Repeating Unit Having Lactone Structure))

It is preferable that the resin P contain a repeating unit Q having a lactone structure.

The repeating unit Q having a lactone structure preferably has a lactone structure on a side chain. The repeating unit Q is more preferably a repeating unit derived from a (meth)acrylic acid derivative monomer.

One kind of repeating unit Q having a lactone structure may be used singly, or two or more kinds of repeating units Q may be used in combination. It is preferable to use one kind of repeating unit Q.

The content of the repeating unit Q having a lactone structure with respect to all the repeating units in the resin P is preferably 3 to 80 mol %, and more preferably 3 to 60 mol %.

The lactone structure is preferably a 5- to 7-membered lactone structure, and more preferably a structure in which another ring structure is fused with a 5- to 7-membered lactone structure by forming a bicyclo structure or a Spiro structure.

It is preferable that the lactone structure have a repeating unit having a lactone structure represented by any of Formulae (LC1-1) to (LC1-17). As the lactone structure, a lactone structure represented by Formula (LC1-1), Formula (LC1-4), Formula (LC1-5), or Formula (LC1-8) is preferable, and a lactone structure represented by Formula (LC1-4) is more preferable.

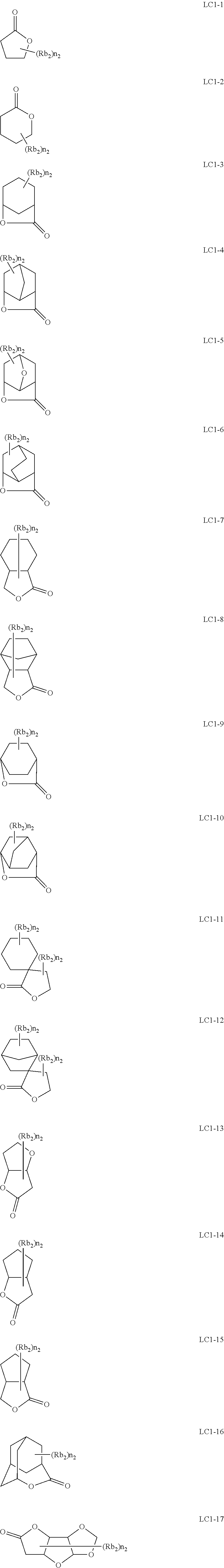

The lactone structure portion may have a substituent (Rb₂). As the substituent (Rb₂), for example, an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, an acid-decomposable group, and the like are preferable. n₂ represents an integer of 0 to 4. In a case where n₂ is equal to or greater than 2, a plurality of substituents (Rb₂) may be the same as or different from each other, and a plurality of substituents (Rb₂) may be bonded to each other to form a ring.

((Repeating Unit Having Phenolic Hydroxyl Group))

The resin P may contain a repeating unit having a phenolic hydroxyl group.

Examples of the repeating unit having a phenolic hydroxyl group include a repeating unit represented by General Formula (I).

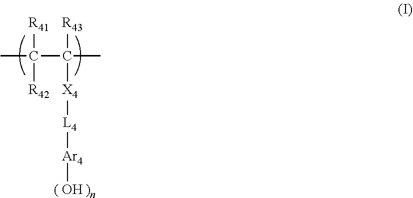

In the formula, R₄₁, R₄₂, and R₄₃ each independently represent a hydrogen atom, an alkyl group, a halogen atom, a cyano group, or an alkoxycarbonyl group. Here, R₄₂ and Ar₄ may be bonded to each other to form a ring. In this case, R₄₂ represents a single bond or an alkylene group.

X₄ represents a single bond, —COO—, or —CONR₆₄—, and R₆₄ represents a hydrogen atom or an alkyl group.

L₄ represents a single bond or an alkylene group.

Ar₄ represents an (n+1)-valent aromatic ring group. In a case where Ar₄ is bonded to R₄₂ to form a ring, Ar₄ represents an (n+2)-valent aromatic ring group.

n represents an integer of 1 to 5.

The alkyl group represented by R₄₁, R₄₂, and R₄₃ in General Formula (I) is preferably an alkyl group having 20 or less carbon atoms such as a methyl group, an ethyl group, a propyl group, an isopropyl group, a n-butyl group, a sec-butyl group, a hexyl group, a 2-ethylhexyl group, an octyl group, or a dodecyl group which may have a substituent, more preferably an alkyl group having 8 or less carbon atoms, and particularly preferably an alkyl group having 3 or less carbon atoms.

The cycloalkyl group represented by R₄₁, R₄₂, and R₄₃ in General Formula (I) may be monocyclic or polycyclic. The cycloalkyl group is preferably a monocyclic cycloalkyl group having 3 to 8 carbon atoms such as a cyclopropyl group, a cyclopentyl group, or a cyclohexyl group which may have a substituent.

Examples of the halogen atom represented by R₄₁, R₄₂, and R₄₃ in General Formula (I) include a fluorine atom, a chlorine atom, a bromine atom, and an iodine atom. Among these, a fluorine atom is preferable.

As the alkyl group contained in the alkoxycarbonyl group represented by R₄₁, R₄₂, and R₄₃ in General Formula (I), the same alkyl group as the alkyl group represented by R₄₁, R₄₂, and R₄₃ described above is preferable.

Examples of the substituent in each of the above groups include an alkyl group, a cycloalkyl group, an aryl group, an amino group, an amide group, a ureide group, a urethane group, a hydroxyl group, a carboxyl group, a halogen atom, an alkoxy group, a thioether group, an acyl group, an acyloxy group, an alkoxycarbonyl group, a cyano group, a nitro group, and the like. The number of carbon atoms in the substituent is preferably equal to or smaller than 8.

Ara represents an (n+1)-valent aromatic ring group. Examples of a divalent aromatic ring group obtained in a case where n is 1 include an arylene group having 6 to 18 carbon atoms such as a phenylene group, a tolylene group, a naphthylene group, or an anthracenylene group which may have a substituent and an aromatic ring group containing a hetero ring such as thiophene, furan, pyrrole, benzothiophene, benzofuran, benzopyrrole, triazine, imidazole, benzimidazole, triazole, thiadiazole, or thiazole.

Specific examples of the (n+1)-valent aromatic ring group obtained in a case where n is an integer equal to or greater than 2 include groups obtained by removing (n−1) pieces of any hydrogen atoms from the specific examples of the divalent aromatic ring group described above.

The (n+1)-valent aromatic ring group may further have a substituent.

Examples of the substituent that the alkyl group, the cycloalkyl group, the alkoxycarbonyl group, the alkylene group, and the (n+1)-valent aromatic ring group described above can have include the alkyl group exemplified above as R₄₁, R₄₂, and R₄₃ in General Formula (I); an alkoxy group such as a methoxy group, an ethoxy group, a hydroxyethoxy group, a propoxy group, a hydroxypropoxy group, or a butoxy group; and an aryl group such as a phenyl group.

Examples of the alkyl group represented by R₆₄ in —CONR₆₄— (R₆₄ represents a hydrogen atom or an alkyl group) represented by X₄ include an alkyl group having 20 or less carbon atoms such as a methyl group, an ethyl group, a propyl group, an isopropyl group, a n-butyl group, a sec-butyl group, a hexyl group, a 2-ethylhexyl group, an octyl group, or a dodecyl group which may have a substituent. Among these, an alkyl group having 8 or less carbon atoms is more preferable.

X₄ is preferably a single bond, —COO—, or —CONH—, and more preferably a single bond or —COO—.

The alkylene group represented by L₄ is preferably an alkylene group having 1 to 8 carbon atoms such as a methylene group, an ethylene group, a propylene group, a butylene group, a hexylene group, or an octylene group which may have a substituent.

Ar₄ is preferably an aromatic ring group having 6 to 18 carbon atoms that may have a substituent, and more preferably a benzene ring group, a naphthalene ring group, or a biphenylene ring group.

It is preferable that the repeating unit represented by General Formula (I) comprise a hydroxystyrene structure. That is, Ar₄ is preferably a benzene ring group.

The content of the repeating unit having a phenolic hydroxyl group with respect to all the repeating units in the resin P is preferably 0 to 50 mol %, more preferably 0 to 45 mol %, and particularly preferably 0 to 40 mol %.

((Repeating Unit Containing Organic Group Having Polar Group))

The resin P may further contain a repeating unit containing an organic group having a polar group, particularly, a repeating unit having an alicyclic hydrocarbon structure substituted with a polar group. In a case where the resin P further contains such a repeating unit, the substrate adhesiveness and the affinity with a developer are improved.

As the alicyclic hydrocarbon structure substituted with a polar group, an adamantyl group, a diamantyl group, or a norbornane group is preferable. As the polar group, a hydroxyl group or a cyano group is preferable.

In a case where the resin P contains the repeating unit containing an organic group having a polar group, the content of the repeating unit with respect to all the repeating units in the resin P is preferably 1 to 50 mol %, more preferably 1 to 30 mol %, even more preferably 5 to 25 mol %, and particularly preferably 5 to 20 mol %.

((Repeating Unit Represented by General Formula (VI))

The resin P may contain a repeating unit represented by General Formula (VI).

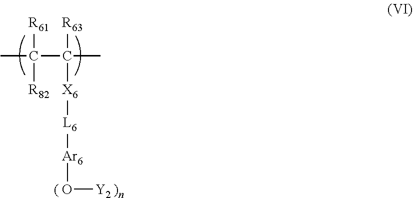

In General Formula (VI), R₆₁, R₆₂, and R₆₃ each independently represent a hydrogen atom, an alkyl group, a cycloalkyl group, a halogen atom, a cyano group, or an alkoxycarbonyl group. Here, R₆₂ may be bonded to Ar₆ to form a ring, and in this case, R₆₂ represents a single bond or an alkylene group.

X₆ represents a single bond, —COO—, or —CONR₆₄—. R₆₄ represents a hydrogen atom or an alkyl group.

L₆ represents a single bond or an alkylene group.

Ar₆ represents an (n+1)-valent aromatic ring group. In a case where Ar₆ is bonded to R₆₂ to form a ring, Ar₆ represents an (n+2)-valent aromatic ring group.

In a case where n≥2, Y₂ each independently represents a hydrogen atom or a group which is dissociated by the action of an acid. Here, at least one of Y₂'s represents a group which is dissociated by the action of an acid.

n represents an integer of 1 to 4.

As the group Y₂ which is dissociated by the action of an acid, a structure represented by General Formula (VI-A) is preferable.

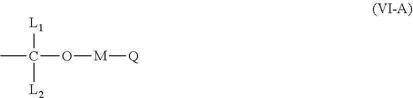

L₁ and L₂ each independently represent a hydrogen atom, an alkyl group, a cycloalkyl group, an aryl group, or a group obtained by combining an alkylene group and an aryl group.

M represents a single bond or a divalent linking group.

Q represents an alkyl group, a cycloalkyl group which may contain a heteroatom, an aryl group which may contain a heteroatom, an amino group, an ammonium group, a mercapto group, a cyano group, or an aldehyde group.

At least two out of Q, M, and Li may be bonded to each other to form a ring (preferably a 5- or 6-membered ring).

The repeating unit represented by General Formula (VI) is preferably a repeating unit represented by General Formula (3).

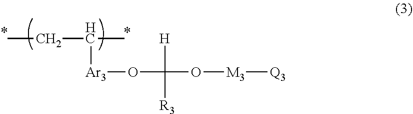

In General Formula (3), Ar₃ represents an aromatic ring group.

R₃ represents a hydrogen atom, an alkyl group, a cycloalkyl group, an aryl group, an aralkyl group, an alkoxy group, an acyl group, or a heterocyclic group.

M₃ represents a single bond or a divalent linking group.

Q₃ represents an alkyl group, a cycloalkyl group, an aryl group, or a heterocyclic group.

At least two out of Q₃, M₃, and R₃ may be bonded to each other to form a ring.

The aromatic ring group represented by Ar₃ is the same as Ar₆ in General Formula (VI) in which n is 1. Ar₃ is preferably a phenylene group or a naphthylene group, and more preferably a phenylene group.

((Repeating Unit Having Silicon Atom on Side Chain))

The resin P may further contain a repeating unit having a silicon atom on a side chain. Examples of the repeating unit having a silicon atom on a side chain include a (meth)acrylate-based repeating unit having a silicon atom, a vinyl-based repeating unit having a silicon atom, and the like. Typically, the repeating unit having a silicon atom on a side chain is a repeating unit having a group having a silicon atom on a side chain. Examples of the group having a silicon atom include a trimethylsilyl group, a triethylsilyl group, a triphenylsilyl group, a tricyclohexylsilyl group, a tristrimethylsiloxysilyl group, a tristrimethylsilyl silyl group, a methyl bistrimethylsilyl silyl group, a methyl bistrimethylsiloxysilyl group, a dimethyltrimethylsilyl silyl group, a dimethyl trimethylsiloxysilyl group, cyclic or linear polysiloxane shown below, a cage-like, ladder-like, or random silsesquioxane structure, and the like. In the formulae, R and R¹ each independently represent a monovalent substituent. * represents a bond.

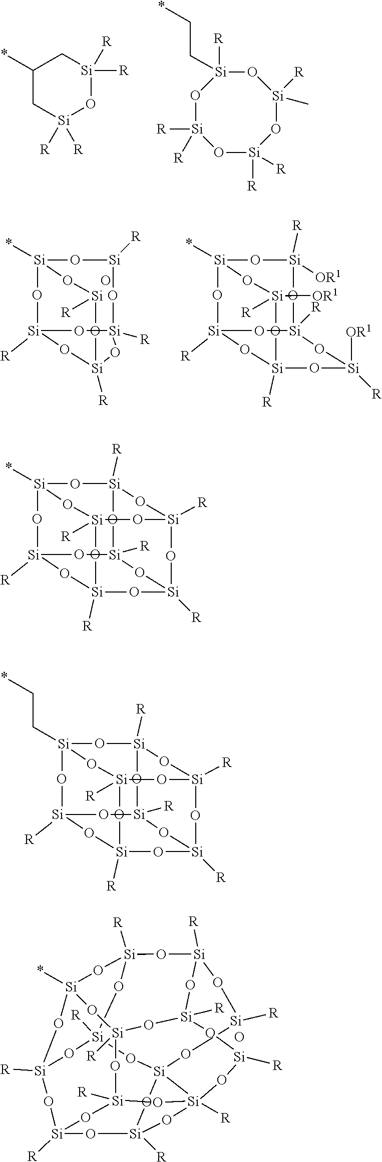

As the repeating unit having the aforementioned group, for example, a repeating unit derived from an acrylate or methacrylate compound having the aforementioned group or a repeating unit derived from a compound having the aforementioned group and a vinyl group is preferable.

In a case where the resin P has the repeating unit having a silicon atom on a side chain, the content of the repeating unit with respect to all the repeating units in the resin P is preferably 1 to 30 mol %, more preferably 5 to 25 mol %, and particularly preferably 5 to 20 mol %.

The weight-average molecular weight of the resin P that is measured by gel permeation chromatography (GPC) and expressed in terms of polystyrene is preferably 1,000 to 200,000, more preferably 3,000 to 20,000, and particularly preferably 5,000 to 15,000. In a case where the weight-average molecular weight is 1,000 to 200,000, it is possible to prevent the deterioration of heat resistance and dry etching resistance, to prevent the deterioration of developability, and to prevent film forming properties from deteriorating due to the increase in viscosity.

The dispersity (molecular weight distribution) is generally 1 to 5, preferably 1 to 3, more preferably 1.2 to 3.0, and particularly preferably 1.2 to 2.0.

The content of the resin P in the total solid content of the chemical liquid is preferably 50% to 99.9% by mass, and more preferably 60% to 99.0% by mass.

In the chemical liquid, one kind of resin P may be used singly, or two or more kinds of resins P may be used in combination.

As other components (for example, an acid generator, a basic compound, a quencher, a hydrophobic resin, a surfactant, a solvent, and the like) to be incorporated into the present chemical liquid, any of known components can be used. Examples thereof include components contained in the actinic ray-sensitive or radiation-sensitive resin compositions described in JP2013-195844A, JP2016-057645A, JP2015-207006A, WO2014/148241A, JP2016-188385A, and JP2017-219818A, and the like.

[Number of Objects to be Counted in Chemical Liquid]

In the present chemical liquid, the number of objects to be counted having a size equal to or greater than 0.04 μm that are counted by a light scattering liquid-borne particle counter is preferably equal to or less than 2,000 particles/mL. In view of further inhibiting the metal impurity-containing defects (particularly, defects containing oxides of metal atoms), the number of objects to be counted is more preferably equal to or less than 100 particles/mL, and particularly preferably equal to or less than 50 particles/mL.

In the present specification, the objects to be counted having a size equal to or greater than 0.04 μm that are counted by a light scattering liquid-borne particle counter are also called “coarse particles”.

Examples of the coarse particles include, but are not limited to, dust, dirt, and particles of organic and inorganic solids and the like contained in raw materials (for example, an organic solvent) used for manufacturing the chemical liquid and dust, dirt, and solids (consisting of organic substances, inorganic substances, and/or metals) mixed in as contaminants in the process of preparing the chemical liquid, and the like.

The coarse particles also contain colloidized impurities containing metal atoms. The metal atoms are not particularly limited. However, in a case where the content of at least one kind of metal atoms selected from the group consisting of Na, K, Ca, Fe, Cu, Mg, Mn, Li, Al, Cr, Ni, Zn, and Pb is particularly low (for example, in a case where the content of each type of the above metal atoms in the organic solvent is equal to or less than 1,000 mass ppt), the impurities containing the metal atoms are easily colloidized.

[Use of Chemical Liquid]

It is preferable that the present chemical liquid be used for manufacturing semiconductor devices. Particularly, it is more preferable that the present chemical liquid be used for forming a fine pattern at a node equal to or smaller than 10 nm (for example, a step including pattern formation using EUV).

The present chemical liquid is particularly preferably used as a chemical liquid (a prewet solution, a developer, a rinsing solution, a solvent of a resist solution, a peeling solution, or the like) used in a resist process in which either or both of a pattern width and a pattern interval are equal to or smaller than 17 nm (preferably equal to or smaller than 15 nm and more preferably equal to or smaller than 12 nm) and/or either or both of the obtained wiring width and wiring interval are equal to or smaller than 17 nm. In other words, the present chemical liquid is particularly preferably used for manufacturing semiconductor devices manufactured using a resist film in which either or both of a pattern width and a pattern interval are equal to or smaller than 17 nm.

Specifically, in a semiconductor device manufacturing process including a lithography step, an etching step, an ion implantation step, a peeling step, and the like, after each step is finished or before the next step is started, the present chemical liquid is used for treating organic substances. To be concrete, the present chemical liquid is suitably used as a prewet solution, a developer, a rinsing solution, a peeling solution, or the like. For example, the present chemical liquid can be used for rinsing the edge line of semiconductor substrates before and after the coating with resist.

Furthermore, the present chemical liquid can also be used as a diluent for a resin contained in a resist solution and as a solvent contained in the resist solution. In addition, the present chemical liquid may be diluted with another organic solvent and/or water, and the like.

The present chemical liquid can also be used for other uses in addition to the manufacturing of semiconductor devices. The present chemical liquid can be used as a developer or a rinsing solution of polyimide, a resist for a sensor, a resist for a lens, and the like.

The present chemical liquid can also be used as a solvent for medical uses or for washing. Particularly, the present chemical liquid can be suitably used for washing containers, piping, substrates (for example, a wafer and glass), and the like.

The present chemical liquid is more effective particularly in a case where the present chemical liquid is used as a raw material of at least one kind of liquid selected from the group consisting of a developer, a rinsing solution, a wafer washing solution, a line washing solution, a prewet solution, a resist solution, a solution for forming an underlayer film, a solution for forming an overlayer film, and a solution for forming a hardcoat.

Particularly, in a case where the present chemical liquid is used as a raw material of at least one kind of liquid selected from the group consisting of a developer, a rinsing solution, a prewet solution, and a piping washing solution, higher effects are exerted.

[Chemical Liquid Manufacturing Method]

As the method for manufacturing the present chemical liquid, known methods can be used without particular limitation. Particularly, in view of obtaining a chemical liquid exhibiting further improved effects of the present invention, it is preferable that the method for manufacturing the present chemical liquid include a filtration step of filtering a substance to be purified containing a solvent by using a filter so as to obtain the present chemical liquid.

The substance to be purified used in the filtration step may be prepared by means of purchasing or the like or may be obtained by reacting raw materials. It is preferable that the content of impurities in the substance to be purified be small. Examples of commercial products of such a substance to be purified include those called “high-purity grade product”.

As the method for obtaining a substance to be purified (typically, a substance to be purified containing an organic solvent) by reacting raw materials, a known method can be used without particular limitation. Examples thereof include a method for obtaining an organic solvent by reacting a single raw material or a plurality of raw materials in the presence of a catalyst.

More specifically, examples of the method include a method for obtaining butyl acetate by reacting acetic acid and n-butanol in the presence of sulfuric acid; a method for obtaining 1-hexanol by reacting ethylene, oxygen, and water in the presence of Al(C₂H₅)₃; a method for obtaining 4-methyl-2-pentanol by reacting cis-4-methyl-2-pentene in the presence of diisopinocampheylborane (Ipc2BH); a method for obtaining propylene glycol 1-monomethyl ether 2-acetate (PGMEA) by reacting propylene oxide, methanol, and acetic acid in the presence of sulfuric acid; a method for obtaining isopropyl alcohol (IPA) by reacting acetone and hydrogen in the presence of copper oxide-zinc oxide-aluminum oxide; a method for obtaining ethyl lactate by reacting lactic acid and ethanol; and the like.

<Filtration Step>

The method for manufacturing the present chemical liquid according to an embodiment of the present invention includes a filtration step of filtering the aforementioned substance to be purified by using a filter so as to obtain the present chemical liquid. The method of filtering the substance to be purified by using a filter is not particularly limited. However, it is preferable to use a method of passing the substance to be purified through a filter unit (letting the substance to be purified run through a filter unit) including a housing and a filter cartridge stored in the housing under pressure or under no pressure.

(Pore Size of Filter)

The pore size of the filter is not particularly limited, and a filter having a pore size that is generally used for filtering the substance to be purified can be used. Particularly, in view of making it easier to control the number of particles (metal-containing particles and the like) contained in the present chemical liquid within a desired range, the pore size of the filter is preferably equal to or smaller than 200 nm, more preferably equal to or smaller than 20 nm, even more preferably equal to or smaller than 10 nm, particularly preferably equal to or smaller than 5 nm, and most preferably equal to or smaller than 3 nm. The lower limit thereof is not particularly limited. From the viewpoint of productivity, the lower limit is preferably equal to or greater than 1 nm in general.

In the present specification, the pore size of a filter and pore size distribution mean a pore size and pore size distribution determined by the bubble point of isopropanol (IPA) or HFE-7200 (“NOVEC 7200”, manufactured by 3M Company, hydrofluoroether, C₄F₉OC₂H₅).

In view of making it easier to control the number of particles contained in the present chemical liquid, it is preferable that the pore size of the filter be equal to or smaller than 5.0 nm. Hereinafter, a filter having a pore size equal to or smaller than 5 nm will be also called “microporous filter”.

The microporous filter may be used singly or used together with another filter having a different pore size. From the viewpoint of further improving productivity, it is particularly preferable to use the microporous filter with a filter having a larger pore size. In this case, in a case where the substance to be purified having been filtered through the filter with a larger pore size is passed through the microporous filter, the clogging of the microporous filter is prevented.

That is, regarding the pore size of the filter, in a case where one filter is used, the pore size is preferably equal to or smaller than 5.0 nm, and in a case where two or more filters are used, the pore size of a filter with the smallest pore size is preferably equal to or smaller than 5.0 nm.

The way the two or more kinds of filters having different pore sizes are used in order is not particularly limited. For example, a method may be used in which the filter units described above are arranged in order along a pipe line through which the substance to be purified is transferred. At this time, in a case where an attempt is made to set the flow rate of the substance to be purified per unit time to be constant throughout the entire pipe line, sometimes the pressure applied to a filter unit having a smaller pore size is higher than the pressure applied to a filter unit having a larger pore size. In this case, it is preferable to dispose a pressure control valve, a damper, or the like between the filter units such that constant pressure is applied to the filter unit having a smaller pore size, or to arrange filter units housing the same filters in a row along the pipe line such that the filtration area is enlarged. In a case where this method is used, it is possible to more stably control the number of particles in the present chemical liquid.

(Material of Filter)

As the material of the filter, materials known as filter materials can be used without particular limitation. Specifically, examples of the material of the filter include a resin like polyamide such as nylon (for example, 6-nylon and 6,6-nylon); polyolefin such as polyethylene and polypropylene; polystyrene; polyimide; polyamide imide; poly(meth)acrylate; polyfluorocarbon such as polytetrafluoroethylene, perfluoroalkoxyalkane, a perfluoroethylene propene copolymer, an ethylene-tetrafluoroethylene copolymer, an ethylene-chlorotrifluoroethylene copolymer, polychlorotrifluoroethylene, polyvinylidene fluoride, and polyvinyl fluoride; polyvinyl alcohol; polyester; cellulose; cellulose acetate, and the like. Among these, at least one kind of resin selected from the group consisting of nylon (particularly preferably 6,6-nylon), polyolefin (particularly preferably polyethylene), poly(meth)acrylate, and polyfluorocarbon (particularly preferably polytetrafluoroethylene (PTFE) and perfluoroalkoxyalkane (PFA)) is preferable, because this resin has higher solvent resistance and makes it possible to obtain the present chemical liquid having further improved defect inhibition performance. One kind of each of these polymers can be used singly, or two or more kinds of these polymers can be used in combination.

In addition to the resin, diatomite, glass, and the like may be used.

Furthermore, a polymer (such as nylon-grafted UPE) obtained by bonding polyamide (for example, nylon such as nylon-6 or nylon-6,6) to polyolefin (such as UPE which will be described later) by graft copolymerization may be used as the material of the filter.

Furthermore, the filter may be a filter having undergone a surface treatment. As the surface treatment method, known methods can be used without particular limitation. Examples of the surface treatment method include a chemical modification treatment, a plasma treatment, a hydrophobization treatment, coating, a gas treatment, sintering, and the like.

The plasma treatment is preferable because the surface of the filter is hydrophilized by this treatment. Although the water contact angle on the surface of a filter medium hydrophilized by the plasma treatment is not particularly limited, a static contact angle measured at 25° C. by using a contact angle meter is preferably equal to or smaller than 60°, more preferably equal to or smaller than 50°, and even more preferably equal to or smaller than 30°.

As the chemical modification treatment, a method of introducing ion exchange groups into a base material is preferable.

That is, the filter is preferably obtained by using various materials exemplified above as a base material and introducing ion exchange groups into the base material. Typically, it is preferable that the filter include a layer, which includes a base material containing ion exchange groups, on a surface of the base material described above. Although the surface-modified base material is not particularly limited, as the filter, a filter obtained by introducing ion exchange groups into the aforementioned polymer is preferable because such a filter is easier to manufacture.

Examples of the ion exchange groups include cation exchange groups such as a sulfonic acid group, a carboxyl group, and a phosphoric acid group and anion exchange groups such as a quaternary ammonium group. The method of introducing ion exchange groups into the polymer is not particularly limited, and examples thereof include a method of reacting a compound containing ion exchange groups and polymerizable groups with the polymer such that the compound is, typically, grafted on the polymer.

The method of introducing the ion exchange groups is not particularly limited. In a case where the fiber of the resin is irradiated with ionizing radiation (such as α-rays, β-rays, γ-rays, X-rays, or electron beams), active portions (radicals) are generated in the resin. The irradiated resin is immersed in a monomer-containing solution such that the monomer is graft-polymerized with the base material. As a result, a polymer is generated in which the monomer is bonded to polyolefin fiber as a side chain by graft polymerization. By bringing the resin containing the generated polymer as a side chain into contact with a compound containing an anion exchange group or a cation exchange group so as to cause a reaction, an end product is obtained in which the ion exchange group is introduced into the polymer of the graft-polymerized side chain.

Furthermore, the filter may be constituted with woven cloth in which ion exchange groups are formed by a radiation graft polymerization method or constituted with a combination of nonwoven cloth and glass wool, woven cloth, or nonwoven filter medium that is conventionally used.

In a case where the filter containing ion exchange groups is used, the content of metal atom-containing particles in the present chemical liquid is more easily controlled within a desired range. The material of the filter containing ion exchange groups is not particularly limited, and examples thereof include polyfluorocarbon, a material obtained by introducing ion exchange groups into polyolefin, and the like. Among these, the material obtained by introducing ion exchange groups into polyfluorocarbon is more preferable.

The pore size of the filter containing ion exchange groups is not particularly limited, but is preferably 1 to 30 nm and more preferably 5 to 20 nm. The filter containing ion exchange groups may also be used as the aforementioned filter having the smallest pore size or used as a filter different from the filter having the smallest pore size. Particularly, in view of obtaining the present chemical liquid exhibiting further improved effects of the present invention, it is preferable that the filter which contains ion exchange groups and the filter which does not contain ion exchange groups and has the smallest pore size be used in the filtration step.

The material of the aforementioned filter having the smallest pore size is not particularly limited. However, from the viewpoint of solvent resistance and the like, as such a material, generally, at least one kind of material selected from the group consisting of polyfluorocarbon and polyolefin is preferable, and polyolefin is more preferable.

Therefore, as the filter used in the filtration step, two or more kinds of filters made of different materials may be used. For example, two or more kinds of filters may be used which are selected from the group consisting of filters made of polyolefin, polyfluorocarbon, polyamide, or a material obtained by introducing ion exchange groups into these materials.

(Pore Structure of Filter)

The pore structure of the filter is not particularly limited, and may be appropriately selected according to the components in the substance to be purified. In the present specification, the pore structure of the filter means a pore size distribution, a positional distribution of pores in the filter, a pore shape, and the like. Typically, the pore structure can be controlled by the filter manufacturing method.

For example, in a case where powder of a resin or the like is sintered to form a filter, a porous membrane is obtained. Furthermore, in a case where a method such as electrospinning, electroblowing, or melt blowing is used to form a filter, a fiber membrane is obtained. These have different pore structures.

“Porous membrane” means a membrane which retains components in a substance to be purified, such as gel, particles, colloids, cells, and oligomers, but allows the components substantially smaller than the pores of the membrane to pass through the membrane. The retention of components in the substance to be purified by the porous membrane depends on operating conditions, for example, the surface velocity, the use of a surfactant, the pH, and a combination of these in some cases. Furthermore, the retention of components can depend on the pore size and structure of the porous membrane, and the size and structure of particles supposed to be removed (such as whether the particles are hard particles or gel).

In a case where the substance to be purified contains negatively charged particles, a filter made of polyamide functions as a non-sieving membrane so as to remove such particles. Typical non-sieving membranes include, but are not limited to, nylon membranes such as a nylon-6 membrane and a nylon-6,6 membrane.

“Non-sieving” retention mechanism used in the present specification refers to retention resulting from the mechanism such as blocking, diffusion, and adsorption irrelevant to the pressure drop or pore size of the filter.

The non-sieving retention includes a retention mechanism such as blocking, diffusion, and adsorption for removing particles supposed to be removed from the substance to be purified irrespective of the pressure drop or pore size of the filter. The adsorption of particles onto the filter surface can be mediated, for example, by the intermolecular van der Waals force and electrostatic force. In a case where the particles moving in the non-sieving membrane layer having a meandering path cannot sufficiently rapidly change direction so as not to contact the non-sieving membrane, a blocking effect is exerted. The transport of particles by diffusion is mainly caused by the random motion or the Brownian motion of small particles that results in a certain probability that the particles may collide with the filter medium. In a case where there is no repulsive force between the particles and the filter, the non-sieving retention mechanism can be activated.

An ultra-high-molecular-weight polyethylene (UPE) filter is typically a sieving membrane. A sieving membrane means a membrane that traps particles mainly through a sieving retention mechanism or a membrane that is optimized for trapping particles through a sieving retention mechanism.

Typical examples of the sieving membrane include, but are not limited to, a polytetrafluoroethylene (PTFE) membrane and a UPE membrane.

“Sieving retention mechanism” refers to the retention caused in a case where the particles to be removed are larger than the pore size of the porous membrane. Sieving retentivity can be improved by forming a filter cake (aggregate of particles to be removed on the surface of the membrane). The filter cake effectively functions as a secondary filter.

The material of the fiber membrane is not particularly limited as long as it is a polymer capable of forming the fiber membrane. Examples of the polymer include polyamide and the like. Examples of the polyamide include nylon 6, nylon 6,6, and the like. The polymer forming the fiber membrane may be poly(ethersulfone). In a case where the fiber membrane is on the primary side of the porous membrane, it is preferable that the surface energy of the fiber membrane be higher than the surface energy of the polymer which is the material of the porous membrane on a secondary side. For example, in some cases, nylon as a material of the fiber membrane and polyethylene (UPE) as the porous membrane are combined.

As the fiber membrane manufacturing method, known methods can be used without particular limitation. Examples of the fiber membrane manufacturing method include electrospinning, electroblowing, melt blowing, and the like.

The pore structure of the porous membrane (for example, a porous membrane including UPE, PTFE, and the like) is not particularly limited. The pores have, for example, a lace shape, a string shape, a node shape, and the like.

The size distribution of pores in the porous membrane and the positional distribution of pore size in the membrane are not particularly limited. The size distribution may be narrower, and the positional distribution of pore size in the membrane may be symmetric. Furthermore, the size distribution may be wider, and the positional distribution of pore size in the membrane may be asymmetric (this membrane is also called “asymmetric porous membrane”). In the asymmetric porous membrane, the size of the holes changes in the membrane. Typically, the pore size increases toward the other surface of the membrane from one surface of the membrane. In this case, the surface with many pores having a large pore size is called “open side”, and the surface with many pores having a small pore size is also called “tight side”.

Examples of the asymmetric porous membrane include a membrane in which the pore size is minimized at a position in the thickness direction of the membrane (this is also called “hourglass shape”).

In a case where the asymmetric porous membrane is used such that large holes are on the primary side, in other words, in a case where the primary side is used as the open side, a pre-filtration effect can be exerted.

The porous membrane layer may contain a thermoplastic polymer such as polyethersulfone (PESU), perfluoroalkoxyalkane (PFA, a copolymer of polytetrafluoroethylene and perfluoroalkoxyalkane), polyamide, or polyolefin, or may contain polytetrafluoroethylene and the like.

Among these, ultra-high-molecular-weight polyethylene is preferable as the material of the porous membrane. The ultra-high-molecular-weight polyethylene means thermoplastic polyethylene having a very long chain. The molecular weight thereof is equal to or greater than 1,000,000. Typically, the molecular weight thereof is preferably 2,000,000 to 6,000,000.

As filters used in the filtration step, two or more kinds of filters having different pore structures may be used, or a porous membrane filter and a fiber membrane filter may be used in combination. Specifically, for example, a method may be used in which a nylon fiber membrane filter and a UPE porous membrane filter are used.

It is preferable that the filters be used after being thoroughly washed before use.

In a case where an unwashed filter (or a filter that has not been thoroughly washed) is used, the impurities contained in the filter are easily mixed into the present chemical liquid.

Examples of the impurities contained in the filter include the organic impurities described above. In a case where an unwashed filter (or a filter that has not been thoroughly washed) is used to perform the filtration step, sometimes the content of the organic impurities in the present chemical liquid exceeds the range acceptable for the present chemical liquid.

For example, in a case where polyolefin such as UPE and polyfluorocarbon such as PTFE are used in a filter, the filter tends to contain an alkane having 12 to 50 carbon atoms as an impurity.

Furthermore, in a case where polyamide such as nylon, polyimide, and a polymer obtained by bonding polyamide (such as nylon) to polyolefin (such as UPE) by graft copolymerization are used in a filter, the filter tends to contain an alkene having 12 to 50 carbon atoms as an impurity.

The filter may be washed, for example, by a method of immersing the filter in an organic solvent with a small impurity content (for example, an organic solvent purified by distillation (such as PGMEA)) for 1 week or longer. In this case, the liquid temperature of the organic solvent is preferably 30° C. to 90° C.

To what extent the filter will be washed may be adjusted, such that the chemical liquid obtained after the substance to be purified is filtered using the filter contains organic impurities derived from the filter in a desired amount.

The filtration step may be a multi-stage filtration step in which the substance to be purified is passed through two or more kinds of filters that differ from each other in terms of at least one kind of aspect selected from the group consisting of filter material, pore size, and pore structure.

Furthermore, the substance to be purified may be passed through the same filter multiple times or passed through a plurality of filters of the same type.

The material of a liquid contact portion of the purification device used in the filtration step is not particularly limited (the liquid contact portion means an inner wall surface or the like that is likely to come into contact with the substance to be purified and the chemical liquid). However, it is preferable that the liquid contact portion be formed of at least one kind of material selected from the group consisting of a nonmetallic material (such as a fluororesin) and an electropolished metallic material (such as stainless steel) (hereinafter, these materials will be collectively called “anticorrosive material”). For example, in a case where a liquid contact portion of a manufacturing tank is formed of an anticorrosive material, the manufacturing tank itself is formed of the anticorrosive material, or the inner wall surface or the like of the manufacturing tank is coated with the anticorrosive material.

As the nonmetallic material, known materials can be used without particular limitation.

Examples of the nonmetallic material include at least one kind of material selected from the group consisting of a polyethylene resin, a polypropylene resin, a polyethylene-polypropylene resin, and a fluororesin (for example, polytetrafluoroethylene, a polytetrafluoroethylene-perfluoroalkyl vinyl ether copolymer, a polytetrafluoroethylene-hexafluoropropylene copolymer resin, a polytetrafluoroethylene-ethylene copolymer, a chlorotrifluoroethylene-ethylene copolymer resin, a vinylidene fluoride resin, a chlorotrifluoroethylene copolymer resin, a vinyl fluoride resin, and the like). However, the present invention is not limited to these.

As the metallic material, known materials can be used without particular limitation.

Examples of the metallic material include a metallic material in which the total content of chromium and nickel is greater than 25% by mass with respect to the total mass of the metallic material. The total content of chromium and nickel is more preferably equal to or greater than 30% by mass. The upper limit of the total content of chromium and nickel in the metallic material is not particularly limited, but is preferably equal to or smaller than 90% by mass in general.

Examples of the metallic material include stainless steel, a nickel-chromium alloy, and the like.

As the stainless steel, known stainless steel can be used without particular limitation. Among these, an alloy with a nickel content equal to or greater than 8% by mass is preferable, and austenite-based stainless steel with a nickel content equal to or greater than 8% by mass is more preferable. Examples of the austenite-based stainless steel include Steel Use Stainless (SUS) 304 (Ni content: 8% by mass, Cr content: 18% by mass), SUS304L (Ni content: 9% by mass, Cr content: 18% by mass), SUS316 (Ni content: 10% by mass, Cr content: 16% by mass), SUS316L (Ni content: 12% by mass, Cr content: 16% by mass), and the like.

As the nickel-chromium alloy, known nickel-chromium alloys can be used without particular limitation. Among these, a nickel-chromium alloy is preferable in which the nickel content is 40% to 75% by mass and the chromium content is 1% to 30% by mass.

Examples of the nickel-chromium alloy include HASTELLOY (trade name, the same is true of the following description), MONEL (trade name, the same is true of the following description), INCONEL (trade name, the same is true of the following description), and the like. More specifically, examples thereof include HASTELLOY C-276 (Ni content: 63% by mass, Cr content: 16% by mass), HASTELLOY C (Ni content: 60% by mass, Cr content: 17% by mass), HASTELLOY C-22 (Ni content: 61% by mass, Cr content: 22% by mass), and the like.

Furthermore, if necessary, the nickel-chromium alloy may further contain boron, silicon, tungsten, molybdenum, copper, cobalt, and the like in addition to the aforementioned alloy.

As the method of electropolishing the metallic material, known methods can be used without particular limitation. For example, it is possible to use the methods described in paragraphs “0011” to “0014” in JP2015-227501A, paragraphs “0036” to “0042” in JP2008-264929A, and the like.

Presumably, in a case where the metallic material is electropolished, the chromium content in a passive layer on the surface thereof may be higher than the chromium content in the parent phase. Therefore, presumably, in a case where a purification device having a liquid contact portion formed of the electropolished metallic material is used, metal-containing particles may be hardly eluted into the substance to be purified.

The metallic material may have undergone buffing. As the buffing method, known methods can be used without particular limitation. The size of abrasive grains used for finishing the buffing is not particularly limited, but is preferably equal to or smaller than #400 because such grains make it easy to further reduce the surface asperity of the metallic material. The buffing is preferably performed before the electropolishing.

<Other Steps>

The method for manufacturing the present chemical liquid may further have other steps in addition to the filtration step. Examples of steps other than the filtration step include a distillation step, a reaction step, an electricity removing step, and the like.

(Distillation Step)

The distillation step is a step of distilling the substance to be purified containing an organic solvent so as to obtain a substance to be purified having undergone distillation. As the method of distilling the substance to be purified, known methods can be used without particular limitation. Typically, examples thereof include a method of disposing a distillation column on a primary side of the purification device used in the filtration step and introducing the distilled substance to be purified into a manufacturing tank.

At this time, the liquid contact portion of the distillation column is not particularly limited, but is preferably formed of the anticorrosive material described above.

(Reaction Step)

The reaction step is a step of reacting raw materials so as to generate a substance to be purified containing an organic solvent as a reactant. As the method of generating the substance to be purified, known methods can be used without particular limitation. Typically, examples thereof include a method of disposing a reactor on a primary side of the manufacturing tank (or the distillation column) of the purification device used in the filtration step and introducing the reactant into the manufacturing tank (or the distillation column).

The liquid contact portion of the manufacturing tank is not particularly limited, but is preferably formed of the anticorrosive material described above.

(Electricity Removing Step)

The electricity removing step is a step of removing electricity from the substance to be purified such that the charge potential of the substance to be purified is reduced.

As the electricity removing method, known electricity removing methods can be used without particular limitation. Examples of the electricity removing method include a method of bringing the substance to be purified into contact with a conductive material.

The contact time for which the substance to be purified is brought into contact with a conductive material is preferably 0.001 to 60 seconds, more preferably 0.001 to 1 second, and particularly preferably 0.01 to 0.1 seconds. Examples of the conductive material include stainless steel, gold, platinum, diamond, glassy carbon, and the like.

Examples of the method of bringing the substance to be purified into contact with a conductive material include a method of disposing a grounded mesh formed of a conductive material in the interior of a pipe line and passing the substance to be purified through the mesh, and the like.

During the purification of the substance to be purified, it is preferable that all of the opening of a container, washing of a container and a device, storage of a solution, analysis, and the like that be included in the purification be performed in a clean room. It is preferable that the clean room have a cleanliness equal to or higher than class 4 specified in the international standard ISO14644-1:2015 established by International Organization for Standardization. Specifically, the clean room preferably meets any of ISO class 1, ISO class 2, ISO class 3, or ISO class 4, more preferably meets ISO class 1 or ISO class 2, and particularly preferably meets ISO class 1.

The storage temperature of the present chemical liquid is not particularly limited. However, in view of further preventing the elution of traces of impurities and the like contained in the present chemical liquid and consequently obtaining further improved effects of the present invention, the storage temperature is preferably equal to or higher than 4° C.

Furthermore, as a step other than the above, a dehydration step may be performed. The dehydration step can be performed using, for example, distillation, a molecular sieve, and the like.

[Chemical Liquid Storage Body]

The present chemical liquid may be stored in a container and kept as it is until use. Such a container and the present chemical liquid stored in the container are collectively called chemical liquid storage body. The present chemical liquid is used after being taken out of the kept chemical liquid storage body.

As the container storing the present chemical liquid, a container for manufacturing semiconductor devices is preferable which has a high internal cleanliness and hardly causes elution of impurities.

Examples of the usable container specifically include a “CLEAN BOTTLE” series manufactured by AICELLO CORPORATION, “PURE BOTTLE” manufactured by KODAMA PLASTICS Co., Ltd., and the like, but the container is not limited to these.

As the container, for the purpose of preventing mixing of impurities into the chemical liquid (contamination), it is also preferable to use a multilayer bottle in which the inner wall of the container has a 6-layer structure formed of 6 kinds of resins or a multilayer bottle having a 7-layer structure formed of 6 kinds of resins. Examples of these containers include the containers described in JP2015-123351A.

At least a part of the liquid contact portion of the container may be the aforementioned anticorrosive material (preferably electropolished stainless steel or a fluororesin) or glass. In view of obtaining further improved effects of the present invention, it is preferable that 90% or more of the area of the liquid contact portion be formed of the above material. It is more preferable that the entirety of the liquid contact portion be formed of the above material.

The void volume in the container in the chemical liquid storage body is preferably 5% to 99.99% by volume, more preferably 5% to 30% by volume, and even more preferably 5% to 25% by volume. In a case where the void volume is within the above range, the container has appropriate space. Therefore, it is easy to handle the present chemical liquid.

The void volume is calculated according to the following Equation (X).

Void volume (% by volume)={1−(volume of chemical liquid in container/container volume)}×100 Equation (X)

The container volume has the same definition as the internal volume (capacity) of the container.

### EXAMPLES

Hereinafter, the present invention will be more specifically described based on examples. The materials, the amounts and ratios of the materials used, the details of treatments, the procedures of treatments, and the like shown in the following examples can be appropriately changed as long as the gist of the present invention is maintained. Accordingly, the scope of the present invention is not limited to the following examples.

For preparing chemical liquids of examples and comparative examples, the handling of containers, and the preparation, filling, storage, and analytical measurement of chemical liquids were all performed in a clean room of a level satisfying ISO class 2 or 1. In order to improve the measurement accuracy, in measuring the content of organic impurities and the content of metal impurities, in a case where the content of the organic impurities or metal impurities was found to be equal to or smaller than a detection limit by general measurement, the chemical liquid was concentrated for the measurement, and the content was calculated by converting the concentration into the concentration of the solution not yet being concentrated.

[Purification of Chemical Liquid]

[Substance to be Purified]

For manufacturing chemical liquids of examples and comparative examples, the following organic solvents were used as substances to be purified. All of the following organic solvents used are commercial products. Here, in a case where a plurality of kinds of organic solvents was used, organic solvents not yet being mixed together were separately purchased and then mixed together to form a total of 100% by mass of a mixture, and the mixture was used as a substance to be purified.

NBA: butyl acetate

CHN: cyclohexanone

IPA: isopropanol

EL: ethyl lactate

PGMEA: propylene glycol monomethyl ether acetate

PGME: propylene glycol monoethyl ether

PC: propylene carbonate

[Purification]

By using the aforementioned substances to be purified, the following pretreatment, distillation step, filtration step, and dehydration step were carried out in this order in the combination described in the tables that will be described later, thereby obtaining chemical liquids of examples and comparative examples.

Each of the substances to be purified was purified by appropriately changing the number of times the substances pass through filters in each treatment or step. Furthermore, as the piping for transferring the substance to be purified and the chemical liquid in the series of purification process, piping having a liquid contact portion made of electropolished stainless steel was used.

<Pretreatment>

As the pretreatment, the filters to be used in the filtration step were washed with propylene glycol monomethyl ether acetate (PGMEA) for the period described in the tables. In a case where the description of “PGMEA 1 week” appears twice for an example, this means that the filter was washed with PGMEA for 1 week and then washed again with new PGMEA for 1 week.

In the tables, “PGMEA ultrasound*1” means that the filter was washed for 1 minute at 100 Hz (frequency) by being immersed in PGMEA, “PGMEA ultrasound*2” means that the filter was washed for 3 minutes at 50 Hz (frequency) by being immersed in a PGMEA solution, “PGMEA ultrasound*3” means that the filter was washed for 5 minutes at 100 Hz (frequency) by being immersed in a PGMEA solution, and “PGMEA ultrasound*4” means that the filter was washed for 2 minutes at 80 Hz (frequency) by being immersed in a PGMEA solution.

<Distillation Step>

Each substance to be purified was distilled using any of the distillation columns in A-1 to A-7.

A-1: atmospheric distillation using a distillation column (theoretical number of plates: 30) was carried out twice.

A-2: atmospheric distillation using a distillation column (theoretical number of plates: 25) was carried out twice.

A-3: atmospheric distillation using a distillation column (theoretical number of plates: 20) was carried out twice.

A-4: atmospheric distillation using a distillation column (theoretical number of plates: 15) was carried out twice.

A-5: atmospheric distillation using a distillation column (theoretical number of plates: 10) was carried out twice.

A-6: atmospheric distillation using a distillation column (theoretical number of plates: 8) was carried out twice.

A-7: atmospheric distillation using a distillation column (theoretical number of plates: 8) was carried out once.

<Filtration Step>

Filters were arranged such that each substance to be purified passed through a filter 1, a filter 2, a filter 3, and a filter 4 in this order.

Filter 1: PTFE 10 nm (polytetrafluoroethylene filter, manufactured by Entegris, pore size of 10 nm) or PTFE 20 nm (polytetrafluoroethylene filter, manufactured by Entegris, pore size of 20 nm)

Filter 2: IEX (fiber membrane of polymer of polytetrafluoroethylene and polyethylene sulfonate, manufactured by Entegris, pore size of 15 nm) or PTFE 10 nm (polytetrafluoroethylene filter, manufactured by Entegris, pore size of 10 nm)

Filter 3: PTFE 5 nm (polytetrafluoroethylene filter, manufactured by Entegris, pore size of 10 nm), Nylon 5 nm (nylon filter, manufactured by Pall Corporation, pore size of 5 nm), or UPE 3 nm (nylon/ultra-high-molecular-weight polyethylene graft copolymer filter, manufactured by Entegris, pore size of 3 nm)

Filter 4: UPE 1 nm (nylon/ultra-high-molecular-weight polyethylene graft copolymer filter, manufactured by Entegris, pore size of 1 nm)

<Dehydration Step>

As the dehydration step, any of the following dehydration 1 to 3 was performed.

Dehydration 1: Distillation was performed once under reduced pressure by using a distillation column (theoretical number of plates: 30).

Dehydration 2: Distillation was performed twice under reduced pressure by using a distillation column (theoretical number of plates: 30).

Dehydration 3: Distillation was performed three times under reduced pressure by using a distillation column (theoretical number of plates: 30).

TABLE 1

| | Organic solvent | | | | | | | | | | | Con- |
|---|---|---|---|---|---|---|---|---|---|---|---|---|
| | First | Second | Third | | | | | | | | | tainer |
| | organic | organic | organic | Purification | | | | | | | | Void |
| | solvent | solvent | solvent | | | Distil- | Filter 1 | Filter 2 | Filter 3 | Filter 4 | Dehy- | volume |
| | (% by | (% by | (% by | | | lation | (Filtration | (Filtration | (Filtration | (Filtration | dration | (% by |
| | mass) | mass) | mass) | Pretreatment | | step | step) | step) | step) | step) | step | volume) |
| Example | nBA | — | — | PGMEA 1 | | A-1 | PTFE | IEX | PTFE 5 nm | — | — | 25 |
| A-1 | | | | week | | | 10 nm | | | | | |
| Example | nBA | — | — | PGMEA 1 | | — | PTFE | IEX | PTFE 5 nm | — | — | 20 |
| A-2 | | | | week | | | 10 nm | | | | | |
| Example | nBA | — | — | PGMEA 1 | | A-2 | PTFE | IEX | PTFE 5 nm | — | — | 35 |
| A-3 | | | | week | | | 10 nm | | | | | |
| Example | nBA | — | — | PGMEA 1 | | A-3 | PTFE | IEX | PTFE 5 nm | — | Dehy- | 25 |
| A-4 | | | | week | | | 10 nm | | | | dration 1 | |
| Example | nBA | — | — | PGMEA 1 | | A-4 | PTFE | IEX | PTFE 5 nm | — | Dehy- | 20 |
| A-5 | | | | week | | | 10 nm | | | | dration 2 | |
| Example | nBA | — | — | PGMEA 1 | | A-5 | PTFE | IEX | Nylon 5 nm | — | Dehy- | 15 |
| A-6 | | | | week | | | 10 nm | | | | dration 3 | |
| Example | nBA | — | — | PGMEA 1 | | A-5 | PTFE | IEX | PTFE 5 nm | — | Dehy- | 20 |
| A-7 | | | | week | | | 10 nm | | | | dration 3 | |
| Example | nBA | — | — | PGMEA 1 | PGMEA | A-6 | PTFE | IEX | PTFE 5 nm | — | Dehy- | 30 |
| A-8 | | | | week | ultrasound*1 | | 10 nm | | | | dration 3 | |
| Example | nBA | — | — | PGMEA 1 | | A-7 | PTFE | IEX | PTFE 5 nm | — | — | 25 |
| A-9 | | | | week | | | 10 nm | | | | | |
| Example | nBA | — | — | PGMEA 1 | | A-2 | PTFE | IEX | PTFE 5 nm | — | — | 20 |
| A-10 | | | | week | | | 10 nm | | | | | |
| Example | nBA | — | — | PGMEA 1 | | A-2 | PTFE | IEX | PTFE 5 nm | — | — | 15 |
| A-11 | | | | day | | | 10 nm | | | | | |
| Example | nBA | — | — | PGMEA 1 | PGMEA | A-5 | PTFE | IEX | PTFE 5 nm | — | — | 10 |
| A-12 | | | | week | ultrasound*1 | | 10 nm | | | | | |
| Example | nBA | — | — | PGMEA 1 | PGMEA | A-5 | PTFE | IEX | PTFE 5 nm | — | — | 15 |
| A-13 | | | | week | ultrasound*2 | | 10 nm | | | | | |
| Example | nBA | — | — | PGMEA 1 | PGMEA | A-5 | PTFE | IEX | PTFE 5 nm | — | — | 5 |
| A-14 | | | | week | ultrasound*3 | | 10 nm | | | | | |
| Example | nBA | — | — | PGMEA 1 | PGMEA | A-5 | PTFE | IEX | PTFE 5 nm | — | — | 15 |
| A-15 | | | | week | ultrasound*4 | | 10 nm | | | | | |
| Example | nBA | — | — | PGMEA 1 | | A-1 | PTFE | IEX | Nylon 5 nm | — | — | 15 |
| A-16 | | | | day | | | 10 nm | | | | | |
| Example | nBA | — | — | PGMEA 1 | | A-1 | PTFE | — | — | — | — | 20 |
| A-17 | | | | week | | | 10 nm | | | | | |
| Example | nBA | — | — | PGMEA 1 | | A-1 | PTFE | — | — | — | — | 25 |
| A-18 | | | | week | | | 30 nm | | | | | |
| Example | nBA | — | — | PGMEA 1 | PGMEA | A-1 | PTFE | PTFE | UPE 3 nm | — | — | 20 |
| A-19 | | | | week | ultrasound*4 | | 10 nm | 10 nm | | | | |
| Example | nBA | — | — | PGMEA 1 | PGMEA | A-1 | PTFE | PTFE | UPE 3 nm | UPE 1 nm | — | 20 |
| A-20 | | | | week | ultrasound*4 | | 10 nm | 10 nm | | | | |
| Example | nBA | — | — | PGMEA 1 | PGMEA 1 | A-1 | PTFE | IEX | PTFE 5 nm | — | — | 3 |
| A-21 | | | | week | week | | 10 nm | | | | | |
| Example | nBA | — | — | PGMEA 1 | PGMEA 1 | A-1 | PTFE | IEX | PTFE 5 nm | — | — | 35 |
| A-22 | | | | week | week | | 10 nm | | | | | |

TABLE 2

| | Organic solvent | | | | | | | | | | | Con- |
|---|---|---|---|---|---|---|---|---|---|---|---|---|
| | First | Second | Third | | | | | | | | | tainer |
| | organic | organic | organic | Purification | | | | | | | | Void |
| | solvent | solvent | solvent | | | Distil- | Filter 1 | Filter 2 | Filter 3 | Filter 4 | Dehy- | volume |
| | (% by | (% by | (% by | | | lation | (Filtration | (Filtration | (Filtration | (Filtration | dration | (% by |
| | mass) | mass) | mass) | Pretreatment | | step | step) | step) | step) | step) | step | volume) |
| Example B-1 | CHN | — | — | PGMEA | | A-1 | PTFE | IEX | PTFE | — | — | 25 |
| | | | | 1 week | | | 10 nm | | 5 nm | | | |
| Example B-2 | CHN | — | — | PGMEA | | — | PTFE | IEX | PTFE | — | — | 20 |
| | | | | 1 week | | | 10 nm | | 5 nm | | | |
| Example B-3 | CHN | — | — | PGMEA | | A-2 | PTFE | IEX | PTFE | — | — | 35 |
| | | | | 1 week | | | 10 nm | | 5 nm | | | |
| Example B-4 | CHN | — | — | PGMEA | | A-3 | PTFE | IEX | PTFE | — | Dehy- | 25 |
| | | | | 1 week | | | 10 nm | | 5 nm | | dration 1 | |
| Example B-5 | CHN | — | — | PGMEA | | A-4 | PTFE | IEX | PTFE | — | Dehy- | 20 |
| | | | | 1 week | | | 10 nm | | 5 nm | | dration 2 | |
| Example B-6 | CHN | — | — | PGMEA | | A-5 | PTFE | IEX | Nylon | — | Dehy- | 15 |
| | | | | 1 week | | | 10 nm | | 5 nm | | dration 3 | |
| Example B-7 | CHN | — | — | PGMEA | | A-5 | PTFE | IEX | PTFE | — | Dehy- | 20 |
| | | | | 1 week | | | 10 nm | | 5 nm | | dration 3 | |
| Example B-8 | CHN | — | — | PGMEA | PGMEA | A-6 | PTFE | IEX | PTFE | — | Dehy- | 30 |
| | | | | 1 week | ultrasound*1 | | 10 nm | | 5 nm | | dration 3 | |
| Example B-9 | CHN | — | — | PGMEA | | A-7 | PTFE | IEX | PTFE | — | — | 25 |
| | | | | 1 week | | | 10 nm | | 5 nm | | | |
| Example B-10 | CHN | — | — | PGMEA | | A-2 | PTFE | IEX | PTFE | — | — | 20 |
| | | | | 1 week | | | 10 nm | | 5 nm | | | |
| Example B-11 | CHN | — | — | PGMEA | | A-2 | PTFE | IEX | PTFE | — | — | 15 |
| | | | | 1 day | | | 10 nm | | 5 nm | | | |
| Example B-12 | CHN | — | — | PGMEA | PGMEA | A-5 | PTFE | IEX | PTFE | — | — | 10 |
| | | | | 1 week | ultrasound*1 | | 10 nm | | 5 nm | | | |
| Example B-13 | CHN | — | — | PGMEA | PGMEA | A-5 | PTFE | IEX | PTFE | — | — | 15 |
| | | | | 1 week | ultrasound*2 | | 10 nm | | 5 nm | | | |
| Example B-14 | CHN | — | — | PGMEA | PGMEA | A-5 | PTFE | IEX | PTFE | — | — | 5 |
| | | | | 1 week | ultrasound*3 | | 10 nm | | 5 nm | | | |
| Example B-15 | CHN | — | — | PGMEA | PGMEA | A-5 | PTFE | IEX | PTFE | — | — | 15 |
| | | | | 1 week | ultrasound*4 | | 10 nm | | 5 nm | | | |
| Example B-16 | CHN | — | — | PGMEA | | A-1 | PTFE | IEX | Nylon | — | — | 15 |
| | | | | 1 day | | | 10 nm | | 5 nm | | | |
| Example B-17 | CHN | — | — | PGMEA | | A-1 | PTFE | — | — | — | — | 20 |
| | | | | 1 week | | | 10 nm | | | | | |
| Example B-18 | CHN | — | — | PGMEA | | A-1 | PTFE | — | — | — | — | 25 |
| | | | | 1 week | | | 20 nm | | | | | |
| Example B-19 | CHN | — | — | PGMEA | PGMEA | A-1 | PTFE | PTFE | UPE | — | — | 20 |
| | | | | 1 week | ultrasound*4 | | 10 nm | 10 nm | 3 nm | | | |
| Example B-20 | CHN | — | — | PGMEA | PGMEA | A-1 | PTFE | PTFE | UPE | UPE | — | 20 |
| | | | | 1 week | ultrasound*4 | | 10 nm | 10 nm | 3 nm | 1 nm | | |
| Example B-21 | CHN | — | — | PGMEA | PGMEA | A-1 | PTFE | IEX | PTFE | — | — | 3 |
| | | | | 1 week | 1 week | | 10 nm | | 5 nm | | | |
| Example B-22 | CHN | — | — | PGMEA | PGMEA | A-1 | PTFE | IEX | PTFE | — | — | 35 |
| | | | | 1 week | 1 week | | 10 nm | | 5 nm | | | |

TABLE 3

| | Organic solvent | | | | | | | | | | | Con- |
|---|---|---|---|---|---|---|---|---|---|---|---|---|
| | First | Second | Third | | | | | | | | | tainer |
| | organic | organic | organic | Purification | | | | | | | | Void |
| | solvent | solvent | solvent | | | Distil- | Filter 1 | Filter 2 | Filter 3 | Filter 4 | Dehy- | volume |
| | (% by | (% by | (% by | | | lation | (Filtration | (Filtration | (Filtration | (Filtration | dration | (% by |
| | mass) | mass) | mass) | Pretreatment | | step | step) | step) | step) | step) | step | volume) |
| Example C-1 | IPA | — | — | PGMEA 1 | | A-1 | PTFE | IEX | PTFE | — | — | 25 |
| | | | | week | | | 10 nm | | 5 nm | | | |
| Example C-2 | IPA | — | — | PGMEA 1 | | — | PTFE | IEX | PTFE | — | — | 20 |
| | | | | week | | | 10 nm | | 5 nm | | | |
| Example C-3 | IPA | — | — | PGMEA 1 | | A-2 | PTFE | IEX | PTFE | — | — | 35 |
| | | | | week | | | 10 nm | | 5 nm | | | |
| Example C-4 | IPA | — | — | PGMEA 1 | | A-3 | PTFE | IEX | PTFE | — | Dehy- | 25 |
| | | | | week | | | 10 nm | | 5 nm | | dration 1 | |
| Example C-5 | IPA | — | — | PGMEA 1 | | A-4 | PTFE | IEX | PTFE | — | Dehy- | 20 |
| | | | | week | | | 10 nm | | 5 nm | | dration 2 | |
| Example C-6 | IPA | — | — | PGMEA 1 | | A-5 | PTFE | IEX | PTFE | — | Dehy- | 15 |
| | | | | week | | | 10 nm | | 5 nm | | dration 3 | |
| Example C-7 | IPA | — | — | PGMEA 1 | | A-5 | PTFE | IEX | PTFE | — | Dehy- | 20 |
| | | | | week | | | 10 nm | | 5 nm | | dration 3 | |
| Example C-8 | IPA | — | — | PGMEA 1 | PGMEA | A-6 | PTFE | IEX | PTFE | — | Dehy- | 30 |
| | | | | week | ultrasound*1 | | 10 nm | | 5 nm | | dration 3 | |
| Example C-9 | IPA | — | — | PGMEA 1 | | A-7 | PTFE | IEX | PTFE | — | — | 25 |
| | | | | week | | | 10 nm | | 5 nm | | | |
| Example C-10 | IPA | — | — | PGMEA 1 | | A-2 | PTFE | IEX | PTFE | — | — | 20 |
| | | | | week | | | 10 nm | | 5 nm | | | |
| Example C-11 | IPA | — | — | PGMEA 1 | | A-2 | PTFE | IEX | PTFE | — | — | 15 |
| | | | | day | | | 10 nm | | 5 nm | | | |
| Example C-12 | IPA | — | — | PGMEA 1 | PGMEA | A-5 | PTFE | IEX | PTFE | — | — | 10 |
| | | | | week | ultrasound*1 | | 10 nm | | 5 nm | | | |
| Example C-13 | IPA | — | — | PGMEA 1 | PGMEA | A-5 | PTFE | IEX | PTFE | — | — | 15 |
| | | | | week | ultrasound*2 | | 10 nm | | 5 nm | | | |
| Example C-14 | IPA | — | — | POMEA | PGMEA | A-5 | PTFE | IEX | PTFE | — | — | 5 |
| | | | | week | ultrasound*3 | | 10 nm | | 5 nm | | | |
| Example C-15 | IPA | — | — | PGMEA 1 | PGMEA | A-5 | PTFE | IEX | PTFE | — | — | 15 |
| | | | | week | ultrasound*4 | | 10 nm | | 5 nm | | | |
| Example C-16 | IPA | — | — | PGMEA 1 | | A-1 | PTFE | IEX | Nylon | — | — | 15 |
| | | | | day | | | 10 nm | | 5 nm | | | |
| Example C-17 | IPA | — | — | PGMEA 1 | | A-1 | PTFE | — | — | — | — | 20 |
| | | | | week | | | 10 nm | | | | | |
| Example C-18 | IPA | — | — | PGMEA 1 | | A-1 | PTFE | — | — | — | — | 25 |
| | | | | week | | | 20 nm | | | | | |
| Example C-19 | IPA | — | — | PGMEA 1 | PGMEA | A-1 | PTFE | PTFE | UPE | | — | 20 |
| | | | | week | ultrasound*4 | | 10 nm | 10 nm | 3 nm | | | |
| Example C-20 | IPA | — | — | PGMEA 1 | PGMEA | A-1 | PTFE | PTFE | UPE | UPE | — | 20 |
| | | | | week | ultrasound*4 | | 10 nm | 10 nm | 3 nm | 1 nm | | |
| Example C-21 | IPA | — | — | PGMEA 1 | PGMEA | A-1 | PTFE | IEX | PTFE | — | — | 3 |
| | | | | week | 1 week | | 10 nm | | 5 nm | | | |
| Example C-22 | IPA | — | — | PGMEA 1 | PGMEA | A-1 | PTFE | IEX | PTFE | — | — | 35 |
| | | | | week | 1 week | | 10 nm | | 5 nm | | | |

TABLE 4

| | Organic | | | | | | | | | | | | |
|---|---|---|---|---|---|---|---|---|---|---|---|---|---|
| | solvent | | | | | | | | | | | | |
| | First | Second | Third | | | | | | | | | | Container |
| | organic | organic | organic | Purification | | | | | | | | | Void |
| | solvent | solvent | solvent | | | Dis- | Filter 1 | Filter 2 | Filter 3 | | Filter 4 | Dehydra- | volume |
| | (% by | (% by | (% by | | | tillation | (Filtration | (Filtration | (Filtration | | (Filtration | tion | (% by |
| | mass) | mass) | mass) | Pretreatment | | step | step) | step) | step) | | step) | step | volume) |
| Example | EL | — | — | PGMEA | | A-1 | PTFE | IEX | PTFE | 5 nm | — | — | 25 |
| D-1 | | | | 1 week | | | 10 nm | | | | | | |
| Example | EL | — | — | PGMEA | | — | PTFE | IEX | PTFE | 5 nm | — | — | 20 |
| D-2 | | | | 1 week | | | 10 nm | | | | | | |
| Example | EL | — | — | PGMEA | | A-2 | PTFE | IEX | PTFE | 5 nm | — | — | 35 |
| D-3 | | | | 1 week | | | 10 nm | | | | | | |
| Example | EL | — | — | PGMEA | | A-3 | PTFE | IEX | PTFE | 5 nm | — | Dehydra- | 25 |
| D-4 | | | | 1 week | | | 10 nm | | | | | tion 1 | |
| Example | EL | — | — | PGMEA | | A-4 | PTFE | IEX | PTFE | 5 nm | — | Dehydra- | 20 |
| D-5 | | | | 1 week | | | 10 nm | | | | | tion 2 | |
| Example | EL | — | — | PGMEA | | A-5 | PTFE | LEX | Nylon | 5 nm | — | Dehydra- | 15 |
| D-6 | | | | 1 week | | | 10 nm | | | | | tion 3 | |
| Example | EL | — | — | PGMEA | | A-5 | PTFE | IEX | PTFE | 5 nm | — | Dehydra- | 20 |
| D-7 | | | | 1 week | | | 10 nm | | | | | tion 3 | |
| Example | EL | — | — | PGMEA | PGMEA | A-6 | PTFE | IEX | PTFE | 5 nm | — | Dehydra- | 30 |
| D-8 | | | | 1 week | ultrasound*1 | | 10 nm | | | | | tion 3 | |
| Example | EL | — | — | PGMEA | | A-7 | PTFE | IEX | PTFE | 5 nm | — | — | 25 |
| D-9 | | | | 1 week | | | 10 nm | | | | | | |
| Example | EL | — | — | PGMEA | | A-2 | PTFE | IEX | PTFE | 5 nm | — | — | 20 |
| D-10 | | | | 1 week | | | 10 nm | | | | | | |
| Example | EL | — | — | PGMEA | | A-2 | PTFE | IEX | PTFE | 5 nm | — | — | 15 |
| D-11 | | | | 1 day | | | 10 nm | | | | | | |
| Example | EL | — | — | PGMEA | PGMEA | A-5 | PTFE | IEX | PTFE | 5 nm | — | — | 10 |
| D-12 | | | | 1 week | ultrasound*1 | | 10 nm | | | | | | |
| Example | EL | — | — | PGMEA | PGMEA | A-5 | PTFE | IEX | PTFE | 5 nm | — | — | 15 |
| D-13 | | | | 1 week | ultrasound*2 | | 10 nm | | | | | | |
| Example | EL | — | — | PGMEA | PGMEA | A-5 | PTFE | IEX | PTFE | 5 nm | — | — | 5 |
| D-14 | | | | 1 week | ultrasound*3 | | 10 nm | | | | | | |
| Example | EL | — | — | PGMEA | PGMEA | A-5 | PTFE | IEX | PTFE | 5 nm | — | — | 15 |
| D-15 | | | | 1 week | ultrasound*4 | | 10 nm | | | | | | |
| Example | EL | — | — | PGMEA | | A-1 | PTFE | IEX | Nylon | 5 nm | — | — | 15 |
| D-16 | | | | 1 day | | | 10 nm | | | | | | |
| Example | EL | — | — | PGMEA | | A-1 | PTFE | — | — | | — | — | 20 |
| D-17 | | | | 1 week | | | 10 nm | | | | | | |
| Example | EL | — | — | PGMEA | | A-1 | PTFE | — | — | | — | — | 25 |
| D-18 | | | | 1 week | | | 20 nm | | | | | | |
| Example | EL | — | — | PGMEA | PGMEA | A-1 | PTFE | PTFE | UPE | 3 nm | | — | 20 |
| D-19 | | | | 1 week | ultrasound*4 | | 10 nm | 10 nm | | | | | |
| Example | EL | — | — | PGMEA | PGMEA | A-1 | PTFE | PTFE | UPE | 3 nm | UPE 1 nm | — | 20 |
| D-20 | | | | 1 week | ultrasound*4 | | 10 nm | 10 nm | | | | | |
| Example | EL | — | — | PGMEA | PGMEA | A-1 | PTFE | IEX | PTFE | 5 nm | — | — | 3 |
| D-21 | | | | 1 week | 1 week | | 10 nm | | | | | | |
| Example | EL | — | — | PGMEA | PGMEA | A-1 | PTFE | IEX | PTFE | 5 nm | — | — | 35 |
| D-22 | | | | 1 week | 1 week | | 10 nm | | | | | | |

TABLE 5

| | Organic | | | | | | | | | | | |
|---|---|---|---|---|---|---|---|---|---|---|---|---|
| | solvent | | | | | | | | | | | |
| | First | Second | Third | | | | | | | | | Container |
| | organic | organic | organic | Purification | | | | | | | | Void |
| | solvent | solvent | solvent | | | Dis- | Filter 1 | Filter 2 | Filter 3 | Filter 4 | Dehydra- | volume |
| | (% by | (% by | (% by | | | tillation | (Filtration | (Filtration | (Filtration | (Filtration | tion | (% by |
| | mass) | mass) | mass) | Pretreatment | | step | step) | step) | step) | step) | step | volume) |
| Example | PGMEA | — | — | PGMEA | | A-1 | PTFE | IEX | PTFE | — | — | 25 |
| E-1 | | | | 1 week | | | 10 nm | | 5 nm | | | |
| Example | PGMEA | — | — | PGMEA | | — | PTFE | IEX | PTFE | — | — | 20 |
| E-2 | | | | 1 week | | | 10 nm | | 5 nm | | | |
| Example | PGMEA | — | — | PGMEA | | A-2 | PTFE | IEX | PTFE | — | — | 35 |
| E-3 | | | | 1 week | | | 10 nm | | 5 nm | | | |
| Example | PGMEA | — | — | PGMEA | | A-3 | PTFE | IEX | PTFE | — | Dehydra- | 25 |
| E-4 | | | | 1 week | | | 10 nm | | 5 nm | | tion 1 | |
| Example | PGMEA | — | — | PGMEA | | A-4 | PTFE | IEX | PTFE | — | Dehydra- | 20 |
| E-5 | | | | 1 week | | | 10 nm | | 5 nm | | tion 2 | |
| Example | PGMEA | — | — | PGMEA | | A-5 | PTFE | IEX | Nylon | — | Dehydra- | 15 |
| E-6 | | | | 1 week | | | 10 nm | | 5 nm | | tion 3 | |
| Example | PGMEA | — | — | PGMEA | | A-5 | PTFE | IEX | PTFE | — | Dehydra- | 20 |
| E-7 | | | | 1 week | | | 10 nm | | 5 nm | | tion 3 | |
| Example | PGMEA | — | — | PGMEA | PGMEA | A-6 | PTFE | IEX | PTFE | — | Dehydra- | 30 |
| E-8 | | | | 1 week | ultrasound*1 | | 10 nm | | 5 nm | | tion 3 | |
| Example | PGMEA | — | — | PGMEA | | A-7 | PTFE | IEX | PTFE | — | — | 25 |
| E-9 | | | | 1 week | | | 10 nm | | 5 nm | | | |
| Example | PGMEA | — | — | PGMEA | | A-2 | PTFE | LEX | PTFE | — | — | 20 |
| E-10 | | | | 1 week | | | 10 nm | | 5 nm | | | |
| Example | PGMEA | — | — | PGMEA | | A-2 | PTFE | IEX | PTFE | — | — | 15 |
| E-11 | | | | 1 day | | | 10 nm | | 5 nm | | | |
| Example | PGMEA | — | — | PGMEA | PGMEA | A-5 | PTFE | LEX | PTFE | — | — | 10 |
| E-12 | | | | 1 week | ultrasound*1 | | 10 nm | | 5 nm | | | |
| Example | PGMEA | — | — | PGMEA | PGMEA | A-5 | PTFE | IEX | PTFE | — | — | 15 |
| E-13 | | | | 1 week | ultrasound*2 | | 10 nm | | 5 nm | | | |
| Example | PGMEA | — | — | PGMEA | PGMEA | A-5 | PTFE | IEX | PTFE | — | — | 5 |
| E-14 | | | | 1 week | ultrasound*3 | | 10 nm | | 5 nm | | | |
| Example | PGMEA | — | — | PGMEA | PGMEA | A-5 | PTFE | IEX | PTFE | — | — | 15 |
| E-15 | | | | 1 week | ultrasound*4 | | 10 nm | | 5 nm | | | |
| Example | PGMEA | — | — | PGMEA | | A-1 | PTFE | IEX | Nylon | — | — | 15 |
| E-16 | | | | 1 day | | | 10 nm | | 5 nm | | | |
| Example | PGMEA | — | — | PGMEA | | A-1 | PTFE | — | — | — | — | 20 |
| E-17 | | | | 1 week | | | 10 nm | | | | | |
| Example | PGMEA | — | — | PGMEA | | A-1 | PTFE | — | — | — | — | 25 |
| E-18 | | | | 1 week | | | 20 nm | | | | | |
| Example | PGMEA | — | — | PGMEA | PGMEA | A-1 | PTFE | PTFE | UPE | — | — | 20 |
| E-19 | | | | 1 week | ultrasound*4 | | 10 nm | 10 nm | 3 nm | | | |
| Example | PGMEA | — | — | PGMEA | PGMEA | A-1 | PTFE | PTFE | UPE | UPE | — | 20 |
| E-20 | | | | 1 week | ultrasound*4 | | 10 nm | 10 nm | 3 nm | 1 nm | | |
| Example | PGMEA | — | — | PGMEA | PGMEA | A-1 | PTFE | IEX | PTFE | — | — | 3 |
| E-21 | | | | 1 week | 1 week | | 10 nm | | 5 nm | | | |
| Example | PGMEA | — | — | PGMEA | PGMEA | A-1 | PTFE | IEX | PTFE | — | — | 35 |
| E-22 | | | | 1 week | 1 week | | 10 nm | | 5 nm | | | |

TABLE 6

| | Organic | | | | | | | | | | |
|---|---|---|---|---|---|---|---|---|---|---|---|
| | solvent | | | | | | | | | | |
| | First | Second | Third | | | | | | | | Container |
| | organic | organic | organic | Purification | | | | | | | Void |
| | solvent | solvent | solvent | | Distil- | Filter 1 | Filter 2 | Filter 3 | Filter 4 | Dehydra- | volume |
| | (% by | (% by | (% by | | lation | (Filtration | (Filtration | (Filtration | (Filtration | tion | (% by |
| | mass) | mass) | mass) | Pretreatment | step | step) | step) | step) | step) | step | volume) |
| Example F−1 | PGMEA | PGME 30% | — | PGMEA | A-1 | PTFE 10 nm | LEX | PTFE 5 nm | — | — | 25 |
| | | by mass | | 1 week | | | | | | | |
| Example G−1 | PGMEA | PC 10% | — | PGMEA | A-1 | PTFE 10 nm | IEX | PTFE 5 nm | — | — | 25 |
| | | by mass | | 1 week | | | | | | | |
| Example H−1 | PGMEA | EL 20% | CHN 20% | PGMEA | A-1 | PTFE 10 nm | IEX | PTFE 5 nm | — | — | 25 |
| | | by mass | by mass | 1 week | | | | | | | |
| Comparative | nBA | — | — | PGMEA | A-1 | PTFE 10 nm | IEX | PTFE 5 nm | — | — | 25 |
| Example 1 | | | | 1 week | | | | | | | |

[Chemical Liquid Storage Body]

First, in a vacuum desiccator having a volume of 1,000 L, a container (container including a liquid contact portion made of SUS that will be described later) was installed, and then the members being likely to come into contact with a chemical liquid, such as the vacuum desiccator, the liquid contact portion of the container, and piping through which the chemical liquid will flow into the container, were washed with a semiconductor-grade aqueous hydrogen peroxide. Thereafter, the air inside the vacuum desiccator was replaced with nitrogen gas so that a dry atmosphere was created.

Subsequently, a treatment of creating a vacuum in the vacuum desiccator and then filling the vacuum desiccator with nitrogen gas was repeated so that a clean atmosphere was created in the vacuum desiccator.

The chemical liquid purified as described above was stored in the container installed in the clean vacuum desiccator prepared as above so that a void volume (% by volume) of the container reached the value shown in the tables. Then, the container was sealed so that the chemical liquid in the container did not flow out, thereby obtaining a chemical liquid storage body. After the chemical liquid storage body was stored at 30° C. for 1 year, the chemical liquid was then taken out of the chemical liquid storage body and used for the measurement of organic impurities, the measurement of metal impurities, and various evaluation tests that will be described later.

[Container]

As the container for storing the chemical liquid, a container having a liquid contact portion made of SUS (stainless steel) was used. As the SUS, SUS was used which conforms to the standard of a mass ratio of a Cu content to a Fe content (Cu/Fe) of higher than 1 and less than 2.

[Organic Impurities]

The type and content of organic impurities in each chemical liquid were measured using a gas chromatography mass spectrometry (trade name “GCMS-2020”, manufactured by Shimadzu Corporation, the measurement conditions were as described below).

<Measurement Conditions>

Capillary column: InertCap 5MS/NP 0.25 mm I.D.×30 m df=0.25 μm

Sample introduction method: split 75 kPa constant pressure

Vaporizing chamber temperature: 230° C.

Column oven temperature: 80° C. (2 min)-500° C. (13 min) heating rate 15° C./min

Carrier gas: helium

Septum purge flow rate: 5 mL/min

Split ratio: 25:1

Interface temperature: 250° C.

Ion source temperature: 200° C.

Measurement mode: Scan m/z=85˜500

Amount of sample introduced: 1 μL

[Metal Impurities]

<Metal-Containing Particles>

The content of metal-containing particles in each chemical liquid was measured by a method using SP-ICP-MS.

The used device is as follows.
Manufacturer: PerkinElmer
Model: NexION350S

The following analysis software was used for analysis.
Syngistix nano application module dedicated for “SP-ICP-MS”

<Content of Metal Ions and Content of Atoms as Measurement Target>

First, the content of metal impurities in the chemical liquid was measured using Agilent 8800 triple quadrupole ICP-MS (for semiconductor analysis, option #200) according to the following measurement condition. The content of the metal ions in the chemical liquid was determined by subtracting the content of the metal-containing particles measured by SP-ICP-MS described above from the measured content of the metal impurities in the chemical liquid.

The content of atoms as a measurement target (Fe atoms, Cr atoms, Ni atoms, and Pb atoms) contained in the metal impurities in the chemical liquid and the content of each type of atoms were also measured using Agilent 8800 triple quadrupole ICP-MSA (for semiconductor analysis, option #200) according to the following measurement conditions.

(Measurement Conditions)

As a sample introduction system, a quartz torch, a coaxial perfluoroalkoxyalkane (PFA) nebulizer (for self-suction), and a platinum interface cone were used. The measurement parameters of cool plasma conditions are as follows.
Output of Radio Frequency (RF) (W): 600
Flow rate of carrier gas (L/min): 0.7
Flow rate of makeup gas (L/min): 1
Sampling depth (mm): 18

<Metal Nanoparticles>

The number of metal nanoparticles (metal-containing particles having a particle size of 0.5 to 17 nm) contained in the chemical liquid was measured by the following method.

First, a 100 nm oxide film was deposited on a silicon substrate and then coated with each chemical liquid, thereby forming a substrate with a chemical liquid layer. After being spin-dried, the substrate with a chemical liquid layer was subjected to dry etching, and then the positions of defects were identified using a wafer inspection device “SP-5” manufactured by KLA-Tencor Corporation. (defects were detected using the method described in paragraphs “0015” to “0067” in JP2009-188333A). That is, a SiO_{X} layer was formed on a substrate by a chemical vapor deposition (CVD) method, and a chemical liquid layer covering the SiO_{X} layer was formed. Subsequently, a method was used in which the composite layer including the SiO_{X} layer and the chemical liquid layer with which the SiO_{X} layer was coated was subjected to dry etching, the obtained projections were irradiated with light, the scattered light was detected, the volume of the projections was calculated from the scattered light, and the particle size of the particles was calculated from the volume of the projections. By this method, the particle size of the original residues was magnified, which made all the defects have size equal to or higher than the sensitivity of the wafer inspection device “SP-5”. The positions of defects present on a surface of the substrate on which the original residues have a particle size equal to or greater than 0.5 nm were identified by the wafer inspection device “SP-5”. The particle size of the original residues was measured by a scanning electron microscope (SEM).

Then, based on the positions of the defects, elemental analysis was performed by energy dispersive X-ray (EDX) spectroscopy, and the composition of the defects was investigated, thereby determining the number of metal-containing particles (metal nanoparticles) having a particle size of 0.5 to 17 nm.

<Number of Metal Nanoparticles Containing Fe, Al, and Ti Atoms>

The content of metal nanoparticles (particles having a particle size of 0.5 to 17 nm) containing Fe, Al, and Ti atoms in the chemical liquid was measured by the following method.

First, a silicon substrate was coated with a certain amount of chemical liquid, thereby forming a substrate with a chemical liquid layer. Then, the surface of the substrate with a chemical liquid layer was scanned with a laser beam, and the scattered light was detected. In this way, the position and particle size of defects present on the surface of the substrate with a chemical liquid layer were specified. Thereafter, based on the position of the defects, elemental analysis was carried out by the energy dispersive X-ray (EDX) spectroscopy, thereby investigating the composition of the defects. By this method, the number of Fe nanoparticles containing Fe atoms, the number of Al nanoparticles containing Al atoms, and the number of Ti nanoparticles containing Ti atoms on the substrate were determined. The determined numbers were respectively converted into the number of particles contained in a unit volume of the chemical liquid (particles/cm³), and added up.

In the same manner as described above, the first iron oxide nanoparticles containing only iron oxide (particle size: 0.5 to 17 nm) and the second iron oxide nanoparticles containing iron oxide and an organic compound (particle size: 0.5 to 17 nm) were also identified.

For pattern analysis, a wafer inspection device “SP-5” manufactured by KLA-Tencor Corporation. and a fully automatic defect review/classification device “SEMVision G6” manufactured by Applied Materials, Inc. were used in combination.

For a sample in which particles having a desired particle size could not be detected due to the resolution of a measurement device and the like, the method described in paragraphs “0015” to “0067” in JP2009-188333A was used for detection. That is, a SiO_{X} layer was formed on a substrate by a chemical vapor deposition (CVD) method, and then a chemical liquid layer covering the SiO_{X} layer was formed. Thereafter, a method was used in which the composite layer including the SiO_{X} layer and the chemical liquid layer with which the SiO_{X} layer was coated was subjected to dry etching, the obtained projections were irradiated with light, the scattered light was detected, the volume of the projections was calculated from the scattered light, and the particle size of the particles was calculated from the volume of the projections.

[Number of Coarse Particles]

The number of coarse particles contained in the chemical liquid (number of objects to be counted having a size equal to or greater than 0.04 μm that are counted by a light scattering liquid-borne particle counter: particles/mL) was measured by the following method.

First, the chemical liquid stored in a storage tank was left to stand at room temperature for one day after being stored. For the chemical liquid that had been left to stand, by using a light scattering liquid-borne particle counter (manufactured by RION Co., Ltd., model number: KS-18F, light source: semiconductor laser excited solid-state laser (wavelength: 532 nm, rated output 500 mW), flow rate: 10 mL/min, based on dynamic light scattering method as the principle of measurement), the number of particles having a size equal to or greater than 0.04 μm contained in 1 mL of the chemical liquid was counted 5 times, and the average thereof was adopted as the number of coarse particles.

The light scattering liquid-borne particle counter was used after being calibrated with a Polystyrene Latex (PSL) standard particle solution.

[Water Content]

The content of water in the chemical liquid (water content) was measured using a device which adopts the Karl Fischer titration method as the principle of measurement.

### Examples A-1 to A-22

Each of the chemical liquids was taken out of the chemical liquid storage body and subjected to the following various evaluation tests. The chemical liquids of Examples A-1 to A-22 can be used as a developer.

A 12-inch silicon wafer was prepared, and the number of particles having a diameter equal to or greater than 19 nm (hereinafter, these particles will be called “defects”) present on the substrate was counted using a wafer surface inspection device (SP-5; manufactured by KLA-Tencor Corporation) (the counted number will be called initial value). Then, by using a spin jet device, a predetermined amount of each chemical liquid was uniformly jetted to a surface of the substrate. Thereafter, the substrate was spin-dried. The number of defects present on the substrate having been coated with the chemical liquid was counted (the counted number will be called measured value). The difference between the initial value and the measured value (measured value−initial value) was calculated. The obtained results (data on the number of defects and the coordinates of defects) were analyzed additionally using a fully automated defect review classification device “SEMVision G6” from Applied Materials, Inc., and the number of residues per unit area was counted.

All the residues were analyzed using EDAX (energy dispersive X-ray spectroscopic analyzer) of G6 (fully automated defect review classification device “SEMVision G6”). In this way, the number of metal residues (residues containing only simple metal atoms), the number of metal oxide residues (residues that contain metal oxides but do not contain an organic compound), the number of organic metal residues (residues containing metal atoms and an organic compound), and the number of organic substance residues (residues that contain an organic compound but do not contain metal atoms) were counted.

The results were evaluated according to the following standard.

AA: The number of defects was less than 100.

A: The number of defects was equal to or greater than 100 and less than 150.

B: The number of defects was equal to or greater than 150 and less than 200.

C: The number of defects was equal to or greater than 200 and less than 300.

D: The number of defects was equal to or greater than 300 and less than 500.

E: The number of defects was equal to or greater than 500.

[Evaluation of Stability of Chemical Liquid]

After being taken out the chemical liquid storage body, the chemical liquid was stored at 23° C. for 1 year in a container (manufactured by SUN FLUORO SYSTEM Co., Ltd.) including a liquid contact portion made of PFA (copolymer of polytetrafluoroethylene and perfluoroalkoxyethylene). Thereafter, the chemical liquid was subjected to the same evaluation as in “Evaluation test for metal residues, metal oxide residues, organic metal residues, and organic substance residues” described above. The rate of change in the number of defects in the chemical liquid before and after storage was calculated, and the stability of the chemical liquid was evaluated according to the following standard. What is listed in each table is a result obtained from residues showing the highest rate of change among all the residues described above.

Rate of change in number of defects (%)=100×(number of defects in chemical liquid after storage−number of defects in chemical liquid before storage)/(number of defects in chemical liquid before storage)

AA: The rate of change in the number of defects is less than 5%

A: The rate of change in the number of defects is equal to or higher than 5% and less than 8%.

B: The rate of change in the number of defects is equal to or higher than 8% and less than 10%

C: The rate of change in the number of defects is equal to or higher than 10% and less than 15%

D: The rate of change in the number of defects is equal to or higher than 15%

### Examples B-1 to B-22

Each of the chemical liquids was taken out of the chemical liquid storage body and subjected to various evaluation tests as in Examples A-1 to A-22. The chemical liquids of Examples B-1 to B-22 can be used as a prewet solution.

### Examples C-1 to C-22

Each of the chemical liquids was taken out of the chemical liquid storage body and subjected to various evaluation tests as in Examples A-1 to A-22. The chemical liquids of Examples C-1 to C-22 can be used as a prewet solution.

### Examples D-1 to D-22

The chemical liquid (10 L) of Comparative Example 1, which will be described later, taken out of the chemical liquid storage body was poured into piping (piping length: 20 m, material of liquid contact portion: EP-SUS) so that the piping was contaminated intentionally. Subsequently, 500 L of each of the chemical liquids of Examples D1 to D22 taken out of the chemical liquid storage body was poured into the piping so that the piping was washed, and then each of the chemical liquids was collected. In this way, each of the chemical liquids of Examples D1 to D22 was used as a piping washing solution.

Each of the collected chemical liquids of Examples D1 to D22 was subjected to various evaluation tests as in Examples A-1 to A-22.

### Examples E-1 to E-22

Each of the chemical liquids was taken out of the chemical liquid storage body and subjected to various evaluation tests as in Examples A-1 to A-22. The chemical liquids of Examples E-1 to E-22 can be used as a prewet solution.

### Example F-1, Example G-1, Example H-1, and Comparative Example 1

The chemical liquids of Example F-1, Example G-1, and Example H-1 were taken out of the chemical liquid storage body and subjected to various evaluation tests as in A-1 to A-22. The chemical liquids of Example F-1, Example G-1, and Example H-1 can be used as a prewet solution.

In addition, the chemical liquid of Comparative Example 1 was taken out of the chemical liquid storage body and subjected to various evaluation tests as in Examples A-1 to A-22. The chemical liquid of Comparative Example 1 can be used as a developer.

The results of the above evaluation tests are shown in the following tables.

In each table, the descriptions such as “6.7E+00”, “2.5E+01”, and “1.3E−02” are abbreviations for exponential notations. Specifically, for example, “6.7E+00” means “6.7”, “2.5E+01” means “2.5×10¹”, and “1.3E−02” means “1.3×10⁻²”.

In each table, “A/B” means “content of phosphoric acid ester/content of adipic acid ester”, “A/C” means “content of phosphoric acid ester content/content of phthalic acid ester”, “B/C” means “content of adipic acid ester/content of phthalic acid ester”, “A/D” means “content of phosphoric acid ester/content of alcohol or acetone”, “B/D” means “content of adipic acid ester/content of alcohol or acetone”, “C/D” means “content of phthalic acid ester/content of alcohol or acetone”, “water/D” means “content of water/content of alcohol or acetone”, “water/E” means “content of water/content of stabilizer”, and “D/E” means “content of alcohol or acetone/content of stabilizer”. Furthermore, “A/tributyl phosphate” means “content of phosphoric acid ester/content of tributyl phosphate”, “tributyl phosphate/C” means “content of tributyl phosphate/content of phthalic acid ester”, “tributyl phosphate/D” means “content of tributyl phosphate/content of alcohol or acetone”, and “tributyl phosphate/E” means “content of tributyl phosphate/content of stabilizer”.

TABLE 7

| | Organic impurities and water | | | | | | | | | | |
|---|---|---|---|---|---|---|---|---|---|---|---|
| | A. | | B. | C. | | | | | | | D. |
| | Phosphoric | Tributyl | Adipic | phthalic | | | | | | Water | Alcohol |
| | acid ester | phosphate | acid ester | acid ester | | | | A/ | Tributyl | content | or |
| | (mass | (mass | (mass | (mass | | | | Tributyl | phosphate/ | (% by | acetone |
| | ppt) | ppt) | ppt) | ppt) | A/B | A/C | B/C | phosphate | C | mass) | Type |
| Example | 0.08 | 0.016 | 0.012 | 0.009 | 6.7E+00 | 8.9E+00 | 1.3E+00 | 5.0E+00 | 1.8E+00 | 0.05 | n-Butanol |
| A-1 | | | | | | | | | | | |
| Example | 0.15 | 0.008 | 0.006 | 0.005 | 2.5E+01 | 3.3E+01 | 1.3E+00 | 1.9E+01 | 1.8E+00 | 0.05 | n-Butanol |
| A-2 | | | | | | | | | | | |
| Example | 30 | 7 | 6 | 4 | 5.4E+00 | 7.2E+00 | 1.3E+00 | 4.1E+00 | 1.8E+00 | 0.05 | n-Butanol |
| A-3 | | | | | | | | | | | |
| Example | 450 | 169 | 127 | 95 | 3.6E+00 | 4.7E+00 | 1.3E+00 | 2.7E+00 | 1.8E+00 | 0.05 | n-Butanol |
| A-4 | | | | | | | | | | | |
| Example | 5,600 | 3,840 | 2,880 | 2,160 | 1.9E+00 | 2.6E+00 | 1.3E+00 | 1.5E+00 | 1.8E+00 | 0.05 | n-Butanol |
| A-5 | | | | | | | | | | | |
| Example | 78,000 | 52,000 | 39,000 | 29,250 | 2.0E+00 | 2.7E+00 | 1.3E+00 | 1.5E+00 | 1.8E+00 | 0.05 | n-Butanol |
| A-6 | | | | | | | | | | | |
| Example | 85,000 | 31,058 | 23,293 | 17,470 | 3.6E+00 | 4.9E+00 | 1.3E+00 | 2.7E+00 | 1.8E+00 | 0.05 | n-Butanol |
| A-7 | | | | | | | | | | | |
| Example | 96,000 | 51,200 | 38,400 | 28,800 | 2.5E+00 | 3.3E+00 | 1.3E+00 | 1.9E+00 | 1.8E+00 | 0.05 | n-Butanol |
| A-8 | | | | | | | | | | | |
| Example | 65,000 | 27,083 | 20,312 | 1,523,430 | 3.2E+00 | 4.3E−02 | 1.3E−02 | 2.4E+00 | 1.8E−02 | 0.05 | n-Butanol |
| A-9 | | | | | | | | | | | |
| Example | 89,000 | 44,144 | 331 | 24,831 | 2.7E+02 | 3.6E+00 | 1.3E−02 | 2.0E+00 | 1.8E+00 | 0.05 | n-Butanol |
| A-10 | | | | | | | | | | | |
| Example | 77,000 | 71,456 | 53,592 | 40,194 | 1.4E+00 | 1.9E+00 | 1.3E+00 | 1.1E+00 | 1.8E+00 | 0.05 | n-Butanol |
| A-11 | | | | | | | | | | | |
| Example | 64,000 | 36,894 | 27,671 | 20,753 | 2.3E+00 | 3.1E+00 | 1.3E+00 | 1.7E+00 | 1.8E+00 | 0.05 | n-Butanol |
| A-12 | | | | | | | | | | | |
| Example | 91,000 | 64,610 | 48,458 | 36,343 | 1.9E+00 | 2.5E+00 | 1.3E+00 | 1.4E+00 | 1.8E+00 | 0.05 | n-Butanol |
| A-13 | | | | | | | | | | | |
| Example | 32,000 | 14,987 | 26,240 | 19,680 | 1.2E+00 | 1.6E+00 | 1.3E+00 | 2.1E+00 | 7.6E−01 | 0.05 | n-Butanol |
| A-14 | | | | | | | | | | | |
| Example | 45,000 | 35,280 | 4 | 19,845 | 1.1E+04 | 2.3E+00 | 2.0E−04 | 1.3E+00 | 1.8E+00 | 0.05 | n-Butanol |
| A-15 | | | | | | | | | | | |
| Example | 48,000 | 15,396 | 115 | 8,660 | 4.2E+02 | 5.5E+00 | 1.3E−02 | 3.1E+00 | 1.8E+00 | 0.05 | n-Butanol |
| A-16 | | | | | | | | | | | |
| Example | 67,000 | 10,669 | 8,002 | 6,002 | 8.4E+00 | 1.1E+01 | 1.3E+00 | 6.3E+00 | 1.8E+00 | 0.05 | n-Butanol |
| A-17 | | | | | | | | | | | |
| Example | 72,000 | 20,800 | 15 | 11,700 | 4.8E+03 | 6.2E+00 | 1.3E+03 | 3.5E+00 | 1.8E+00 | 0.05 | n-Butanol |
| A-18 | | | | | | | | | | | |
| Example | 895,000 | 835,333 | 626,500 | 469,875 | 1.4E+00 | 1.9+00E | 1.3E+00 | 1.1E+00 | 1.8E+00 | 0.05 | n-Butanol |
| A-19 | | | | | | | | | | | |
| Example | 1,000,000 | 54,545 | 40,909 | 30,682 | 2.4E+01 | 3.3E+01 | 1.3E+00 | 1.8E+01 | 1.8E+00 | 0.05 | n-Butanol |
| A-20 | | | | | | | | | | | |
| Example | 56,800,000 | 16,408,889 | 12,306,667 | 9,230,000 | 4.6E+00 | 6.2E+00 | 1.3E+00 | 3.5E+00 | 1.8E+00 | 0.05 | n-Butanol |
| A-21 | | | | | | | | | | | |
| Example | 115,000,000 | 29,272,727 | 21,954,545 | 16,465,909 | 5.2E+00 | 7.0E+00 | 1.3E+00 | 3.9E+00 | 1.8E+00 | 0.05 | n-Butanol |
| A-22 | | | | | | | | | | | |
| | Organic impurities and water | | | | | | | | | | |
| | D. | | | | | | | | | | |
| | Alcohol | | | | | | | | | | |
| | or | | | | | | | | | | |
| | acetone | | | | | E. Stabilizer | | | | | |
| | Content | | | | Tributyl | | Content | | | Tributyl | |
| | (mass | | | | phosphate/ | | (mass | Water/ | Water/ | phosphate/ | |
| | ppm) | A/D | B/D | C/D | D | Type | ppm) | D | E | E | D/E |
| Example | 850 | 9.4E−05 | 1.4E−05 | 1.1E−05 | 1.9E−05 | — | — | 5.9E−01 | — | — | — |
| A-1 | | | | | | | | | | | |
| Example | 2,800 | 5.4E−05 | 2.2E−06 | 1.6E−06 | 2.9E−06 | — | — | 1.8E−01 | — | — | — |
| A-2 | | | | | | | | | | | |
| Example | 53 | 5.7E−01 | 1.0E−01 | 7.8E−02 | 1.4E−01 | — | — | 9.4E+00 | — | — | — |
| A-3 | | | | | | | | | | | |
| Example | 8 | 5.6E+01 | 1.6E+01 | 1.2E+01 | 2.1E+01 | — | — | 6.3E+00 | — | — | — |
| A-4 | | | | | | | | | | | |
| Example | 0.35 | 1.6E+04 | 8.2E+03 | 6.2E+03 | 1.1E+04 | — | — | 1.4E+03 | — | — | — |
| A-5 | | | | | | | | | | | |
| Example | 0.007 | 1.1E+07 | 5.6E+06 | 4.2E+ 06 | 7.4E+06 | — | — | 7.1E+04 | — | — | — |
| A-6 | | | | | | | | | | | |
| Example | 0.000004 | 2.1E+10 | 5.8E+09 | 4.4E+09 | 7.8E+09 | — | — | 1.3E+08 | — | — | — |
| A-7 | | | | | | | | | | | |
| Example | 0.0000002 | 6.4E+11 | 2.6E+11 | 1.9E+11 | 3.4E+11 | — | — | 3.3E+09 | — | — | — |
| A-8 | | | | | | | | | | | |
| Example | 0.0000008 | 8.1E+10 | 2.5E+10 | 1.9E+12 | 3.4E+10 | — | — | 6.3E+08 | — | — | — |
| A-9 | | | | | | | | | | | |
| Example | 250 | 3.6E+02 | 1.3E+00 | 9.9E+01 | 1.8E+02 | — | — | 2.0E+00 | — | — | — |
| A-10 | | | | | | | | | | | |
| Example | 125 | 6.2E+02 | 4.3E+02 | 3.2E+02 | 5.7E+02 | — | — | 4.0E+00 | — | — | — |
| A-11 | | | | | | | | | | | |
| Example | 85 | 7.5E+02 | 3.3E+02 | 2.4E+02 | 4.3E+02 | — | — | 5.9E+00 | — | — | — |
| A-12 | | | | | | | | | | | |
| Example | 200 | 4.6E+02 | 2.4E+02 | 1.8E+02 | 3.2E+02 | — | — | 2.5E+00 | — | — | — |
| A-13 | | | | | | | | | | | |
| Example | 150 | 2.1E+02 | 1.7E+02 | 1.3E+02 | 1.0E+02 | — | — | 3.3E+00 | — | — | — |
| A-14 | | | | | | | | | | | |
| Example | 250 | 1.8E+02 | 1.6E−02 | 7.9E+01 | 1.4E+02 | — | — | 2.0E+00 | — | — | — |
| A-15 | | | | | | | | | | | |
| Example | 530 | 9.1E+01 | 2.2E−01 | 1.6E+01 | 2.9E+01 | — | — | 9.4E−01 | — | — | — |
| A-16 | | | | | | | | | | | |
| Example | 310 | 2.2E+02 | 2.6E+01 | 1.9E+01 | 3.4E+01 | — | — | 1.6E+00 | — | — | — |
| A-17 | | | | | | | | | | | |
| Example | 40 | 1.8E+03 | 3.8E+01 | 2.9E+02 | 5.2E+02 | — | — | 1.3E+01 | — | — | — |
| A-18 | | | | | | | | | | | |
| Example | 120 | 7.5E+03 | 5.2E+03 | 3.9E+03 | 7.0E+03 | — | — | 1.2E+00 | — | — | — |
| A-19 | | | | | | | | | | | |
| Example | 550 | 1.8E+03 | 7.4E+01 | 5.6E+01 | 9.9E+01 | — | — | 9.1E−01 | — | — | — |
| A-20 | | | | | | | | | | | |
| Example | 450 | 1.3E+05 | 2.7E+04 | 2.1E+04 | 3.6E+04 | — | — | 1.1E+00 | — | — | — |
| A-21 | | | | | | | | | | | |
| Example | 550 | 2.1E+05 | 4.0E+04 | 3.0E+04 | 5.3E+04 | — | — | 9.1E−01 | — | — | — |
| A-22 | | | | | | | | | | | |

TABLE 8

| | Organic impurities and water | | | | | | | | | | |
|---|---|---|---|---|---|---|---|---|---|---|---|
| | A. | | B. | C. | | | | | | | D. |
| | Phosphoric | Tributyl | Adipic | phthalic | | | | | | Water | Alcohol |
| | acid ester | phosphate | acid ester | acid ester | | | | A/ | Tributyl | content | or |
| | (mass | (mass | (mass | (mass | | | | Tributyl | phosphate/ | (% by | acetone |
| | ppt) | ppt) | ppt) | ppt) | A/B | A/C | B/C | phosphate | C | mass) | Type |
| Example | 0.08 | 0.031 | 0.023 | 0.017 | 3.4E+00 | 4.5E+00 | 1.3E+00 | 2.6E+00 | 1.8E+00 | 0.05 | Cyclohexanol |
| B-1 | | | | | | | | | | | |
| Example | 0.15 | 0.015 | 0.012 | 0.009 | 1.3E+01 | 1.7E+01 | 1.3E+00 | 9.5E+00 | 1.8E+00 | 0.05 | Cyclohexanol |
| B-2 | | | | | | | | | | | |
| Example | 29 | 14 | 11 | 8 | 2.8E+00 | 3.7E+00 | 1.3E+00 | 2.1E+00 | 1.8E+00 | 0.05 | Cyclohexanol |
| B-3 | | | | | | | | | | | |
| Example | 441 | 324 | 243 | 182 | 1.8E+00 | 2.4E+00 | 1.3E+00 | 1.4E+00 | 1.8E+00 | 0.05 | Cyclohexanol |
| B-4 | | | | | | | | | | | |
| Example | 5,488 | 3,576 | 5,532 | 4,149 | 9.9E−01 | 1.3E+00 | 1.3E+00 | 1.5E+00 | 8.6E−01 | 0.05 | Cyclohexanol |
| B-5 | | | | | | | | | | | |
| Example | 76,440 | 46,882 | 74,911 | 56,183 | 1.0E+00 | 1.4E+00 | 1.3E+00 | 1.6E+00 | 8.3E−01 | 0.05 | Cyclohexanol |
| B-6 | | | | | | | | | | | |
| Example | 83,300 | 59,656 | 44,742 | 33,556 | 1.9E+00 | 2.5E+00 | 1.3E+00 | 1.4E+00 | 1.8E+00 | 0.05 | Cyclohexanol |
| B-7 | | | | | | | | | | | |
| Example | 94,080 | 65,345 | 73,759 | 55,319 | 1.3E+00 | 1.7E+00 | 1.3E+00 | 1.4E+00 | 1.2E+00 | 0.05 | Cyclohexanol |
| B-8 | | | | | | | | | | | |
| Example | 63,700 | 42,426 | 390,162 | 292,622 | 1.6E−01 | 2.2E−01 | 1.3E+00 | 1.5E+00 | 1.4E−01 | 0.05 | Cyclohexanol |
| B-9 | | | | | | | | | | | |
| Example | 87,220 | 84,792 | 63,594 | 47,695 | 1.4E+00 | 1.8E+00 | 1.3E+00 | 1.0E+00 | 1.8E+00 | 0.05 | Cyclohexanol |
| B-10 | | | | | | | | | | | |
| Example | 75,460 | 57,350 | 102,940 | 77,205 | 7.3E−01 | 9.3E−01 | 1.3E+00 | 1.3E+00 | 7.4E−01 | 0.05 | Cyclohexanol |
| B-11 | | | | | | | | | | | |
| Example | 62,720 | 47,667 | 53,150 | 39,862 | 1.2E+00 | 1.6E+00 | 1.3E+00 | 1.3E+00 | 1.2E+00 | 0.05 | Cyclohexanol |
| B-12 | | | | | | | | | | | |
| Example | 89,180 | 67,777 | 93,077 | 69,808 | 9.6E−01 | 1.3E+00 | 1.3E+00 | 1.3E+00 | 9.7E−01 | 0.05 | Cyclohexanol |
| B-13 | | | | | | | | | | | |
| Example | 31,360 | 23,834 | 50,402 | 37,801 | 6.2E−01 | 8.3E−01 | 1.3E+00 | 1.3E+00 | 6.3E−01 | 0.05 | Cyclohexanol |
| B-14 | | | | | | | | | | | |
| Example | 44,100 | 33,516 | 3 | 38,118 | 1.5E+04 | 1.2E+00 | 7.9E−05 | 1.3E+00 | 8.8E−01 | 0.05 | Cyclohexanol |
| B-15 | | | | | | | | | | | |
| Example | 47,040 | 29,573 | 221 | 16,635 | 2.1E+02 | 2.8E+00 | 1.3E−02 | 1.6E+00 | 1.8E+00 | 0.05 | Cyclohexanol |
| B-16 | | | | | | | | | | | |
| Example | 66,150 | 20,494 | 1,530 | 11,528 | 4.3E+01 | 5.7E+00 | 1.3E−01 | 3.2E+00 | 1.8E+00 | 0.05 | Cyclohexanol |
| B-17 | | | | | | | | | | | |
| Example | 70,560 | 39,953 | 29 | 22,473 | 2.4E+03 | 3.1E+00 | 1.3E−03 | 1.8E+00 | 1.8E+00 | 0.05 | Cyclohexanol |
| B-18 | | | | | | | | | | | |
| Example | 877,100 | 666,596 | 1,203,381 | 10,025,350 | 7.3E−01 | 8.7E−02 | 1.2E−01 | 1.3E+00 | 6.6E−02 | 0.05 | Cyclohexanol |
| B-19 | | | | | | | | | | | |
| Example | 980,000 | 104,771 | 78,578 | 58,934 | 1.2E+01 | 1.7E+01 | 1.3E+00 | 9.4E+00 | 1.8E+00 | 0.05 | Cyclohexanol |
| B-20 | | | | | | | | | | | |
| Example | 55,664,000 | 31,518,194 | 23,638,645 | 17,728,984 | 2.4E+00 | 3.1E+00 | 1.3E+00 | 1.8E+00 | 1.8E+00 | 0.05 | Cyclohexanol |
| B-21 | | | | | | | | | | | |
| Example | 112,700,000 | 56,227,055 | 42,170,291 | 31,627,718 | 2.7E+00 | 3.6E+00 | 1.3E+00 | 2.0E+00 | 1.8E+00 | 0.05 | Cyclohexanol |
| B-22 | | | | | | | | | | | |
| | Organic impurities and water | | | | | | | | | | |
| | D. | | | | | | | | | | |
| | Alcohol | | | | | | | | | | |
| | or | | | | | | | | | | |
| | acetone | | | | | E. Stabilizer | | | | | |
| | Content | | | | Tributyl | | Content | | | Tributyl | |
| | (mass | | | | phosphate/ | | (mass | Water/ | Water/ | phosphate/ | |
| | ppm) | A/D | B/D | C/D | D | Type | ppm) | D | E | E | D/E |
| Example | 425 | 1.8E−04 | 5.4E−05 | 4.1E−05 | 72E−05 | — | — | 1.2E+00 | — | — | — |
| B-1 | | | | | | | | | | | |
| Example | 1,400 | 1.1E−04 | 8.3E−06 | 6.2E−06 | 1.1E−05 | — | — | 3.6E−01 | — | — | — |
| B-2 | | | | | | | | | | | |
| Example | 27 | 1.1E+00 | 4.0E−01 | 3.0E−01 | 5.3E−01 | — | — | 1.9E+01 | — | — | — |
| B-3 | | | | | | | | | | | |
| Example | 4 | 1.1E+02 | 6.1E+01 | 4.6E+01 | 8.1E+01 | — | — | 1.3E+02 | — | — | — |
| B-4 | | | | | | | | | | | |
| Example | 0.18 | 3.1E+04 | 3.2E+04 | 2.4E+04 | 2.0E+04 | — | — | 2.9E+03 | — | — | — |
| B-5 | | | | | | | | | | | |
| Example | 0.004 | 2.2E+07 | 2.1E+07 | 1.6E+07 | 1.3E+07 | — | — | 1.4E+05 | — | — | — |
| B-6 | | | | | | | | | | | |
| Example | 0.000002 | 4.2E+10 | 2.2E+10 | 1.7E+10 | 3.0E+10 | — | — | 2.5E+08 | — | — | — |
| B-7 | | | | | | | | | | | |
| Example | 0.0000001 | 1.3E+12 | 9.8E+11 | 7.4E+11 | 8.7E+11 | — | — | 6.7E+09 | — | — | — |
| B-8 | | | | | | | | | | | |
| Example | 0.0000004 | 1.6E+11 | 9.8E+11 | 7.3E+11 | 1.1E+11 | — | — | 1.3E+09 | — | — | — |
| B-9 | | | | | | | | | | | |
| Example | 125 | 7.0E+02 | 5.1E+02 | 3.8E +02 | 6.8E+02 | — | — | 4.0E+00 | — | — | — |
| B-10 | | | | | | | | | | | |
| Example | 63 | 1.2E+03 | 1.6E+03 | 1.2E+03 | 9.2E+02 | — | — | 8.0E+00 | — | — | — |
| B-11 | | | | | | | | | | | |
| Example | 43 | 1.5E+03 | 1.3E+03 | 9.4E+02 | 1.1E+03 | — | — | 1.2E+01 | — | — | — |
| B-12 | | | | | | | | | | | |
| Example | 100 | 8.9E+02 | 9.3E+02 | 7.0E+02 | 6.8E+02 | — | — | 5.0E+00 | — | — | — |
| B-13 | | | | | | | | | | | |
| Example | 75 | 4.2E+02 | 6.7E+02 | 5.0E+02 | 3.2E+02 | — | — | 6.7E+00 | — | — | — |
| B-14 | | | | | | | | | | | |
| Example | 125 | 3.5E+02 | 2.4E−02 | 3.0E +02 | 2.7E+02 | — | — | 4.0E+00 | — | — | — |
| B-15 | | | | | | | | | | | |
| Example | 265 | 1.8E+02 | 8.3E+01 | 6.3E+01 | 1.1E+02 | — | — | 1.9E+00 | — | — | — |
| B-16 | | | | | | | | | | | |
| Example | 155 | 4.3E+02 | 9.9E+00 | 7.4E+01 | 1.3E+02 | — | — | 3.2E+00 | — | — | — |
| B-17 | | | | | | | | | | | |
| Example | 20 | 3.5E+03 | 1.5E+00 | 1.1E+03 | 2.0E+03 | — | — | 2.5E+01 | — | — | — |
| B-18 | | | | | | | | | | | |
| Example | 60 | 1.5E+04 | 2.0E+04 | 1.7E+05 | 1.1E+04 | — | — | 8.3E+00 | — | — | — |
| B-19 | | | | | | | | | | | |
| Example | 275 | 3.6E+03 | 2.9E+02 | 2.1E+02 | 3.8E+02 | — | — | 1.8E+00 | — | — | — |
| B-20 | | | | | | | | | | | |
| Example | 225 | 2.5E+05 | 1.1E+05 | 7.9E+04 | 1.4E+05 | — | — | 2.2E+00 | — | — | — |
| B-21 | | | | | | | | | | | |
| Example | 275 | 4.1E+05 | 1.5E+05 | 1.2E+05 | 2.0E+05 | — | — | 1.8E+00 | — | — | — |
| B-22 | | | | | | | | | | | |

TABLE 9

| | Organic impurities and water | | | | | | | | | | |
|---|---|---|---|---|---|---|---|---|---|---|---|
| | A. | | B. | C. | | | | | | | D. |
| | Phosphoric | Tributyl | Adipic | phthalic | | | | | | Water | Alcohol |
| | acid ester | phosphate | acid ester | acid ester | | | | A/ | Tributyl | content | or |
| | (mass | (mass | (mass | (mass | | | | Tributyl | phosphate/ | (% by | acetone |
| | ppt) | ppt) | ppt) | ppt) | A/B | A/C | B/C | phosphate | C | mass) | Type |
| Example | 0.09 | 0.025 | 0018 | 0.014 | 5.1E+00 | 6.8E+00 | 1.3E+00 | 3.8E+00 | 1.8E+00 | 0.05 | Acetone |
| C-1 | | | | | | | | | | | |
| Example | 0.18 | 0.012 | 0.009 | 0.007 | 1.9E+01 | 2.5E+01 | 1.3E+00 | 1.4E+01 | 1.8E+00 | 0.05 | Acetone |
| C-2 | | | | | | | | | | | |
| Example | 35 | 11 | 8 | 6 | 4.2E+00 | 5.5E+00 | 1.3E+00 | 3.1E+00 | 1.8E+00 | 0.05 | Acetone |
| C-3 | | | | | | | | | | | |
| Example | 529 | 259 | 194 | 146 | 2.7E+00 | 3.6E+00 | 1.3E+00 | 2.0E+00 | 1.8E+00 | 0.05 | Acetone |
| C-4 | | | | | | | | | | | |
| Example | 6,586 | 5,901 | 4,426 | 3,319 | 1.5E+00 | 2.0E+00 | 1.3E+00 | 1.1E+00 | 1.8E+00 | 0.05 | Acetone |
| C-5 | | | | | | | | | | | |
| Example | 91,728 | 79,905 | 59,929 | 44,947 | 1.5E+00 | 2.0E+00 | 1.3E+00 | 1.1E+00 | 1.8E+00 | 0.05 | Acetone |
| C-6 | | | | | | | | | | | |
| Example | 99,960 | 47,724 | 35793 | 26,845 | 2.8E+00 | 3.7E+00 | 1.3E+00 | 2.1E+00 | 1.8E+00 | 0.05 | Acetone |
| C-7 | | | | | | | | | | | |
| Example | 112,896 | 78,676 | 59,007 | 44,255 | 1.9E+00 | 2.6E+00 | 1.3E+00 | 1.4E+00 | 1.8E+00 | 0.05 | Acetone |
| C-8 | | | | | | | | | | | |
| Example | 76,440 | 58,094 | 31,213 | 2,340,970 | 2.4E+00 | 3.3E−02 | 1.3E−02 | 1.3E+00 | 2.5E−02 | 0.05 | Acetone |
| C-9 | | | | | | | | | | | |
| Example | 104,664 | 67,833 | 50,875 | 38,156 | 2.1E+00 | 2.7E+00 | 1.3E+00 | 1.5E+00 | 1.8E+00 | 0.05 | Acetone |
| C-10 | | | | | | | | | | | |
| Example | 90,552 | 68,820 | 82,352 | 61,764 | 1.1E+00 | 1.5E+00 | 1.3E+00 | 1.3E+00 | 1.1E+00 | 0.05 | Acetone |
| C-11 | | | | | | | | | | | |
| Example | 75,264 | 56,693 | 42,520 | 31,890 | 1.8E+00 | 2.4E+00 | 1.3E+00 | 1.3E+00 | 1.8E+00 | 0.05 | Acetone |
| C-12 | | | | | | | | | | | |
| Example | 107,016 | 99,282 | 74,462 | 55,846 | 1.4E+00 | 1.9E+00 | 1.3E+00 | 1.1E+00 | 1.8E+00 | 0.05 | Acetone |
| C-13 | | | | | | | | | | | |
| Example | 37,632 | 28,600 | 40,321 | 30,241 | 9.3E−01 | 1.2E+00 | 1.3E+00 | 1.3E+00 | 9.5E−01 | 0.05 | Acetone |
| C-14 | | | | | | | | | | | |
| Example | 52,920 | 40,219 | 4 | 30,495 | 1.3E+04 | 1.7E+00 | 1.3E−04 | 1.3E+00 | 1.3E+00 | 0.05 | Acetone |
| C-15 | | | | | | | | | | | |
| Example | 56,448 | 23,658 | 177 | 13308 | 3.2E+02 | 4.2E+00 | 1.3E−02 | 2.4E+00 | 1.8E+00 | 0.05 | Acetone |
| C-16 | | | | | | | | | | | |
| Example | 79,380 | 16,395 | 1,230 | 9,222 | 6.5E+01 | 8.6E+00 | 1.3E−01 | 4.8E+00 | 1.8E+00 | 0.05 | Acetone |
| C17 | | | | | | | | | | | |
| Example | 84,672 | 31,962 | 23 | 17,979 | 3.7E+03 | 4.7E+00 | 1.3E−03 | 2.6E+00 | 1.8E+00 | 0.05 | Acetone |
| C18 | | | | | | | | | | | |
| Example | 1,052,520 | 799,915 | 962,705 | 722,029 | 1.1E+00 | 1.5E+00 | 1.3E+00 | 1.3E+00 | 1.1E+00 | 0.05 | Acetone |
| C19 | | | | | | | | | | | |
| Example | 1,176,000 | 83,817 | 62,863 | 47,147 | 1.9E+01 | 2.5E+01 | 1.3E+00 | 1.4E+01 | 1.8E+00 | 0.05 | Acetone |
| C20 | | | | | | | | | | | |
| Example | 66,796,800 | 25,214,555 | 18,910,916 | 14,183,187 | 3.5E+00 | 4.7E+00 | 1.3E+00 | 2.6E+00 | 1.8E+00 | 0.05 | Acetone |
| C21 | | | | | | | | | | | |
| Example | 135,240,000 | 44,981,644 | 33,736,233 | 25,302,175 | 4.0E+00 | 5.3E+00 | 1.3E+00 | 3.0E+00 | 1.8E+00 | 0.05 | Acetone |
| C22 | | | | | | | | | | | |
| | Organic impurities and water | | | | | | | | | | |
| | D. | | | | | | | | | | |
| | Alcohol | | | | | | | | | | |
| | or | | | | | | | | | | |
| | acetone | | | | | E. Stabilizer | | | | | |
| | Content | | | | Tributyl | | Content | | | Tributyl | |
| | (mass | | | | phosphate/ | | (mass | Water/ | Water/ | phosphate/ | |
| | ppm) | A/D | B/D | C/D | D | Type | ppm) | D | E | E | D/E |
| Example | 765 | 1.2E−04 | 2.4E−05 | 1.8E−05 | 3.2E−05 | — | — | 6.5E−01 | — | — | — |
| C-1 | | | | | | | | | | | |
| Example | 2,520 | 7.0E−05 | 3.7E−06 | 2.8E−06 | 4.9E−06 | — | — | 2.0E−01 | — | — | — |
| C-2 | | | | | | | | | | | |
| Example | 48 | 7.4E−01 | 1.8E−01 | 1.3E−01 | 2.4E−01 | — | — | 1.0E+01 | — | — | — |
| C-3 | | | | | | | | | | | |
| Example | 7 | 7.4E+01 | 2.7E+01 | 2.0E+01 | 3.6E+01 | — | — | 6.9E+01 | — | — | — |
| C-4 | | | | | | | | | | | |
| Example | 0.32 | 2.1E+04 | 1.4E+04 | 1.1E+04 | 1.9E+04 | — | — | 1.6E+03 | — | — | — |
| C-5 | | | | | | | | | | | |
| Example | 0.006 | 1.5E+07 | 9.5E+06 | 7.1E+06 | 1.3E+07 | — | — | 7.9E+04 | — | — | — |
| C-6 | | | | | | | | | | | |
| Example | 0.000004 | 2.8E+10 | 9.9E+09 | 7.5E+09 | 1.3E+10 | — | — | 1.4E+08 | — | — | — |
| C-7 | | | | | | | | | | | |
| Example | 0.0000001 | 8.4E+11 | 4.4E+11 | 3.3E+11 | 5.8E+11 | — | — | 3.7E+09 | — | — | — |
| C-8 | | | | | | | | | | | |
| Example | 0.0000007 | 1.1E+11 | 4.3E+10 | 3.3E+12 | 8.1E+10 | — | — | 6.9E+08 | — | — | — |
| C-9 | | | | | | | | | | | |
| Example | 225 | 4.7E+02 | 2.3E+02 | 1.7E+02 | 3.0E+02 | — | — | 2.2E+00 | — | — | — |
| C-10 | | | | | | | | | | | |
| Example | 113 | 8.0E+02 | 7.3E+02 | 5.5E+02 | 6.1E+02 | — | — | 4.4E+00 | — | — | — |
| C-11 | | | | | | | | | | | |
| Example | 77 | 9.8E+02 | 5.6E+02 | 4.2E+02 | 7.4E+02 | — | — | 6.5E+00 | — | — | — |
| C-12 | | | | | | | | | | | |
| Example | 180 | 5.9E+02 | 4.1E+02 | 3.1E+02 | 5.5E+02 | — | — | 2.8E+00 | — | — | — |
| C-13 | | | | | | | | | | | |
| Example | 135 | 2.8E+02 | 3.0E+02 | 2.2E+02 | 2.1E+02 | — | — | 3.7E+00 | — | — | — |
| C-14 | | | | | | | | | | | |
| Example | 225 | 2.4E+02 | 1.8E+02 | 1.4E+02 | 1.8E+02 | — | — | 2.2E+00 | — | — | — |
| C-15 | | | | | | | | | | | |
| Example | 477 | 1.2E+02 | 3.7E−01 | 2.8E+01 | 5.0E+01 | — | — | 1.0E+00 | — | — | — |
| C-16 | | | | | | | | | | | |
| Example | 279 | 2.8E+02 | 4.4E+00 | 3.3E+01 | 5.9E+01 | — | — | 1.8E+00 | — | — | — |
| C17 | | | | | | | | | | | |
| Example | 36 | 2.4E+03 | 6.4E+01 | 5.0E+02 | 8.9E+02 | — | — | 1.4E+01 | — | — | — |
| C18 | | | | | | | | | | | |
| Example | 108 | 9.7E+03 | 8.9E+03 | 6.7E+03 | 7.4E+03 | — | — | 4.6E+00 | — | — | — |
| C19 | | | | | | | | | | | |
| Example | 495 | 2.4E+03 | 1.3E+02 | 9.5E+01 | 1.7E+02 | — | — | 1.0E+00 | — | — | — |
| C20 | | | | | | | | | | | |
| Example | 405 | 1.6E+05 | 4.7E+04 | 3.5E+04 | 6.2E+04 | — | — | 1.2E+00 | — | — | — |
| C21 | | | | | | | | | | | |
| Example | 495 | 2.7E+05 | 6.8E+04 | 5.1E+04 | 9.1E+04 | — | — | 1.0E+00 | — | — | — |
| C22 | | | | | | | | | | | |

TABLE 10

| | Organic impurities and water | | | | | | | | | | |
|---|---|---|---|---|---|---|---|---|---|---|---|
| | A. | | B. | C. | | | | | | | D. |
| | Phosphoric | Tributyl | Adipic | phthalic | | | | | | Water | Alcohol |
| | acid ester | phosphate | acid ester | acid ester | | | | A/ | Tributyl | content | or |
| | (mass | (mass | (mass | (mass | | | | Tributyl | phosphate/ | (% by | acetone |
| | ppt) | ppt) | ppt) | ppt) | A/B | A/C | B/C | phosphate | C | mass) | Type |
| Example | 0.07 | 0.011 | 0.008 | 0.006 | 8.5E+00 | 1.1E+01 | 1.3E+00 | 6.4E+00 | 1.8E+00 | 0.05 | Ethanol |
| D-1 | | | | | | | | | | | |
| Example | 0.13 | 0.006 | 0.004 | 0.003 | 3.2E+01 | 4.2E+01 | 1.3E+00 | 2.4E+01 | 1.8E+00 | 0.05 | Ethanol |
| D-2 | | | | | | | | | | | |
| Example | 26 | 5 | 4 | 3 | 6.9E+00 | 9.2E+00 | 1.3E+00 | 5.2E+00 | 1.8E+00 | 0.05 | Ethanol |
| D-3 | | | | | | | | | | | |
| Example | 397 | 117 | 88 | 66 | 4.5E+00 | 6.0E+00 | 1.3E+00 | 3.4E+00 | 1.8E+00 | 0.05 | Ethanol |
| D-4 | | | | | | | | | | | |
| Example | 4,939 | 2,655 | 1,991 | 1,494 | 2.5E+00 | 3.3E+00 | 1.3E+00 | 1.9E+00 | 1.8E+00 | 0.05 | Ethanol |
| D-5 | | | | | | | | | | | |
| Example | 68 ,796 | 35,957 | 26,968 | 20,226 | 2.6E+00 | 3.4E+00 | 1.3E+00 | 1.9E+00 | 1.8E+00 | 0.05 | Ethanol |
| D-6 | | | | | | | | | | | |
| Example | 74,970 | 21,476 | 16,107 | 12,080 | 4.7E+00 | 6.2E+00 | 1.3E+00 | 3.5E+00 | 1.8E+00 | 0.05 | Ethanol |
| D-7 | | | | | | | | | | | |
| Example | 84,672 | 35,404 | 26553 | 19,915 | 3.2E+00 | 4.3E+00 | 1.3E+00 | 2.4E+00 | 1.8E+00 | 0.05 | Ethanol |
| D-8 | | | | | | | | | | | |
| Example | 57,330 | 43,571 | 140,459 | 105,344 | 4.1E−01 | 5.4E−01 | 1.3E+00 | 1.3E+00 | 4.1E−01 | 0.05 | Ethanol |
| D-9 | | | | | | | | | | | |
| Example | 78,498 | 30,525 | 22,894 | 17,170 | 3.4E+00 | 4.6E+00 | 1.3E+00 | 2.6E+00 | 1.8E+00 | 0.05 | Ethanol |
| D-10 | | | | | | | | | | | |
| Example | 67,914 | 49,411 | 37,058 | 27,794 | 1.8E+00 | 2.4E+00 | 1.3E+00 | 1.4E+00 | 1.8E+00 | 0.05 | Ethanol |
| D-11 | | | | | | | | | | | |
| Example | 56,448 | 25,512 | 19,134 | 14,350 | 3.0E+00 | 3.9E+00 | 1.3E+00 | 2.2E+00 | 1.8E+00 | 0.05 | Ethanol |
| D-12 | | | | | | | | | | | |
| Example | 80,262 | 44,677 | 33,508 | 2,513,000 | 2.4E+00 | 3.2E−02 | 1.3E−02 | 1.8E+00 | 1.8E− 02 | 0.05 | Ethanol |
| D-13 | | | | | | | | | | | |
| Example | 28,224 | 24,193 | 18,145 | 13,608 | 1.6E+00 | 2.1E+00 | 1.3E+00 | 1.2E+00 | 1.8E+00 | 0.05 | Ethanol |
| D-14 | | | | | | | | | | | |
| Example | 39,690 | 24,396 | 2 | 13723 | 2.0E+04 | 2.9E+00 | 1.5E−04 | 1.6E+00 | 1.8E+00 | 0.05 | Ethanol |
| D-15 | | | | | | | | | | | |
| Example | 42,336 | 10,646 | 798 | 5,989 | 5.3E+01 | 7.1E+00 | 1.3E−01 | 4.0E+00 | 1.8E+00 | 0.05 | Ethanol |
| D-16 | | | | | | | | | | | |
| Example | 59,535 | 7.378 | 55 | 4,150 | 1.1E+03 | 1.4E+01 | 1.3E−02 | 8.1E+00 | 1.8E+00 | 0.05 | Ethanol |
| D-17 | | | | | | | | | | | |
| Example | 63,504 | 14,383 | 11 | 8,090 | 5.8E+03 | 7.8E+00 | 1.4E−03 | 4.4E+00 | 1.8E+00 | 0.05 | Ethanol |
| D-18 | | | | | | | | | | | |
| Example | 789,390 | 577,623 | 433,217 | 324,913 | 1.8E+00 | 2.4E+00 | 1.3E+00 | 1.4E+00 | 1.8E+00 | 0.05 | Ethanol |
| D-19 | | | | | | | | | | | |
| Example | 882,000 | 37,718 | 28,288 | 21,216 | 3.1E+01 | 4.2E+01 | 1.3E+00 | 2.3E+01 | 1.8E+00 | 0.05 | Ethanol |
| D-20 | | | | | | | | | | | |
| Example | 50,097,600 | 11,346,550 | 8,509,912 | 6,382,434 | 5.9E+00 | 7.8E+00 | 1.3E+00 | 4.4E+00 | 1.8E+00 | 0.05 | Ethanol |
| D-21 | | | | | | | | | | | |
| Example | 101,430,000 | 20,241,740 | 15,181,305 | 11,385,979 | 6.7E+00 | 8.9E+00 | 1.3E+00 | 5.0E+00 | 1.8E+00 | 0.05 | Ethanol |
| D-22 | | | | | | | | | | | |
| | Organic impurities and water | | | | | | | | | | |
| | D. | | | | | | | | | | |
| | Alcohol | | | | | | | | | | |
| | or | | | | | | | | | | |
| | acetone | | | | | E. Stabilizer | | | | | |
| | Content | | | | Tributyl | | Content | | | Tributyl | |
| | (mass | | | | phosphate/ | | (mass | Water/ | Water/ | phosphate/ | |
| | ppm) | A/D | B/D | C/D | D | Type | ppm) | D | E | E | D/E |
| Example | 956 | 7.4E−05 | 8.7E−06 | 6.5E−06 | 1.2E−05 | — | — | 5.2E−01 | — | — | — |
| D-1 | | | | | | | | | | | |
| Example | 3,150 | 4.2E−05 | 1.3E−06 | 9.9E−07 | 1.8E−06 | — | — | 1.6E−01 | — | — | — |
| D-2 | | | | | | | | | | | |
| Example | 60 | 4.4E−01 | 6.4E−02 | 4.8E−02 | 8.5E−02 | — | — | 8.4E+00 | — | — | — |
| D-3 | | | | | | | | | | | |
| Example | 9 | 4.4E+01 | 9.7E+00 | 7.3E+00 | 1.3E+01 | — | — | 5.6E+01 | — | — | — |
| D-4 | | | | | | | | | | | |
| Example | 0.39 | 1.3E+04 | 5.1E+03 | 3.8E+03 | 6.7E+03 | — | — | 1.3E+03 | — | — | — |
| D-5 | | | | | | | | | | | |
| Example | 0.008 | 8.7E+06 | 3.4E+06 | 2.6E+06 | 4.6E+06 | — | — | 6.3E+04 | — | — | — |
| D-6 | | | | | | | | | | | |
| Example | 0.000005 | 1.7E+10 | 3.6E+09 | 2.7E+09 | 4.8E+09 | — | — | 1.1E+08 | — | — | — |
| D-7 | | | | | | | | | | | |
| Example | 0.0000002 | 5.0E+11 | 1.6E+11 | 1.2E+11 | 2.1E+11 | — | — | 3.0E+09 | — | — | — |
| D-8 | | | | | | | | | | | |
| Example | 0.0000009 | 6.4E+10 | 1.6E+11 | 1.2E+11 | 4.8E+10 | — | — | 5.6E+08 | — | — | — |
| D-9 | | | | | | | | | | | |
| Example | 281 | 2.8E+02 | 8.1E+01 | 6.1E+01 | 1.1E+02 | — | — | 1.8E+00 | — | — | — |
| D-10 | | | | | | | | | | | |
| Example | 141 | 4.8E+02 | 2.6E+02 | 2.0E+02 | 3.5E+02 | — | — | 3.6E+00 | — | — | — |
| D-11 | | | | | | | | | | | |
| Example | 96 | 5.9E+02 | 2.0E+02 | 1.5E+02 | 2.7E+02 | — | — | 5.2E+00 | — | — | — |
| D-12 | | | | | | | | | | | |
| Example | 225 | 3.6E+02 | 1.5E+02 | 1.1E+04 | 2.0E+02 | — | — | 2.2E+00 | — | — | — |
| D-13 | | | | | | | | | | | |
| Example | 169 | 1.7E+02 | 1.1E+02 | 8.1E+01 | 1.4E+02 | — | — | 3.0E+00 | — | — | — |
| D-14 | | | | | | | | | | | |
| Example | 281 | 1.4E+02 | 7.1E−03 | 4.9E+01 | 8.7E+01 | — | — | 1.8E+00 | — | — | — |
| D-15 | | | | | | | | | | | |
| Example | 596 | 7.1E+01 | 1.3E+00 | 1.0E+01 | 1.8E+01 | — | — | 8.4E−01 | — | — | — |
| D-16 | | | | | | | | | | | |
| Example | 349 | 1.7E+02 | 1.6E−01 | 1.2E+01 | 2.1E+01 | — | — | 1.4E+01 | — | — | — |
| D-17 | | | | | | | | | | | |
| Example | 45 | 1.4E+03 | 2.4E−01 | 1.8E+02 | 3.2E+02 | — | — | 1.1E+02 | — | — | — |
| D-18 | | | | | | | | | | | |
| Example | 135 | 5.8E+03 | 3.2E+03 | 2.4E+03 | 4.3E+03 | — | — | 3.7E+00 | — | — | — |
| D-19 | | | | | | | | | | | |
| Example | 619 | 1.4E+03 | 4.6E+01 | 3.4E+01 | 6.1E+01 | — | — | 8.1E−01 | — | — | — |
| D-20 | | | | | | | | | | | |
| Example | 506 | 9.9E+04 | 1.7E+04 | 1.3E+04 | 2.2E+04 | — | — | 9.9E−01 | — | — | — |
| D-21 | | | | | | | | | | | |
| Example | 619 | 1.6E+04 | 2.5E+04 | 1.8E+04 | 3.3E+04 | — | — | 8.1E−01 | — | — | — |
| D-22 | | | | | | | | | | | |

TABLE 11

| | Organic impurities and water | | | | | | | | | | |
|---|---|---|---|---|---|---|---|---|---|---|---|
| | A. | | B. | C. | | | | | | | D. |
| | Phosphoric | Tributyl | Adipic | phthalic | | | | | | Water | Alcohol |
| | acid ester | phosphate | acid ester | acid ester | | | | A/ | Tributyl | content | or |
| | (mass | (mass | (mass | (mass | | | | Tributyl | phosphate/ | (% by | acetone |
| | ppt) | ppt) | ppt) | ppt) | A/B | A/C | B/C | phosphate | C | mass) | Type |
| Example | 0.07 | 0.014 | 0.011 | 0.008 | 6.9E−00 | 9.2E+00 | 1.3E+00 | 5.2E+00 | 1.8E+00 | 0.05 | Methanol |
| E-1 | | | | | | | | | | | |
| Example | 0.14 | 0.007 | 0.005 | 0.004 | 2.6E+01 | 3.4E+01 | 1.3E+00 | 1.9E+01 | 1.8E+00 | 0.05 | Methanol |
| E-2 | | | | | | | | | | | |
| Example | 28 | 7 | 5 | 4 | 5.6E+00 | 7.5E+00 | 1.3E+00 | 4.2E+00 | 1.8E+00 | 0.05 | Methanol |
| E-3 | | | | | | | | | | | |
| Example | 417 | 151 | 114 | 85 | 3.7E+00 | 4.9E+00 | 1.3E+00 | 2.8E+00 | 1.8E+00 | 0.05 | Methanol |
| E-4 | | | | | | | | | | | |
| Example | 5,186 | 3,444 | 2,583 | 1,937 | 2.0E+00 | 2.7E+00 | 1.3E+00 | 1.5E+00 | 1.8E+00 | 0.05 | Methanol |
| E-5 | | | | | | | | | | | |
| Example | 72,236 | 46,639 | 34,979 | 26,234 | 2.1E+00 | 2.8E+00 | 1.3E+00 | 1.5E+00 | 1.8E+00 | 0.05 | Methanol |
| E-6 | | | | | | | | | | | |
| Example | 78,719 | 27,856 | 20,892 | 15,669 | 3.8E+00 | 5.0E+00 | 1.3E+00 | 2.8E+00 | 1.8E+00 | 0.05 | Methanol |
| E-7 | | | | | | | | | | | |
| Example | 88,906 | 45,921 | 34,441 | 25,831 | 2.6E+00 | 3.4E+00 | 1.3E+00 | 1.9E+00 | 1.8E+00 | 0.05 | Methanol |
| E-8 | | | | | | | | | | | |
| Example | 60,197 | 45,749 | 18,218 | 1,366,380 | 3.3E+00 | 4.4E−02 | 1.3E−02 | 1.3E+00 | 3.3E−02 | 0.05 | Methanol |
| E-9 | | | | | | | | | | | |
| Example | 82,423 | 39,593 | 29,695 | 22,271 | 2.8E+00 | 3.7E+00 | 1.3E+00 | 2.1E+00 | 1.8E+00 | 0.05 | Methanol |
| E-10 | | | | | | | | | | | |
| Example | 71,310 | 64,089 | 48,067 | 36,050 | 1.5E+00 | 2.0E+00 | 1.3E+00 | 1.1E+00 | 1.8E+00 | 0.05 | Methanol |
| E-11 | | | | | | | | | | | |
| Example | 59,270 | 33,090 | 24,818 | 18,613 | 2.4E+00 | 3.2E+00 | 1.3E+00 | 1.8E+00 | 1.8E+00 | 0.05 | Methanol |
| E-12 | | | | | | | | | | | |
| Example | 84,275 | 57,949 | 43,462 | 32.596 | 1.9E+00 | 2.6E+00 | 1.3E+00 | 1.5E+00 | 1.8E+00 | 0.05 | Methanol |
| E-13 | | | | | | | | | | | |
| Example | 29,635 | 22,523 | 23,535 | 17,651 | 1.3E+00 | 1.7E+00 | 1.3E+00 | 1.3E+00 | 1.8E+00 | 0.05 | Methanol |
| E-14 | | | | | | | | | | | |
| Example | 41,675 | 31,643 | 2 | 17,799 | 2.1E+04 | 2.3E+00 | 1.1E−04 | 1.3E+00 | 1.8E+00 | 0.05 | Methanol |
| E-15 | | | | | | | | | | | |
| Example | 44,453 | 13,809 | 103 | 7,767 | 4.3E+02 | 5.7E+00 | 1.3E−02 | 3.2E+00 | 1.8E+00 | 0.05 | Methanol |
| E-16 | | | | | | | | | | | |
| Example | 62,512 | 9,569 | 71 | 5,383 | 8.8E+02 | 1.2E+01 | 1.3E−02 | 6.5E+00 | 1.8E+00 | 0.05 | Methanol |
| E-17 | | | | | | | | | | | |
| Example | 66,679 | 18,656 | 13 | 10,494 | 5.1E+03 | 6.4E+00 | 1.2E−03 | 3.6E+00 | 1.8E+00 | 0.05 | Methanol |
| E-18 | | | | | | | | | | | |
| Example | 828,860 | 749,211 | 561,908 | 421,431 | 1.5E+00 | 2.0E+00 | 1.3E+00 | 1.1E+00 | 1.8E+00 | 0.05 | Methanol |
| E-19 | | | | | | | | | | | |
| Example | 926,100 | 48,922 | 36,691 | 27,519 | 2.5E+01 | 3.4E+01 | 1.3E+00 | 1.9E+01 | 1.8E+00 | 0.05 | Methanol |
| E-20 | | | | | | | | | | | |
| Example | 56,602,480 | 14,717,142 | 11,307,857 | 8,278,393 | 4.8E+00 | 6.4E+00 | 1.3E+00 | 3.6E+00 | 1.8E+00 | 0.05 | Methanol |
| E-21 | | | | | | | | | | | |
| Example | 106,501,500 | 26,254,727 | 19,691,045 | 14,768,284 | 5.4E+00 | 7.2E+00 | 1.3E+00 | 4.1E+00 | 1.8E+00 | 0.05 | Methanol |
| E-22 | | | | | | | | | | | |
| | Organic impurities and water | | | | | | | | | | |
| | D. | | | | | | | | | | |
| | Alcohol | | | | | | | | | | |
| | or | | | | | | | | | | |
| | acetone | | | | | E. Stabilizer | | | | | |
| | Content | | | | Tributyl | | Content | | | Tributyl | |
| | (mass | | | | phosphate/ | | (mass | Water/ | Water/ | phosphate/ | |
| | ppm) | A/D | B/D | C/D | D | Type | ppm) | D | E | E | D/E |
| Example | 813 | 9.1E−05 | 1.3E−05 | 9.9E−06 | 1.8E−05 | BHT | 3 | 6.2E−01 | 1.7E+02 | 4.8.E−03 | 2.7.E+02 |
| E-1 | | | | | | | | | | | |
| Example | 2,673 | 5.2E−05 | 2.0E−06 | 1.5E−06 | 2.7E−06 | BHT | 2 | 1.9E−01 | 2.5E−02 | 3.6.E−03 | 1.3.E+03 |
| E-2 | | | | | | | | | | | |
| Example | 51 | 5.5E−01 | 9.8E−02 | 7.3E−02 | 1.3E−01 | BHT | 3 | 9.9E+00 | 1.7E+02 | 2.2.E+00 | 1.7.E+01 |
| E-3 | | | | | | | | | | | |
| Example | 8 | 5.4E+01 | 1.5E+01 | 1.1E+01 | 2.0E+01 | BHT | 3 | 6.5E+01 | 1.7E+00 | 5.0.E+01 | 2.6.E+00 |
| E-4 | | | | | | | | | | | |
| Example | 0.33 | 1.5E+04 | 7.7E+03 | 5.8E+03 | 1.0E+04 | BHT | 3 | 1.5E+03 | 1.7E+02 | 1.1.E+03 | 1.1.E−01 |
| E-5 | | | | | | | | | | | |
| Example | 0.007 | 1.1E+07 | 5.2E+06 | 3.9E+06 | 7.0E+06 | BHT | 3 | 7.5E+04 | 1.7E+02 | 1.6.E+04 | 2.2.E−03 |
| E-6 | | | | | | | | | | | |
| Example | 0.000004 | 2.1E+10 | 5.5E+09 | 4.1E+09 | 7.3E+09 | BHT | 3 | 1.3E+08 | 1.7E+02 | 9.3.E+03 | 1.3.E−06 |
| E-7 | | | | | | | | | | | |
| Example | 0.0000001 | 6.2E+11 | 2.4E+11 | 1.8E+11 | 3.2E+11 | BHT | 3 | 3.5E+09 | 1.7E+02 | 1.5.E+04 | 4.8.E−08 |
| E-8 | | | | | | | | | | | |
| Example | 0.0000008 | 7.9E+10 | 2.4E+10 | 1.8E+12 | 6.0E+10 | BHT | 3 | 6.5E+08 | 1.7E+02 | 1.5.E+04 | 2.6.E−07 |
| E-9 | | | | | | | | | | | |
| Example | 239 | 3.4E+02 | 1.2E+02 | 9.3E+01 | 1.7E+02 | BHT | 3 | 2.1E+00 | 1.7E+00 | 1.3.E+04 | 8.0.E+01 |
| E-10 | | | | | | | | | | | |
| Example | 120 | 6.0E+02 | 4.0E+02 | 3.0E+02 | 5.4E+02 | BHT | 3 | 4.2E+00 | 1.7E+00 | 2.1.E+04 | 4.0.E+01 |
| E-11 | | | | | | | | | | | |
| Example | 81 | 7.3E+02 | 3.1E+02 | 2.3E+02 | 4.1E+02 | BHT | 3 | 6.2E+02 | 1.7E+02 | 1.1.E+04 | 2.7.E+01 |
| E-12 | | | | | | | | | | | |
| Example | 191 | 4.4E+02 | 2.3E+02 | 1.7E+02 | 3.0E+02 | BHT | 3 | 2.6E+00 | 1.7E+02 | 1.9.E+04 | 6.4.E+02 |
| E-13 | | | | | | | | | | | |
| Example | 143 | 2.1E+02 | 1.6E+02 | 1.2E+02 | 1.6E+02 | BHT | 3 | 3.5E+00 | 1.7E+02 | 7.5.E+03 | 4.8.E+01 |
| E-14 | | | | | | | | | | | |
| Example | 143 | 1.7E+02 | 8.4E−03 | 7.4E+01 | 1.3E+02 | BHT | 3 | 2.1E+02 | 1.7E+02 | 1.1.E+04 | 8.0.E+01 |
| E-15 | | | | | | | | | | | |
| Example | 507 | 8.8E+01 | 2.0E−01 | 1.5E+01 | 2.7E+01 | BHT | 3 | 9.9E−01 | 1.7+02E | 4.6.E+03 | 1.7.E+02 |
| E-16 | | | | | | | | | | | |
| Example | 296 | 2.1E+01 | 2.4E−01 | 1.8E+01 | 3.2E+01 | BHT | 3 | 1.7E+00 | 1.7E+02 | 3.2.E+03 | 9.9.E+01 |
| E-17 | | | | | | | | | | | |
| Example | 38 | 1.7E+03 | 3.4E−01 | 2.7E+02 | 4.9E+02 | BHT | 3 | 1.3E+01 | 1.7E+02 | 6.2.E+03 | 1.3.E+01 |
| E-18 | | | | | | | | | | | |
| Example | 115 | 7.2E+03 | 4.9E+03 | 3.7E+03 | 6.5E+03 | BHT | 3 | 4.4E+00 | 1.7E+02 | 2.5.E+05 | 3.8.E+01 |
| E-19 | | | | | | | | | | | |
| Example | 526 | 1.8E+03 | 7.0E+01 | 5.2E+01 | 9.3E+01 | BHT | 3 | 9.5E−01 | 1.7E+02 | 1.6.E+04 | 1.8.E+02 |
| E-20 | | | | | | | | | | | |
| Example | 430 | 1.2E+05 | 2.6E+04 | 1.9E+04 | 3.4E+04 | BHT | 3 | 1.2E+00 | 1.7E+02 | 4.9.E+06 | 1.4.E+02 |
| E-21 | | | | | | | | | | | |
| Example | 526 | 2.0E+05 | 3.7E+04 | 2.8E+04 | 5.0E+04 | BHT | 3 | 9.5E−01 | 1.7E+02 | 8.8.E.+06 | 1.8.E+02 |
| E-22 | | | | | | | | | | | |

TABLE 12

| | Organic impurities and water | | | | | | | | | | |
|---|---|---|---|---|---|---|---|---|---|---|---|
| | A. | | B. | C. | | | | | | | D. |
| | Phosphoric | Tributyl | Adipic | phthalic | | | | | | Water | Alcohol |
| | acid ester | phosphate | acid ester | acid ester | | | | A/ | Tributyl | content | or |
| | (mass | (mass | (mass | (mass | | | | Tributyl | phosphate/ | (% by | acetone |
| | ppt) | ppt) | ppt) | ppt) | A/B | A/C | B/C | phosphate | C | mass) | Type |
| Example | 84,500 | 20,218 | 15,164 | 11,373 | 5.6E+00 | 7.4E+00 | 1.3E+00 | 4.2E+00 | 1.8E+00 | 0.10 | Methanol |
| F-1 | | | | | | | | | | | |
| Example | 115,700 | 22,246 | 16,684 | 12,513 | 6.9E+00 | 9.2E+00 | 1.3E+00 | 5.2E+00 | 1.8E+00 | 0.10 | Methanol |
| G-1 | | | | | | | | | | | |
| Example | 100,100 | 19,582 | 14,687 | 11,015 | 6.8E+00 | 9.1E+00 | 1.3E+00 | 5.1E+00 | 1.8E+00 | 0.10 | Methanol |
| H-1 | | | | | | | | | | | Ethanol |
| Comparative | 83,200 | 63,232 | 90,918 | 66,194 | 9.2E−01 | 1.3E+00 | 1.4E+00 | 1.3E+00 | 9.6E−01 | 0.05 | n-Butanol |
| Example | | | | | | | | | | | |
| | Organic impurities and water | | | | | | | | | | |
| | D. | | | | | | | | | | |
| | Alcohol | | | | | | | | | | |
| | or | | | | | | | | | | |
| | acetone | | | | | E. Stabilizer | | | | | |
| | Content | | | | Tributyl | | Content | | | Tributyl | |
| | (mass | | | | phosphate/ | | (mass | Water/ | Water/ | phosphate/ | |
| | ppm) | A/D | B/D | C/D | D | Type | ppm) | D | E | E | D/E |
| Example | 691 | 1.2E+02 | 2.2E+01 | 1.6E+01 | 2.9E+01 | BHT | 3 | 1.4E+00 | 3.3E+02 | 6.7E+03 | 2.3E+02 |
| F-1 | | | | | | | | | | | |
| Example | 759 | 1.5E+02 | 2.2E+01 | 1.6E+01 | 2.9E+01 | BHT | 3 | 1.3+00 | 3.3E+02 | 7.4E+03 | 2.5E+02 |
| G-1 | | | | | | | | | | | |
| Example | 646 | 1.5E+02 | 2.3E+01 | 1.7E+01 | 3.0E+01 | BHT | 3 | 1.5E+00 | 3.3E+02 | 6.5E+03 | 2.2E+02 |
| H-1 | | | | | | | | | | | |
| Comparative | 650 | 1.3E+02 | 1.4E+02 | 1.02+02 | 9.7E+01 | — | — | 7.7E−01 | — | — | — |
| Example | | | | | | | | | | | |

TABLE 13

| | | | | | | | | Total | | | | | | | | |
|---|---|---|---|---|---|---|---|---|---|---|---|---|---|---|---|---|
| | | | | | | | | number | | | | | | | | |
| | | | | | | | | of Fe | | | | | | | | |
| | | | | | | | | nano- | | | | | | | | |
| | | | | | | | | parti- | | | | | | | | |
| | | | | | | | | cles | | | | | | | | |
| | | | | | | | | con- | | Num- | | | | | | |
| | | | | | | | | taining | | ber | | | | | | |
| | | | | | | | | Fe | | of | | | | | | |
| | | | | | | | | atoms, | | second | | | | | | |
| | | | | | | | | Al | | iron | | | | | | |
| | | | | | | | | nano- | | oxide | | | | | | |
| | | | | | | | | parti- | | nano- | | | | | | |
| | | | | | | | | cles | | parti- | | | | | | |
| | | | | | | | | con- | | cles | | | | | | |
| | | | | | | | | taining | | con- | | | | | | |
| | | | | | | | | Al | | tained | | | | | | |
| | | | | | | | | atoms, | Num- | in | | | | | | |
| | | | | | | | | and Ti | ber | chemi- | | | | | | |
| | | | | | | | | nano- | of | cal | | | | | | |
| | | | | | | | | parti- | first | liquid/ | | | | | | |
| | | | | | | | | cles | iron | Num- | | | | | | |
| | | | | | | | | con- | oxide | ber of | | | | | | |
| | | | | | | | | taining | nano- | first | | | | | | |
| | | | | | | | | Ti | parti- | iron | | | | | | |
| | | | Atom as measurement target | | | | | atoms | cles | oxide | | | | | | |
| | Metal | | | | | | Total | con- | con- | nano- | Num- | | | | | |
| | impurities | | | | | | content | tained | tained | parti- | ber | | | | | |
| | | Metal- | | | | | of atom | in | in | cles | of | Evaluation | | | | |
| | | con- | | | | | as | chemi- | chemi- | con- | coarse | | | | Or- | Stabi- |
| | | taining | | | | | measure- | cal | cal | tained | parti- | | | Or- | ganic | lity |
| | Metal | parti- | | | | | ment | liquid | liquid | in | cles | | Metal | ganic | sub- | of |
| | ions | cles | Fe | Cr | Ni | Pb | target | (part- | (parti- | chemi- | (parti- | Metal | oxide | metal | stance | chemi- |
| | (mass | (mass | (mass | (mass | (mass | (mass | (mass | icles/ | cles/ | cal | cles/ | resi- | resi- | resi- | resi- | cal |
| | ppt) | ppt) | ppt) | ppt) | ppt) | ppt) | ppt) | cm³) | cm³) | liquid | mL) | dues | dues | dues | dues | liquid |
| Example | 320 | 240 | 3 | 1 | 3 | 1 | 8 | 4.4E+03 | 4.2E+04 | 3.3E+02 | 12 | C | AA | AA | AA | A |
| A-1 | | | | | | | | | | | | | | | | |
| Example | 312 | 192 | 12 | 2 | 5 | 1 | 20 | 4.4E+04 | 2.5E+02 | 1.2E+03 | 30 | B | AA | AA | AA | D |
| A-2 | | | | | | | | | | | | | | | | |
| Example | 455 | 320 | 20 | 2 | 7 | 1 | 30 | 1.1E+05 | 1.4E+01 | 2.7E+02 | 45 | AA | AA | AA | AA | AA |
| A-3 | | | | | | | | | | | | | | | | |
| Example | 390 | 240 | 8 | 1 | 2 | 1 | 12 | 1.8E+04 | 5.9E+00 | 1.8E+02 | 18 | A | AA | AA | AA | AA |
| A-4 | | | | | | | | | | | | | | | | |
| Example | 260 | 160 | 4 | 1 | 3 | 1 | 9 | 6.7E+03 | 2.4E+00 | 9.7E+00 | 14 | A | A | AA | AA | AA |
| A-5 | | | | | | | | | | | | | | | | |
| Example | 325 | 200 | 7 | 1 | 4 | 1 | 13 | 1.7E+04 | 6.1E+06 | 1.0E+02 | 20 | AA | AA | A | AA | AA |
| A-6 | | | | | | | | | | | | | | | | |
| Example | 390 | 240 | 42 | 2 | 12 | 1 | 57 | 4.4E+05 | 1.8E+09 | 1.8E+02 | 86 | AA | AA | B | AA | AA |
| A-7 | | | | | | | | | | | | | | | | |
| Example | 470 | 320 | 38 | 3 | 10 | 1 | 52 | 3.7E+05 | 4.2E+11 | 1.3E+02 | 78 | A | AA | C | AA | A |
| A-8 | | | | | | | | | | | | | | | | |
| Example | 525 | 380 | 44 | 2 | 11 | 1 | 58 | 4.7E+05 | 3.3E+04 | 1.6E+02 | 87 | A | A | AA | AA | C |
| A-9 | | | | | | | | | | | | | | | | |
| Example | 270 | 166 | 20 | 2 | 7 | 1 | 30 | 1.1E+05 | 4.9E+04 | 1.3E+04 | 45 | AA | AA | AA | AA | AA |
| A-10 | | | | | | | | | | | | | | | | |
| Example | 293 | 180 | 21 | 2 | 7 | 1 | 31 | 1.2E+05 | 5.3E+04 | 7.2E+01 | 47 | AA | AA | AA | AA | AA |
| A-11 | | | | | | | | | | | | | | | | |
| Example | 280 | 172 | 32 | 2 | 10 | 1 | 45 | 2.7E+05 | 5.3E+04 | 1.2E+02 | 68 | AA | AA | AA | AA | AA |
| A-12 | | | | | | | | | | | | | | | | |
| Example | 273 | 168 | 35 | 1 | 11 | 1 | 48 | 3.1E+05 | 4.8E+00 | 9.4E+01 | 72 | AA | AA | AA | AA | AA |
| A-13 | | | | | | | | | | | | | | | | |
| Example | 286 | 176 | 42 | 1 | 7 | 1 | 51 | 4.0E+05 | 3.9E+10 | 6.1E+01 | 77 | AA | AA | AA | AA | AA |
| A-14 | | | | | | | | | | | | | | | | |
| Example | 325 | 200 | 32 | 1 | 8 | 1 | 42 | 2.5E+05 | 3.5E+04 | 5.6E+05 | 63 | AA | B | C | AA | AA |
| A-15 | | | | | | | | | | | | | | | | |
| Example | 300 | 150 | 18 | 2 | 9 | 1 | 30 | 1.0E+05 | 3.1E+04 | 2.1E+04 | 45 | AA | AA | AA | AA | A |
| A-16 | | | | | | | | | | | | | | | | |
| Example | 350 | 123 | 1,200 | 85 | 125 | 13 | 1,423 | 7.9E+09 | 3.0E+03 | 4.2E+02 | 123 | AA | A | AA | AA | AA |
| A-17 | | | | | | | | | | | | | | | | |
| Example | 163 | 100 | 1,800 | 123 | 250 | 11 | 2,184 | 1.8E+12 | 2.1E+03 | 2.4E+05 | 153 | AA | AA | AA | AA | AA |
| A-18 | | | | | | | | | | | | | | | | |
| Example | 368 | 129 | 0.005 | 0.001 | 0.001 | 0.001 | 0.008 | 1.5E+01 | 2.1E+03 | 7.1E+08 | 8 | AA | A | AA | AA | AA |
| A-19 | | | | | | | | | | | | | | | | |
| Example | 403 | 141 | 0.003 | 0.001 | 0.001 | 0.001 | 0.004 | 8.0E+00 | 4.8E+04 | 1.2E+03 | 3 | AA | AA | AA | AA | A |
| A-20 | | | | | | | | | | | | | | | | |
| Example | 325 | 260 | 4 | 1 | 3 | 1 | 9 | 6.7E+03 | 5.1E+04 | 2.3E+07 | 14 | A | AA | AA | AA | AA |
| A-21 | | | | | | | | | | | | | | | | |
| Example | 155 | 50 | 5 | 2 | 4 | 1 | 12 | 1.1E+04 | 3.5E+04 | 2.6E+02 | 18 | B | AA | AA | AA | A |
| A-22 | | | | | | | | | | | | | | | | |

TABLE 14

| | | | | | | | | Total | | Number | | | | | | |
|---|---|---|---|---|---|---|---|---|---|---|---|---|---|---|---|---|
| | | | | | | | | number | | of | | | | | | |
| | | | | | | | | of Fe | | second | | | | | | |
| | | | | | | | | nano- | | iron | | | | | | |
| | | | | | | | | particles | | oxide | | | | | | |
| | | | | | | | | containing | | nano- | | | | | | |
| | | | | | | | | Fe atoms, | | particles | | | | | | |
| | | | | | | | | Al nano- | | contained | | | | | | |
| | | | | | | | | particles | | in | | | | | | |
| | | | | | | | | containing | Number | chemical | | | | | | |
| | | | | | | | | Al atoms, | of first | liquid/ | | | | | | |
| | | | | | | | | and Ti | iron | Number | | | | | | |
| | | | Atom as measurement target | | | | | nano- | oxide | of first | | | | | | |
| | | | | | | | Total | particles | nano- | iron | | | | | | |
| | | | | | | | content of | containing | particles | oxide | | | | | | |
| | Metal impurities | | | | | | atom as | Ti atoms | contained | nano- | Number | | | | | |
| | | Metal- | | | | | measure- | contained in | in | particles | of | Evaluation | | | | |
| | Metal | containing | | | | | ment | chemical | chemical | contained | coarse | | | | | Stability |
| | ions | particles | Fe | Cr | Ni | Pb | target | liquid | liquid | in | particles | | Metal | Organic | Organic | of |
| | (mass | (mass | (mass | (mass | (mass | (mass | (mass | (particles/ | (particles/ | chemical | (particles/ | Metal | oxide | metal | substance | chemical |
| | ppt) | ppt) | ppt) | ppt) | ppt) | ppt) | ppt) | cm³) | cm³) | liquid | mL) | residues | residues | residues | residues | liquid |
| Example B-1 | 288 | 216 | 3 | 1 | 3 | 1 | 8 | 4.0E+03 | 6.2E+04 | 1.7E+02 | 11 | C | AA | AA | AA | AA |
| Example B-2 | 281 | 173 | 11 | 2 | 5 | 1 | 19 | 4.0E+04 | 3.8E+02 | 6.3E+02 | 29 | B | A | AA | AA | D |
| Example B-3 | 410 | 288 | 19 | 2 | 7 | 1 | 29 | 1.0E+05 | 2.1E+01 | 1.4E+02 | 43 | AA | AA | AA | AA | AA |
| Example B-4 | 351 | 216 | 8 | 1 | 2 | 1 | 11 | 1.6E+04 | 8.9E+00 | 9.1E+01 | 17 | A | AA | AA | AA | AA |
| Example B-5 | 234 | 144 | 4 | 1 | 3 | 1 | 9 | 6.0E+03 | 3.6E+00 | 5.0E+00 | 13 | A | A | AA | AA | AA |
| Example B-6 | 293 | 180 | 7 | 1 | 4 | 1 | 12 | 1.5E+04 | 9.1E+06 | 5.1E+01 | 19 | AA | AA | B | AA | AA |
| Example B-7 | 351 | 216 | 40 | 2 | 11 | 1 | 54 | 4.0E+05 | 2.7E+09 | 9.3E+01 | 81 | AA | AA | C | AA | AA |
| Example B-8 | 423 | 288 | 36 | 3 | 10 | 1 | 49 | 3.3E+05 | 6.2E+11 | 6.4E+01 | 74 | A | AA | C | AA | A |
| Example B-9 | 473 | 342 | 42 | 2 | 10 | 1 | 55 | 4.3E+05 | 5.0E+04 | 8.2E+00 | 83 | AA | A | AA | AA | D |
| Example B-10 | 243 | 149 | 19 | 2 | 7 | 1 | 29 | 1.0E+05 | 7.3E+04 | 6.9E+01 | 43 | AA | AA | AA | AA | AA |
| Example B-11 | 263 | 162 | 20 | 2 | 7 | 1 | 29 | 1.1E+05 | 8.0E+04 | 3.7E+01 | 44 | AA | AA | AA | AA | AA |
| Example B-12 | 252 | 155 | 30 | 2 | 10 | 1 | 43 | 2.4E+05 | 8.0E+04 | 5.9E+01 | 64 | AA | AA | AA | AA | AA |
| Example B-13 | 246 | 151 | 33 | 1 | 10 | 1 | 46 | 2.8E+05 | 7.1E+00 | 4.8E+01 | 68 | AA | AA | AA | AA | AA |
| Example B-14 | 257 | 158 | 40 | 1 | 7 | 1 | 48 | 3.6E+05 | 5.8E+10 | 3.1E+01 | 73 | AA | AA | AA | AA | AA |
| Example B-15 | 293 | 180 | 30 | 1 | 8 | 1 | 40 | 2.2E+05 | 5.2E+04 | 7.4E+05 | 60 | AA | B | C | AA | AA |
| Example B-16 | 270 | 135 | 17 | 2 | 9 | 1 | 29 | 9.0E+04 | 4.7E+04 | 1.1E+04 | 43 | AA | AA | AA | AA | AA |
| Example B-17 | 315 | 110 | 1,140 | 81 | 119 | 12 | 1,352 | 7.1E+09 | 4.5E+03 | 2.2E+03 | 117 | AA | AA | AA | AA | AA |
| Example B-18 | 146 | 90 | 1,710 | 117 | 238 | 10 | 2,075 | 1.6E+12 | 3.2E+03 | 1.2E+05 | 145 | AA | AA | AA | AA | AA |
| Example B-19 | 331 | 116 | 0.005 | 0.001 | 0.001 | 0.001 | 0.008 | 1.5E+01 | 3.2E+03 | 3.6E+08 | 8 | AA | B | AA | AA | AA |
| Example B-20 | 362 | 127 | 0.002 | 0.000 | 0.000 | 0.000 | 0.004 | 8.0E+00 | 7.IE+04 | 6.2E+02 | 3 | AA | AA | AA | AA | AA |
| Example B-21 | 293 | 234 | 4 | 1 | 3 | 1 | 9 | 6.0E+03 | 7.7E+04 | 1.2E+07 | 13 | A | AA | AA | AA | AA |
| Example B-22 | 140 | 45 | 5 | 2 | 4 | 1 | 11 | 1.0E+04 | 5.3E+04 | 1.3E+02 | 17 | B | AA | AA | AA | AA |

TABLE 15

| | | | | | | | | Total | | | | | | | | |
|---|---|---|---|---|---|---|---|---|---|---|---|---|---|---|---|---|
| | | | | | | | | number | | | | | | | | |
| | | | | | | | | of Fe | | | | | | | | |
| | | | | | | | | nanoparticles | | Number | | | | | | |
| | | | | | | | | containing | | of second | | | | | | |
| | | | | | | | | Fe atoms, Al | | iron oxide | | | | | | |
| | | | | | | | | nanoparticles | | nanoparticles | | | | | | |
| | | | Atom as measurement target | | | | | containing | | contained | | | | | | |
| | | | | | | | Total | Al atoms, | | in chemical | | | | | | |
| | | | | | | | content | and Ti | Number | liquid/ | | | | | | |
| | | | | | | | of | nanoparticles | of first | Number | | | | | | |
| | Metal impurities | | | | | | atom as | containing | iron oxide | of first | | | | | | |
| | | Metal- | | | | | measure- | Ti atoms | nanoparticles | iron oxide | Number | Evaluation | | | | |
| | Metal | containing | | | | | ment | contained in | contained | nanoparticles | of coarse | | | | | Stability |
| | ions | particles | Fe | Cr | Ni | Pb | target | chemical | in chemical | contained | particles | | Metal | Organic | Organic | of |
| | (mass | (mass | (mass | (mass | (mass | (mass | (mass | liquid | liquid | in chemical | (particles/ | Metal | oxide | metal | substance | chemical |
| | ppt) | ppt) | ppt) | ppt) | ppt) | ppt) | ppt) | (particles/cm³) | (particles/cm³) | liquid | mL) | residues | residues | residues | residues | liquid |
| Example C-1 | 432 | 324 | 4 | 1 | 4 | 1 | 10 | 6.3E+03 | 9.4E+04 | 2.6E+02 | 14 | C | AA | AA | AA | A |
| Example C-2 | 421 | 259 | 14 | 2 | 6 | 1 | 24 | 6.3E+04 | 5.7E+02 | 9.5E+02 | 36 | B | A | AA | AA | D |
| Example C-3 | 614 | 432 | 24 | 2 | 8 | 1 | 36 | 1.6E+05 | 3.2E+01 | 2.1E+02 | 53 | A | A | AA | AA | AA |
| Example C-4 | 527 | 324 | 10 | 1 | 2 | 1 | 14 | 2.5E+04 | 1.3E+01 | 1.4E+02 | 21 | A | A | AA | AA | AA |
| Example C-5 | 351 | 216 | 5 | 1 | 4 | 1 | 11 | 9.4E+03 | 5.3E+00 | 7.4E+00 | 16 | A | A | AA | AA | AA |
| Example C-6 | 439 | 270 | 8 | 1 | 5 | 1 | 15 | 2.4E+04 | 1.4E+07 | 7.7E+01 | 23 | AA | AA | A | AA | AA |
| Example C-7 | 527 | 324 | 50 | 2 | 14 | 1 | 68 | 6.2E+05 | 4.1E+09 | 1.4E+02 | 102 | A | A | B | AA | AA |
| Example C-8 | 635 | 432 | 45 | 4 | 12 | 1 | 62 | 5.2E+05 | 9.4E+11 | 9.6E+01 | 93 | B | A | C | AA | A |
| Example C-9 | 709 | 513 | 52 | 2 | 13 | 1 | 69 | 6.7E+05 | 7.5E+04 | 1.2E+02 | 103 | A | A | AA | AA | C |
| Example C-10 | 364 | 224 | 24 | 2 | 8 | 1 | 36 | 1.6E+05 | 1.1E+05 | 1.0E+02 | 53 | AA | AA | AA | AA | AA |
| Example C-11 | 395 | 243 | 25 | 2 | 8 | 1 | 37 | 1.7E+05 | 1.2E+05 | 5.5E+01 | 55 | AA | AA | AA | AA | AA |
| Example C-12 | 377 | 232 | 38 | 2 | 12 | 1 | 53 | 3.8E+05 | 1.2E+05 | 8.9E+01 | 80 | AA | AA | AA | AA | AA |
| Example C-13 | 369 | 227 | 42 | 1 | 13 | 1 | 57 | 4.4E+05 | 1.1E+01 | 7.2E+01 | 86 | AA | AA | AA | AA | AA |
| Example C-14 | 386 | 238 | 50 | 1 | 8 | 1 | 61 | 5.6E+05 | 8.7E+10 | 4.7E+01 | 91 | AA | AA | AA | AA | AA |
| Example C-15 | 439 | 270 | 38 | 1 | 10 | 1 | 50 | 3.5E+05 | 7.9E+04 | 6.6E+05 | 75 | AA | B | C | AA | AA |
| Example C-16 | 405 | 203 | 21 | 2 | 11 | 1 | 36 | 1.4E+05 | 7.1E+04 | 1.6E+04 | 53 | AA | AA | AA | AA | AA |
| Example C-17 | 473 | 165 | 1,425 | 101 | 148 | 15 | 1,690 | 1.1E+10 | 6.8E+03 | 3.2E+03 | 146 | AA | AA | AA | AA | AA |
| Example C-18 | 219 | 135 | 2,138 | 146 | 297 | 13 | 2,594 | 2.6E+12 | 4.8E+03 | 1.8E+05 | 182 | AA | AA | AA | AA | AA |
| Example C-19 | 496 | 174 | 0.006 | 0.001 | 0.001 | 0.001 | 0.010 | 1.5E+01 | 4.8E+03 | 5.5E+08 | 10 | AA | A | AA | AA | AA |
| Example C-20 | 543 | 190 | 0.003 | 0.001 | 0.001 | 0.001 | 0.005 | 8.0E+00 | 1.1E+05 | 9.4E+02 | 4 | A | A | AA | AA | AA |
| Example C-21 | 439 | 351 | 5 | 1 | 4 | 1 | 11 | 9.4E+03 | 1.2E+05 | 1.8E+07 | 16 | A | AA | AA | AA | AA |
| Example C-22 | 209 | 68 | 6 | 2 | 5 | 1 | 14 | 1.6E+04 | 7.9E+04 | 2.0E+02 | 21 | B | AA | AA | AA | AA |

TABLE 16

| | | | | | | | | Total | | | | | | | | |
|---|---|---|---|---|---|---|---|---|---|---|---|---|---|---|---|---|
| | | | | | | | | number | | | | | | | | |
| | | | | | | | | of Fe | | | | | | | | |
| | | | | | | | | nanoparticles | | Number | | | | | | |
| | | | | | | | | containing | | of | | | | | | |
| | | | | | | | | Fe atoms, | | second | | | | | | |
| | | | | | | | | Al nano- | | iron oxide | | | | | | |
| | | | | | | | | particles | | nanoparticles | | | | | | |
| | | | Atom as measurement target | | | | | containing | | contained | | | | | | |
| | | | | | | | Total | Al atoms, | Number | in chemical | | | | | | |
| | | | | | | | content | and Ti | of first | liquid/ | | | | | | |
| | Metal | | | | | | of | nanoparticles | iron oxide | Number | Number | | | | | |
| | impurities | | | | | | atom as | containing | nanoparticles | of first | of | | | | | |
| | | Metal- | | | | | measure- | Ti atoms | contained | iron oxide | coarse | Evaluation | | | | |
| | Metal | containing | | | | | ment | contained | in chemical | nanoparticles | particles | | | | | Stability |
| | ions | particles | Fe | Cr | Ni | Pb | target | in chemical | liquid | contained | (parti- | | Metal | Organic | Organic | of |
| | (mass | (mass | (mass | (mass | (mass | (mass | (mass | liquid | (particles/ | in chemical | cles/ | Metal | oxide | metal | substance | chemical |
| | ppt) | ppt) | ppt) | ppt) | ppt) | ppt) | ppt) | (particles/cm³) | cm³) | liquid | mL) | residues | residues | residues | residues | liquid |
| Example D-1 | 389 | 292 | 2 | 1 | 2 | 1 | 6 | 2.3E+03 | 1.4E+05 | 4.3E+02 | 9 | C | A | AA | AA | A |
| Example D-2 | 379 | 233 | 9 | 1 | 4 | 1 | 14 | 2.3E+04 | 8.5E+02 | 1.6E+03 | 21 | B | A | AA | AA | D |
| Example D-3 | 553 | 389 | 14 | 1 | 5 | 1 | 21 | 5.6E+04 | 4.8E+01 | 3.5E+02 | 32 | A | A | AA | AA | AA |
| Example D-4 | 474 | 292 | 6 | 1 | 1 | 1 | 9 | 9.0E+03 | 2.0E+01 | 2.3E+02 | 13 | AA | AA | AA | AA | AA |
| Example D-5 | 316 | 194 | 3 | 1 | 2 | 1 | 6 | 3.4E+03 | 8.0E+00 | 1.2E+01 | 10 | A | AA | AA | AA | AA |
| Example D-6 | 395 | 243 | 5 | 1 | 3 | 1 | 9 | 8.5E+03 | 2.0E+07 | 1.3E+02 | 14 | AA | AA | A | AA | AA |
| Example D-7 | 474 | 292 | 30 | 1 | 9 | 1 | 41 | 2.2E+05 | 6.1E+09 | 2.3E+02 | 61 | AA | AA | B | AA | AA |
| Example D-8 | 571 | 389 | 27 | 2 | 7 | 1 | 37 | 1.9E+05 | 1.4E+12 | 1.6E+02 | 56 | A | A | C | AA | A |
| Example D-9 | 638 | 462 | 31 | 1 | 8 | 1 | 41 | 2.4E+05 | 1.1E+05 | 2.0E+01 | 62 | A | A | AA | AA | C |
| Example D-10 | 328 | 202 | 14 | 1 | 5 | 1 | 21 | 5.6E+04 | 1.6E+05 | 1.7E+02 | 32 | AA | AA | AA | AA | AA |
| Example D-11 | 355 | 219 | 15 | 1 | 5 | 1 | 22 | 6.1E+04 | 1.8E+05 | 9.2E+01 | 33 | AA | AA | AA | AA | AA |
| Example D-12 | 340 | 209 | 23 | 1 | 7 | 1 | 32 | 1.4E+05 | 1.8E+05 | 1.5E+02 | 48 | AA | AA | AA | AA | AA |
| Example D-13 | 332 | 204 | 25 | 1 | 8 | 1 | 34 | 1.6E+05 | 1.6E+01 | 1.2E+02 | 51 | AA | A | AA | AA | AA |
| Example D-14 | 347 | 214 | 30 | 1 | 5 | 1 | 36 | 2.0E+05 | 1.3E+11 | 7.8E+01 | 55 | A | AA | AA | AA | AA |
| Example D-15 | 395 | 243 | 23 | 1 | 6 | 1 | 30 | 1.3E+05 | 1.2E+05 | 9.9E+05 | 45 | AA | B | C | AA | AA |
| Example D-16 | 365 | 182 | 13 | 1 | 6 | 1 | 21 | 5.1E+04 | 1.1E+05 | 2.7E+03 | 32 | AA | AA | AA | AA | A |
| Example D-17 | 425 | 149 | 855 | 61 | 89 | 9 | 1,014 | 4.0E+09 | 1.0E+04 | 5.4E+04 | 88 | AA | A | AA | AA | AA |
| Example D-18 | 197 | 122 | 1,283 | 88 | 178 | 8 | 1,556 | 9.2E+11 | 7.2E+03 | 2.9E+05 | 109 | AA | AA | AA | AA | AA |
| Example D-19 | 447 | 156 | 0.0036 | 0.0007 | 0.0007 | 0.0007 | 0.0057 | 1.5E+01 | 7.2E+03 | 9.1E+08 | 6 | AA | A | AA | AA | AA |
| Example D-20 | 489 | 171 | 0.0018 | 0.0004 | 0.0004 | 0.0004 | 0.0029 | 8.0E+00 | 1.6E+05 | 1.6E+03 | 2.1375 | AA | AA | AA | AA | A |
| Example D-21 | 395 | 316 | 3 | 1 | 2 | 1 | 6 | 3.4E+03 | 1.7E+05 | 2.9E+07 | 10 | A | AA | AA | AA | A |
| Example D-22 | 188 | 61 | 4 | 1 | 3 | 1 | 9 | 5.6E+03 | 1.2E+05 | 3.3E+02 | 13 | B | AA | AA | AA | A |

TABLE 17

| | | | | | | | | Total | | | | | | | | |
|---|---|---|---|---|---|---|---|---|---|---|---|---|---|---|---|---|
| | | | | | | | | number of Fe | | | | | | | | |
| | | | | | | | | nanoparticles | | Number | | | | | | |
| | | | | | | | | containing | | of second | | | | | | |
| | | | | | | | | Fe atoms, Al | | iron oxide | | | | | | |
| | | | | | | | | nanoparticles | | nanoparticles | | | | | | |
| | | | Atom as measurement target | | | | | containing | | contained | | | | | | |
| | | | | | | | Total | Al atoms, | | in chemical | | | | | | |
| | | | | | | | content | and Ti | Number | liquid/ | | | | | | |
| | Metal | | | | | | of | nanoparticles | of first | Number | | | | | | |
| | impurities | | | | | | atom as | containing | iron oxide | of first | | | | | | |
| | | Metal | | | | | measure- | Ti atoms | nanoparticles | iron oxide | Number | Evaluation | | | | |
| | Metal | containing | | | | | ment | contained | contained | nanoparticles | of coarse | | | | | Stability |
| | ions | particles | Fe | Cr | Ni | Pb | target | in chemical | in chemical | contained | particles | | Metal | Organic | Organic | of |
| | (mass | (mass | (mass | (mass | (mass | (mass | (mass | liquid | liquid | in chemical | (particles/ | Metal | oxide | metal | substance | chemical |
| | ppt) | ppt) | ppt) | ppt) | ppt) | ppt) | ppt) | (particles/cm³) | (particles/cm³) | liquid | mL) | residues | residues | residues | residues | liquid |
| Example E-1 | 350 | 262 | 3 | 1 | 3 | 1 | 7 | 3.2E+03 | 2.1E+05 | 3.4E+02 | 10 | C | AA | AA | AA | A |
| Example E-2 | 341 | 210 | 10 | 2 | 4 | 1 | 17 | 3.2E+04 | 1.3E+03 | 1.3E+03 | 26 | B | A | AA | AA | D |
| Example E-3 | 498 | 350 | 17 | 2 | 6 | 1 | 26 | 8.1E+04 | 7.2E+01 | 2.8E+02 | 38 | AA | AA | AA | AA | AA |
| Example E-4 | 426 | 262 | 7 | 1 | 2 | 1 | 10 | 1.3E+04 | 3.0E+01 | 1.8E+02 | 15 | AA | AA | AA | AA | AA |
| Example E-5 | 284 | 175 | 3 | 1 | 3 | 1 | 8 | 4.9E+03 | 1.2E+01 | 1.0E+01 | 12 | AA | AA | AA | AA | AA |
| Example E-6 | 355 | 219 | 6 | 1 | 3 | 1 | 11 | 1.2E+04 | 3.1E+07 | 1.0E+02 | 17 | AA | AA | A | AA | AA |
| Example E-7 | 426 | 262 | 36 | 2 | 10 | 1 | 49 | 3.2E+05 | 9.2E+09 | 1.9E+02 | 73 | AA | AA | B | AA | AA |
| Example E-8 | 514 | 350 | 32 | 3 | 9 | 1 | 44 | 2.7E+05 | 2.1E+12 | 1.3E+02 | 67 | B | A | C | AA | B |
| Example E-9 | 574 | 416 | 38 | 2 | 9 | 1 | 50 | 3.5E+05 | 1.7E+05 | 1.7E+02 | 74 | A | A | AA | AA | C |
| Example E-10 | 295 | 182 | 17 | 2 | 6 | 1 | 26 | 8.1E+04 | 2.5E+05 | 1.4E+02 | 38 | AA | AA | AA | AA | AA |
| Example E-11 | 320 | 197 | 18 | 2 | 6 | 1 | 27 | 8.8E+04 | 2.7E+05 | 7.4E+01 | 40 | AA | AA | AA | AA | AA |
| Example E-12 | 306 | 188 | 27 | 2 | 9 | 1 | 38 | 1.9E+05 | 2.7E+05 | 1.2E+02 | 58 | AA | AA | AA | AA | AA |
| Example E-13 | 299 | 184 | 30 | 1 | 9 | 1 | 41 | 2.3E+05 | 2.4E+01 | 9.7E+01 | 62 | AA | AA | AA | AA | AA |
| Example E-14 | 313 | 192 | 36 | 1 | 6 | 1 | 44 | 2.9E+05 | 2.0E+11 | 6.3E+01 | 65 | AA | AA | AA | AA | AA |
| Example E-15 | 355 | 219 | 27 | 1 | 7 | 1 | 36 | 1.8E+05 | 1.8E+05 | 1.0E+06 | 54 | AA | B | AA | AA | AA |
| Example E-16 | 328 | 164 | 15 | 2 | 8 | 1 | 26 | 7.3E+04 | 1.6E+05 | 2.2E+04 | 38 | AA | AA | C | AA | A |
| Example E-17 | 383 | 134 | 1,026 | 73 | 107 | 11 | 1,217 | 5.8E+09 | 1.5E+04 | 4.4E+04 | 105 | AA | A | AA | AA | AA |
| Example E-18 | 178 | 109 | 1,539 | 105 | 214 | 9 | 1,867 | 1.3E+12 | 1.1E+04 | 2.6E+05 | 131 | AA | AA | AA | AA | AA |
| Example E-19 | 402 | 141 | 0.004 | 0.001 | 0.001 | 0.001 | 0.007 | 1.5E+01 | 1.1E+04 | 7.4E+08 | 7 | AA | A | AA | AA | AA |
| Example E-20 | 440 | 154 | 0.002 | 0.000 | 0.000 | 0.000 | 0.003 | 8.0E+00 | 2.4E+05 | 1.3E+03 | 2.565 | AA | A | AA | AA | A |
| Example E-21 | 355 | 284 | 3 | 1 | 3 | 1 | 8 | 4.9E+03 | 2.6E+05 | 2.4E+07 | 12 | A | AA | AA | AA | AA |
| Example E-22 | 169 | 55 | 4 | 2 | 3 | 1 | 10 | 8.1E+03 | 1.8E+05 | 2.7E+02 | 15 | B | AA | AA | AA | A |

TABLE 18

| | | | | | | | | Total | | | | | | | | |
|---|---|---|---|---|---|---|---|---|---|---|---|---|---|---|---|---|
| | | | | | | | | number | | | | | | | | |
| | | | | | | | | of Fe | | | | | | | | |
| | | | | | | | | nano- | | | | | | | | |
| | | | | | | | | particles | | | | | | | | |
| | | | | | | | | con- | | | | | | | | |
| | | | | | | | | taining | | Number | | | | | | |
| | | | | | | | | Fe | | of | | | | | | |
| | | | | | | | | atoms, | | second | | | | | | |
| | | | | | | | | Al | | iron | | | | | | |
| | | | | | | | | nano- | | oxide | | | | | | |
| | | | | | | | | parti- | | nano- | | | | | | |
| | | | | | | | | cles | | parti- | | | | | | |
| | | | | | | | | con- | | cles | | | | | | |
| | | | | | | | | taining | | con- | | | | | | |
| | | | | | | | | Al | | tained | | | | | | |
| | | | | | | | | atoms, | | in | | | | | | |
| | | | | | | | | and Ti | | chem- | | | | | | |
| | | | | | | | | nano- | | ical | | | | | | |
| | | | | | | | | parti- | | liquid/ | | | | | | |
| | | | | | | | | cles | Number | Num- | | | | | | |
| | | | | | | | | con- | of first | ber of | | | | | | |
| | | | | | | | | taining | iron | first | | | | | | |
| | | | | | | | | Ti | oxide | iron | | | | | | |
| | | | Atom as measurement target | | | | | atoms | nano- | oxide | | | | | | |
| | Metal | | | | | | Total | con- | particles | nano- | Num- | | | | | |
| | impurities | | | | | | content | tained | con- | parti- | ber | | | | | |
| | | Metal- | | | | | of | in | tained | cles | of | | | | | |
| | | con- | | | | | atom as | chem- | in | con- | coarse | Evaluation | | | | |
| | | taining | | | | | measure- | ical | chemical | tained | parti- | | | Or- | Organic | Stability |
| | Metal | parti- | | | | | ment | liquid | liquid | in | cles | | Metal | ganic | sub- | of |
| | ions | cles | Fe | Cr | Ni | Pb | target | (parti- | (parti- | chem- | (parti- | Metal | oxide | metal | stance | chem- |
| | (mass | (mass | (mass | (mass | (mass | (mass | (mass | cles/ | cles/ | ical | cles/ | resi- | resi- | resi- | resi- | ical |
| | ppt) | ppt) | ppt) | ppt) | ppt) | ppt) | ppt) | cm³) | cm³) | liquid | mL) | dues | dues | dues | dues | liquid |
| Example F-1 | 315 | 236 | 3 | 1 | 3 | 1 | 8 | 4.7E+03 | 3.2E+05 | 2.8E+02 | 12 | AA | AA | AA | AA | AA |
| Example G-1 | 307 | 189 | 3 | 1 | 3 | 1 | 8 | 4.5E+03 | 1.9E+03 | 3.5E+02 | 12 | AA | AA | AA | AA | AA |
| Example H-1 | 448 | 315 | 3 | 1 | 3 | 1 | 8 | 4.3E+03 | 1.1E+02 | 3.4E+02 | 12 | AA | AA | AA | AA | AA |
| Comparative | 384 | 236 | 3 | 1 | 3 | 1 | 8 | 4.4E+03 | 4.5E+01 | 4.6E+01 | 12 | E | E | D | AA | AA |
| Example 1 | | | | | | | | | | | | | | | | |

As shown in the tables, it has been found that in a chemical liquid containing an organic solvent, organic impurities, and metal impurities, in a case where the mass ratio of the content of the phosphoric acid ester to the content of the adipic acid ester is equal to or higher than 1, the performance of inhibiting metal impurity-containing defects is excellent (examples).

On the other hand, it has been found that in a case where the mass ratio of the content of the phosphoric acid ester to the content of the adipic acid ester in the chemical liquid is lower than 1, the performance of inhibiting metal impurity-containing defects is poor (comparative example).

Furthermore, from the comparison of Examples A-3 and Examples A-1 and A-22, it has been found that in a case where the content of the phosphoric acid ester is 0.1 mass ppt to 100 mass ppm with respect to the total mass of the chemical liquid, the metal impurity-containing defects are further inhibited.

From the comparison of Examples A-3 and Examples A-1, A-2, A-21, and A-22, it has been found that in a case where the content of the adipic acid ester is 0.1 mass ppt to 10 mass ppm with respect to the total mass of the chemical liquid, the metal impurity-containing defects are further inhibited.

From the comparison between Example A-3 and Example A-15, it has been found that in a case where the mass ratio of the content of the phosphoric acid ester to the content of the adipic acid ester is 1 to 10⁴, the metal impurity-containing defects (particularly, defects containing both the organic impurities and metal impurities and defects containing oxides of metal atoms) are further inhibited.

From the comparison of Examples A-3 and Examples A-1 and A-2, it has been found that in a case where the content of the phthalic acid ester is 0.1 mass ppt to 10 mass ppm with respect to the total mass of the chemical liquid, the metal impurity-containing defects are further inhibited.

From the comparison of Example A-3 and Examples A-9 and A-17, it has been found that in a case where the mass ratio of the content of the phosphoric acid ester to the content of the phthalic acid ester is 10⁻² to 10, at least the stability of the chemical liquid or the performance of inhibiting metal impurity-containing defects (particularly, defects containing oxides of metal atoms) is further improved.

From the comparison between Example A-3 and Example A-15, it has been found that in a case where the mass ratio of the content of the adipic acid ester to the content of the phthalic acid ester is 10⁻³ to 10, the metal impurity-containing defects (particularly, defects containing both the organic impurities and metal impurities and defects containing oxides of metal atoms) are further inhibited.

From the comparison of Example A-3 and Examples A-2 and A-9, it has been found that in a case where the total content of alcohol and acetone as organic impurities is 1 mass ppt to 3,000 mass ppm with respect to the total mass of the chemical liquid, at least the stability of the chemical liquid or the performance of inhibiting metal impurity-containing defects (particularly, metal atom-containing defects) is further improved.

From the comparison of Example A-3 and Examples A-2 and A-9, it has been found that in a case where the mass ratio of the content of the phosphoric acid ester to the total content of alcohol and acetone as organic impurities is 10⁻³ to 10⁹, at least the stability of the chemical liquid or the performance of inhibiting metal impurity-containing defects (particularly, metal atom-containing defects) is further improved.

From the comparison of Example A-3 and Examples A-6 to A-8 and A-15, it has been found that in a case where the mass ratio of the content of the adipic acid ester to the total content of alcohol and acetone as organic impurities is 10⁻¹ to 10⁵, the metal impurity-containing defects (particularly, at least defects containing both the organic impurities and metal impurities or defects containing oxides of metal atoms) are further inhibited.

From the comparison of Example A-3 and Examples A-1, A-2, A-8, A-16, A-20, and A-22, it has been found that in a case where the mass ratio of the content of water to the total content of alcohol and acetone as organic impurities is 1 to 10⁹, at least the stability of the chemical liquid or the performance of inhibiting metal impurity-containing defects is further improved.

From the comparison of Example A-3 and Examples A-4, A-5, and A-8, it has been found that in a case where the number of the first iron oxide nanoparticles contained in a unit volume of the chemical liquid is 10 to 1.0×10¹¹ particles/cm³, the metal impurity-containing defects (particularly, at least metal atom-containing defects or defects containing both the organic impurities and metal impurities) are further inhibited.

From the comparison of Example A-3 and Examples A-5 and A-19, it has been found that in a case where the ratio of the number of the second iron oxide nanoparticles contained in a unit volume of the chemical liquid to the number of the first iron oxide nanoparticles contained in a unit volume of the chemical liquid is 10 to 10⁸, the metal impurity-containing defects (particularly, defects containing oxides of metal atoms) are further inhibited.

It has been found that in the comparison of Examples B-1 to B-22, the comparison of Examples C-1 to C-22, the comparison of Examples D-1 to D-22, and the comparison of Examples E-1 to E-22, the same trend as that in the comparison of Examples A-1 to A-22 described above is exhibited.

What is claimed is:

1. A chemical liquid comprising:
an organic solvent;
organic impurities; and
metal impurities,
wherein the organic impurities contain a phosphoric acid ester and an adipic acid ester, and
a mass ratio of a content of the phosphoric acid ester to a content of the adipic acid ester is equal to or higher than 1.

2. The chemical liquid according to claim 1,
wherein the content of the phosphoric acid ester is 0.1 mass ppt to 100 mass ppm with respect to a total mass of the chemical liquid.

3. The chemical liquid according to claim 1,
wherein the content of the adipic acid ester is 0.1 mass ppt to 10 mass ppm with respect to a total mass of the chemical liquid.

4. The chemical liquid according to claim 1,
wherein the mass ratio of the content of the phosphoric acid ester to the content of the adipic acid ester is 1 to 10⁴.

5. The chemical liquid according to claim 1,
wherein the organic impurities further contain a phthalic acid ester.

6. The chemical liquid according to claim 5,
wherein a content of the phthalic acid ester is 0.1 mass ppt to 10 mass ppm with respect to a total mass of the chemical liquid.

7. The chemical liquid according to claim 5,
wherein a mass ratio of the content of the phosphoric acid ester to a content of the phthalic acid ester is 10⁻² to 10.

8. The chemical liquid according to claim 5,
wherein a mass ratio of the content of the adipic acid ester to a content of the phthalic acid ester is 10⁻³ to 10.

9. The chemical liquid according to claim 1, further comprising:
water,
wherein a content of the water is 0.001% to 0.10% by mass with respect to a total mass of the chemical liquid.

10. The chemical liquid according to claim 1,
wherein the organic impurities further contain at least one kind of compound selected from the group consisting of alcohol and acetone.

11. The chemical liquid according to claim 10,
wherein the alcohol is at least one kind of compound selected from the group consisting of methanol, ethanol, n-butanol, and cyclohexanol.

12. The chemical liquid according to claim 10,
wherein a total content of the alcohol and the acetone is 1 mass ppt to 3,000 mass ppm with respect to a total mass of the chemical liquid.

13. The chemical liquid according to claim 10,
wherein a mass ratio of the content of the phosphoric acid ester to a total content of the alcohol and the acetone is 10⁻³ to 10⁹.

14. The chemical liquid according to claim 10,
wherein a mass ratio of the content of the adipic acid ester to a total content of the alcohol and the acetone is 10⁻¹ to 10⁵.

15. The chemical liquid according to claim 10, further comprising:
water,
wherein a mass ratio of a content of water to a total content of the alcohol and the acetone is 1 to 10⁹.

16. The chemical liquid according to claim 1,
wherein a content of the metal impurities is 0.1 to 2,000 mass ppt with respect to a total mass of the chemical liquid.

17. The chemical liquid according to claim 1,
wherein the metal impurities contain metal-containing particles and metal ions.

18. The chemical liquid according to claim 17,
wherein the metal-containing particles contain metal nanoparticles having a particle size of 0.5 to 17 nm.

19. The chemical liquid according to claim 18,
wherein the metal nanoparticles contain first iron oxide nanoparticles consisting of iron oxide, and
the number of the first iron oxide nanoparticles contained in a unit volume of the chemical liquid is 10 to 1.0×10¹¹ particles/cm³.

20. The chemical liquid according to claim 19,
wherein the metal nanoparticles contain second iron oxide nanoparticles containing iron oxide and an organic compound, and
a ratio of the number of the second iron oxide nanoparticles contained in a unit volume of the chemical liquid to the number of the first iron oxide nanoparticles contained in a unit volume of the chemical liquid is 10 to 10⁸.

21. The chemical liquid according to claim 1,
wherein the organic impurities further contain a stabilizer.

22. The chemical liquid according to claim 21,
wherein the stabilizer is an antioxidant.

23. The chemical liquid according to claim 21, further comprising:
water,
wherein a mass ratio of a content of the water to a content of the stabilizer is 10 to 10⁵.

24. The chemical liquid according to claim 21,
wherein the organic impurities further contain at least one kind of compound selected from the group consisting of alcohol and acetone, and
a mass ratio of a total content of the alcohol and the acetone to a content of the stabilizer is 10⁷ to 10³.

25. The chemical liquid according to claim 21,
wherein the stabilizer is at least one kind of antioxidant selected from the group consisting of dibutylhydroxytoluene, hydroquinone, didodecyl 3,3′-thiodipropionate, dioctadecyl 3,3′-thiodipropionate, ditetradecyl 3,3′-thiodipropionate, 4,4′-butylidenebis-(6-tert-butyl-3-methylphenol), 2,2′-methylenebis-(4-ethyl-6-tert-butylphenol), butylhydroxyanisole, tris(2-ethylhexyl)phosphite, and triisodecyl phosphite.

26. The chemical liquid according to claim 21,
wherein a boiling point of the stabilizer is 150° C. to 500° C.

27. The chemical liquid according to claim 1,
wherein the number of objects to be counted having a size equal to or greater than 0.04 μm that is counted by a light scattering liquid-borne particle counter is equal to or less than 100 particles/mL.

28. The chemical liquid according to claim 1, which is used as a raw material of at least one kind of liquid selected from the group consisting of a developer, a rinsing solution, a prewet solution, and a piping washing solution.

29. A chemical liquid storage body comprising:
a container; and
the chemical liquid according to claim 1 that is stored in the container.

30. The chemical liquid storage body according to claim 29,
wherein at least a part of a liquid contact portion of the container is a fluororesin, electropolished stainless steel, or glass.

31. The chemical liquid storage body according to claim 29,
wherein a void volume of the container in the chemical liquid storage body is 5% to 30% by volume.
